(19) United States
(12) Patent Application Publication
(10) Pub. No.: US 2015/0279872 A1
(43) Pub. Date: Oct. 1, 2015

(54) DISPLAY DEVICE, ELECTRONIC APPARATUS, AND SUBSTRATE

(71) Applicant: Sony Corporation, Tokyo (JP)

(72) Inventors: Yuichi Kato, Kanagawa (JP); Yasuhiro Terai, Kanagawa (JP); Hiroshi Fujimura, Aichi (JP)

(21) Appl. No.: 14/645,979

(22) Filed: Mar. 12, 2015

(30) Foreign Application Priority Data
Mar. 27, 2014 (JP) 2014-066718

(51) Int. Cl. H01L 27/12; H01L 27/32; H01L 29/786

(52) U.S. Cl. CPC H01L 27/1255; H01L 29/7869; H01L 27/1225; H01L 27/124; H01L 27/3262; H01L 27/3265; H01L 27/3276

(57) ABSTRACT

Provided is a display device provided with a substrate and a display element on the substrate, the substrate including: a base; and a plurality of capacitive elements that are stacked on the base and each include a bottom electrode and a top electrode, wherein the plurality of capacitive elements include a lower capacitive element and an upper capacitive element that are different in position in a stacking direction, and the bottom electrode of the lower capacitive element and the top electrode of the upper capacitive element are electrically independent from one another.

### CROSS REFERENCE TO RELATED APPLICATIONS

This application claims the benefit of Japanese Priority Patent Application JP 2014-066718 filed on Mar. 27, 2014, the entire contents of which are incorporated herein by reference.

### BACKGROUND

The present disclosure relates to a display device suitable for liquid crystal display, organic electroluminescence (EL) display, or the like, an electronic apparatus including the display device, and a substrate used in the display device.

In a display device of an active matrix type, which is typified by a liquid crystal display or an organic EL display device, a pixel circuit uses a capacitive element to retain a potential of a picture signal until the next writing.

For example, Japanese Unexamined Patent Application Publication No. 2010-282216 (Example 5, and FIG. 15) considers forming a retention capacitor in a stacked structure such as a top electrode (a capacitor wiring)/a dielectric layer (a gate insulating film)/a bottom electrode that also serves as a top electrode (a semiconductor film)/a dielectric layer (an insulating film)/a bottom electrode (a capacitor electrode), in a pixel circuit for a liquid crystal display device.

### SUMMARY

In the stacked structure of Japanese Unexamined Patent Application Publication No. 2010-282216, an upper capacitive element and a lower capacitive element are stacked. The upper capacitive element is made up of the top electrode (the capacitor wiring)/the dielectric layer (the gate insulating film)/the bottom electrode (the semiconductor film). The lower capacitive element is made up of the top electrode (the semiconductor film)/the dielectric layer (the insulating film)/the bottom electrode (the capacitor electrode). However, since the capacitor wiring and the capacitor electrode are electrically connected, the upper capacitive element and the lower capacitive element constitute a single capacitive element in view of operation and function. In other words, in the existing stacked structure, it has never been proposed to stack a plurality of capacitive elements having different operations and functions.

It is desirable to provide a display device that makes it possible to stack a plurality of capacitive elements having different operations and functions to enhance layout efficiency, an electronic apparatus including the display device, and a substrate used in the display device.

According to an embodiment of the present disclosure, there is provided a display device provided with a substrate and a display element on the substrate, the substrate including: a base; and a plurality of capacitive elements that are stacked on the base and each include a bottom electrode and a top electrode, wherein the plurality of capacitive elements include a lower capacitive element and an upper capacitive element that are different in position in a stacking direction, and the bottom electrode of the lower capacitive element and the top electrode of the upper capacitive element are electrically independent from one another.

In the display device according to the above-described embodiment of the present disclosure, the bottom electrode of the lower capacitive element and the top electrode of the upper capacitive element are electrically independent from one another. In other words, the bottom electrode of the lower capacitive element and the top electrode of the upper capacitive element are not electrically connected, but connected to, for example, their respective wirings that are different from one another. This allows the lower capacitive element and the upper capacitive element to perform different operations from one another.

According to an embodiment of the present disclosure, there is provided an electronic apparatus provided with a display device including a substrate and a display element on the substrate, the substrate including: a base; and a plurality of capacitive elements that are stacked on the base and each include a bottom electrode and a top electrode, wherein the plurality of capacitive elements include a lower capacitive element and an upper capacitive element that are different in position in a stacking direction, and the bottom electrode of the lower capacitive element and the top electrode of the upper capacitive element are electrically independent from one another.

In the electronic apparatus according to the above-described embodiment of the present disclosure, image display is performed by the display device.

According to an embodiment of the present disclosure, there is provided a substrate including: a base; and a plurality of capacitive elements that are stacked on the base and each include a bottom electrode and a top electrode, wherein the plurality of capacitive elements include a lower capacitive element and an upper capacitive element that are different in position in a stacking direction, and the bottom electrode of the lower capacitive element and the top electrode of the upper capacitive element are electrically independent from one another.

According to the display device in the above-described embodiment of the present disclosure, and the substrate in the above-described embodiment of the present disclosure, the plurality of capacitive elements are stacked on the base. The plurality of capacitive elements include the lower capacitive element and the upper capacitive element that are different in position in the stacking direction. The bottom electrode of the lower capacitive element and the top electrode of the upper capacitive element are electrically independent from one another. Hence, it is possible to stack the plurality of capacitive elements having different operations and functions from one another, leading to enhanced layout efficiency. This is suitable for higher definition (an increase in the number of pixels) or downsizing of the display device.

According to the electronic apparatus in the above-described embodiment of the present disclosure, the electronic apparatus is provided with the display device according to the above-described embodiment of the present disclosure. Hence, the electronic apparatus is suitable for high-definition image display in large-sized electronic apparatuses such as a television set or a digital signage, or applications to small-sized electronic apparatuses such as a mobile terminal.

It is to be noted that effects of the present disclosure are not limited to those described here, but may be any of effects described in the followings.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a block diagram illustrating an overall configuration of a display device according to a first embodiment of the present disclosure.

FIG. 2 is a diagram illustrating an example of a pixel circuit of the display device illustrated in FIG. 1.

FIG. 3 is a plan view illustrating a configuration example in which a retention capacitor and an auxiliary capacitor illustrated in FIG. 2 are arranged side by side in a plane.

FIG. 4 is a cross-sectional view along an IVA-IVA′ line in FIG. 3.

FIG. 5 is a plan view illustrating another configuration example in which the retention capacitor and the auxiliary capacitor illustrated in FIG. 2 are arranged side by side in a plane.

FIG. 6 is a cross-sectional view along a VIA-VIA′ line in FIG. 5.

FIG. 7 is a plan view illustrating a configuration in which the retention capacitor and the auxiliary capacitor illustrated in FIG. 2 are stacked.

FIG. 8 is a cross-sectional view along a VIIIA-VIIIA′ line in FIG. 7.

FIG. 9 is a cross-sectional view illustrating a configuration of one pixel of a display device including a substrate illustrated in FIG. 8.

FIG. 10 is a cross-sectional view illustrating an example of an organic layer illustrated in FIG. 9.

FIG. 11 is a cross-sectional view illustrating another example of the organic layer illustrated in FIG. 9.

FIG. 12 is a cross-sectional view illustrating still another example of the organic layer illustrated in FIG. 9.

FIG. 13 is a cross-sectional view illustrating a method of manufacturing the display device illustrated in FIG. 8 in the order of procedure.

FIG. 14 is a cross-sectional view illustrating a process following FIG. 13.

FIG. 15 is a cross-sectional view illustrating a process following FIG. 14.

FIG. 16 is a cross-sectional view illustrating a process following FIG. 15.

FIG. 17 is a cross-sectional view illustrating a process following FIG. 16.

FIG. 18 is a cross-sectional view illustrating a process following FIG. 17.

FIG. 19 is a cross-sectional view illustrating a process following FIG. 18.

FIG. 20 is a cross-sectional view illustrating a process following FIG. 19.

FIG. 21 is a cross-sectional view illustrating a process following FIG. 20.

FIG. 22 is a cross-sectional view illustrating a process following FIG. 21.

FIG. 23 is a cross-sectional view illustrating a process following FIG. 22.

FIG. 24 is a cross-sectional view illustrating a process following FIG. 23.

FIG. 25 is a cross-sectional view illustrating a process following FIG. 24.

FIG. 26 is a cross-sectional view illustrating a process following FIG. 25.

FIG. 27 is a timing chart illustrating operations of the pixel circuit illustrated in FIG. 2.

FIG. 28 is a circuit diagram illustrating an operation of the pixel circuit illustrated in FIG. 2.

FIG. 29 is a circuit diagram illustrating an operation of the pixel circuit illustrated in FIG. 2.

FIG. 30 is a circuit diagram illustrating an operation of the pixel circuit illustrated in FIG. 2.

FIG. 31 is a circuit diagram illustrating an operation of the pixel circuit illustrated in FIG. 2.

FIG. 32 is a circuit diagram illustrating an operation of the pixel circuit illustrated in FIG. 2.

FIG. 33 is a circuit diagram illustrating an operation of the pixel circuit illustrated in FIG. 2.

FIG. 34 is a plan view illustrating, in a display device according to a second embodiment of the present disclosure, a configuration in which the retention capacitor and the auxiliary capacitor illustrated in FIG. 2 are stacked.

FIG. 35 is a cross-sectional view along an XXXVA-XXXVA′ line in FIG. 34.

FIG. 36 is a cross-sectional view illustrating a method of manufacturing the display device illustrated in FIG. 35 in the order of procedure.

FIG. 37 is a cross-sectional view illustrating a process following FIG. 36.

FIG. 38 is a cross-sectional view illustrating a process following FIG. 37.

FIG. 39 is a cross-sectional view illustrating a process following FIG. 38.

FIG. 40 is a cross-sectional view illustrating a process following FIG. 39.

FIG. 41 is a cross-sectional view illustrating a process following FIG. 40.

FIG. 42 is a cross-sectional view illustrating a process following FIG. 41.

FIG. 43 is a cross-sectional view illustrating a process following FIG. 42.

FIG. 44 is a cross-sectional view illustrating a process following FIG. 43.

FIG. 45 is a plan view illustrating, in a display device according to a modification example 1, a configuration in which the retention capacitor and the auxiliary capacitor illustrated in FIG. 2 are stacked.

FIG. 46 is a cross-sectional view along an XLVIA-XLVIA′ line in FIG. 45.

FIG. 47 is a cross-sectional view illustrating a method of manufacturing the display device illustrated in FIG. 46 in the order of procedure.

FIG. 48 is a cross-sectional view illustrating a process following FIG. 47.

FIG. 49 is a cross-sectional view illustrating a process following FIG. 48.

FIG. 50 is a cross-sectional view illustrating a process following FIG. 49.

FIG. 51 is a cross-sectional view illustrating a process following FIG. 50.

FIG. 52 is a cross-sectional view illustrating a process following FIG. 51.

FIG. 53 is a cross-sectional view illustrating a process following FIG. 52.

FIG. 54 is a cross-sectional view illustrating a process following FIG. 53.

FIG. 55 is a cross-sectional view illustrating a process following FIG. 54.

FIG. 56 is a cross-sectional view illustrating a process following FIG. 55.

FIG. 57 is a plan view illustrating, in a display device according to a modification example 2, a configuration in which the retention capacitor and the auxiliary capacitor illustrated in FIG. 2 are stacked.

FIG. 58 is a cross-sectional view along an LVIIIA-LVIIIA′ line in FIG. 57.

FIG. 59 is a plan view illustrating, in a display device according to a modification example 3, a configuration in which the retention capacitor and the auxiliary capacitor illustrated in FIG. 2 are stacked.

FIG. 60 is a cross-sectional view along an LXA-LXA′ line in FIG. 59.

FIG. 61 is a cross-sectional view illustrating a method of manufacturing the display device illustrated in FIG. 60 in the order of procedure.

FIG. 62 is a cross-sectional view illustrating a process following FIG. 61.

FIG. 63 is a cross-sectional view illustrating a process following FIG. 62.

FIG. 64 is a cross-sectional view illustrating a process following FIG. 63.

FIG. 65 is a cross-sectional view illustrating a process following FIG. 64.

FIG. 66 is a cross-sectional view illustrating a process following FIG. 65.

FIG. 67 is a cross-sectional view illustrating a process following FIG. 66.

FIG. 68 is a cross-sectional view illustrating a process following FIG. 67.

FIG. 69 is a cross-sectional view illustrating a process following FIG. 68.

FIG. 70 is a cross-sectional view illustrating a process following FIG. 69.

FIG. 71 is a plan view illustrating, in a display device according to a modification example 4, a configuration in which the retention capacitor and the auxiliary capacitor illustrated in FIG. 2 are stacked.

FIG. 72 is a cross-sectional view along an LXXIIA-LXXIIA′ line in FIG. 71.

FIG. 73 is a plan view illustrating, in a display device according to a modification example 5, a configuration in which the retention capacitor and the auxiliary capacitor illustrated in FIG. 2 are stacked.

FIG. 74 is a cross-sectional view illustrating a configuration of one pixel of a display device according to a modification 6 of the present disclosure.

FIG. 75 is a plan view illustrating a configuration of an electrophoretic element as an example of a display element, in a display device according to a modification example 7 of the present disclosure.

FIG. 76 is a cross-sectional view illustrating a configuration of the electrophoretic element illustrated in FIG. 75.

FIG. 77 is a cross-sectional view illustrating a configuration of one pixel of a display device including the electrophoretic element illustrated in FIG. 76.

FIG. 78 is a cross-sectional view illustrating an operation of the display device illustrated in FIG. 77.

FIG. 79 is a plan view illustrating an overall configuration of a module including the display device of the above-described embodiment.

FIG. 80 is a perspective view illustrating an appearance of an application example 1.

FIG. 81 is a perspective view illustrating an appearance of an application example 2.

FIG. 82 is a perspective view illustrating an appearance of an application example 3.

### DETAILED DESCRIPTION

In the following, some embodiments of the present disclosure will be described in detail with reference to the accompanying drawings. It is to be noted that description will be made in the following order.

1. First Embodiment (an organic EL display device, double-gate type oxide TFTs; an example in which a first capacitive element is disposed on a display element side while a second capacitive element is disposed on a base side)

2. Second Embodiment (an organic EL display device, double-gate type oxide TFTs; an example in which the first capacitive element is disposed on the base side while the second capacitive element is disposed on the display element side)

3. Modification Example 1 (an organic EL display device, bottom-gate type oxide TFTs; an example in which an oxide semiconductor is used as an electrode of a capacitive element in the first embodiment)

4. Modification Example 2 (an organic EL display device, bottom-gate type oxide TFTs; an example in which the oxide semiconductor is used as the electrode of the capacitive element in the second embodiment)

5. Modification Example 3 (an organic EL display device, top-gate type oxide TFTs; an example in which the oxide semiconductor is used as the electrode of the capacitive element in the first embodiment)

6. Modification Example 4 (an organic EL display device, top-gate type oxide TFTs; an example in which the oxide semiconductor is used as the electrode of the capacitive element in the second embodiment)

7. Modification Example 5 (an organic EL display device, bottom-gate oxide TFTs; an example in which a top electrode of an upper capacitive element is connected to a shield electrode of a transistor)

8. Modification Example 6 (an example of a liquid crystal display device)

9. Modification Example 7 (an example of an electrophoretic display device)

10. Application Examples (electronic apparatuses)

### First Embodiment

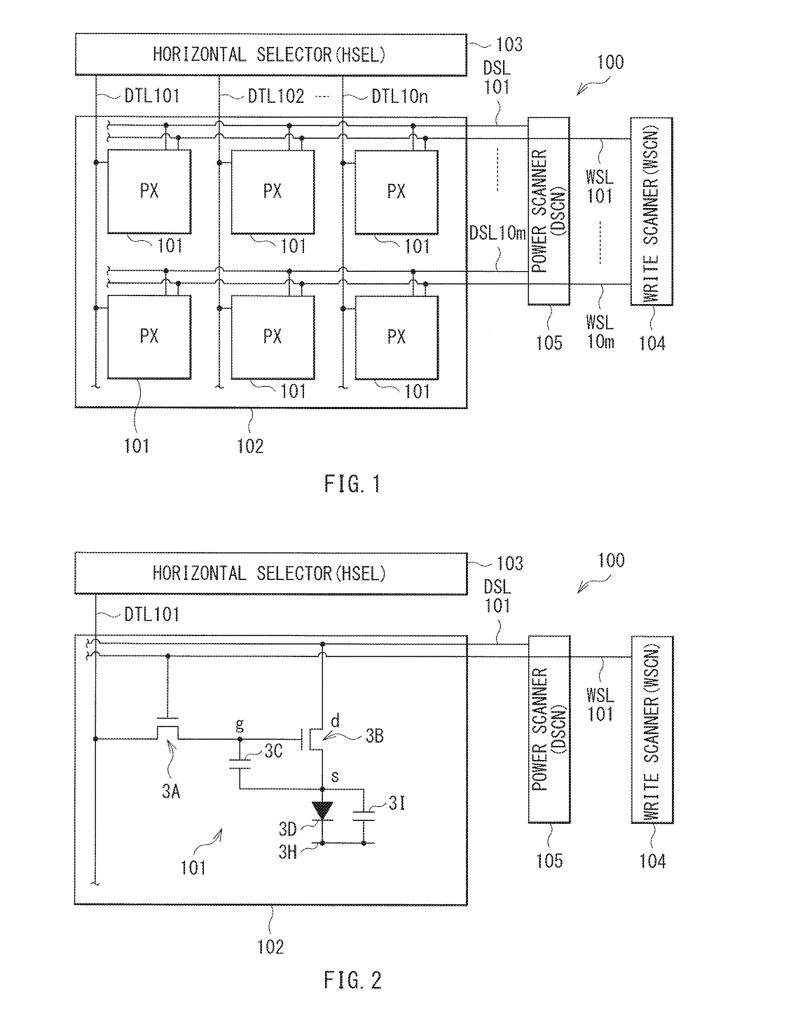

FIG. 1 illustrates an overall configuration of a display device 100 according to a first embodiment of the present disclosure. The display device 100 may include, for example, a pixel array section 102, and a drive section (a signal selector 103, a main scanner 104, and a power scanner 105) that is configured to drive the pixel array section 102.

The pixel array section 102 may include a plurality of pixels PX that are arranged in a matrix, and power lines DSL101 to 10m that are disposed in correspondence with respective rows of the plurality of pixels PX. Each of the pixels PX may be disposed at an intersection of scan lines WSL101 to 10m in rows and signal lines DTL101 to 10n in columns, and may have a pixel circuit 101.

The main scanner (a write scanner WSCN) 104 is configured to supply a control signal to the scan lines WSL101 to 10m in turn, performing line sequential scanning of the pixels PX in units of rows. The power scanner (DSCN) 105 is configured to supply a power supply voltage that is switched between a first potential and a second potential, to the power lines DSL101 to 10m in accordance with the line sequential scanning. The signal selector (a horizontal selector HSEL) 103 is configured to supply a signal potential that serves as a picture signal and a reference potential to the signal lines DTL101 to 10n in columns in accordance with the line sequential scanning.

FIG. 2 illustrates one example of a specific configuration and a connection relation of the pixel circuit 101 illustrated in FIG. 1. The pixel circuit 101 may include, for example, a light emitting element 3D that is typified by an organic EL display element, a sampling transistor 3A, a drive transistor 3B, a retention capacitor 3C, and an auxiliary capacitor 3I.

The sampling transistor 3A may have a gate, a source, and a drain. The gate may be connected to the associated scan line WSL101. One of the source and the drain may be connected to the associated signal line DTL101. Another of the source and the drain may be connected to a gate g of the drive transistor 3B.

The drive transistor 3B may have the gate g, a source s and a drain d. One of the source s and the drain d may be connected to the light emitting element 3D. Another of the source s and the drain d may be connected to the associated power line DSL101. In this embodiment, the drain d of the drive transistor 3B may be connected to the power line DSL101, while the source s may be connected to an anode of the light emitting element 3D. A cathode of the light emitting element 3D may be connected to a ground wiring 3H. It is to be noted that the ground wiring 3H may be wired commonly to all the pixels PX.

The retention capacitor 3C may be connected between the source s and the gate g of the drive transistor 3B. The retention capacitor 3C is configured to retain the signal potential of the picture signal that is supplied from the signal line DTL101, and is related to correction functions of the pixel circuit 101, which will be described below. Here, the “retention capacitor 3C” corresponds to a specific example of a “first capacitive element” of the present disclosure.

The auxiliary capacitor 3I may correspond to a capacitor component of the light emitting element 3D, and may be connected between the source s of the drive transistor 3B and the ground wiring 3H (the cathode of the light emitting element 3D), in parallel with the light emitting element 3D. By providing the auxiliary capacitor 3I separately from the light emitting element 3D, as will be described below, it is possible to restrain influences of variation of driving of the drive transistor 3B, enhancing the correction ability of the pixel circuit 101. Here, the “auxiliary capacitor 3I” corresponds to a specific example of a “second capacitive element” of the present disclosure.

The pixel circuit 101 may have, for example, a threshold voltage correction function, a mobility correction function, and a boot strap function.

First, description will be given on the threshold voltage correction function. For example, the sampling transistor 3A becomes conductive in response to the control signal supplied from the scan line WSL101, samples the signal potential supplied from the signal line DTL101, and allows the retention capacitor 3C to retain the sampled signal potential. The drive transistor 3B receives supply of currents from the power line DSL101 at the first potential, and allows a drive current to flow in the light emitting element 3D according to the signal potential retained by the retention capacitor 3C. The power scanner (DSCN) 105 switches the power line DSL101 between the first potential and the second potential, while the signal selector (HSEL) 103 supplies the reference potential to the signal line DTL101 after the sampling transistor 3A becomes conductive. Thus, the retention capacitor 3C is allowed to retain a potential corresponding to a threshold voltage Vth of the drive transistor 3B. By the threshold voltage correction function as described above, in the display device 100, it is possible to cancel influences of the threshold voltage of the drive transistor 3B that tends to vary for each of the pixels PX.

Next, description will be given on the mobility correction function. Specifically, the signal selector (HSEL) 103 switches the signal line DTL101 at a first timing from the reference potential to the signal potential, after the sampling transistor 3A becomes conductive. On the other hand, the main scanner (WSCN) 104 releases application of the control signal to the scan line WSL101 at a second timing after the first timing, allowing the sampling transistor 3A to become a non-conductive state. By setting an appropriate period between the first and the second timings, correction with respect to mobility μ of the drive transistor 3B is applied to the signal potential, in allowing the retention capacitor 3C to retain the signal potential. In this case, the drive section (the signal selector 103, the main scanner 104, and the power scanner 105) adjusts a relative difference in phase between the picture signal supplied by the signal selector 103 and the control signal supplied by the main scanner 104, making it possible to optimize the period between the first and the second timings (a mobility correction period). Moreover, the signal selector 103 may provide an inclination at a rising of the picture signal switched from the reference potential to the signal potential, allowing the mobility correction period between the first and the second timings to automatically follow the single potential.

Subsequently, description will be given on the boot strap function. Specifically, the main scanner (WSCN) 104 releases application of the control signal to the scan line WSL101 at a phase where the signal potential is retained by the retention capacitor 3C, and allows the sampling transistor 3A to become a non-conductive state, disconnecting electrically the gate g of the drive transistor 3B from the signal line DTL101. In this way, a gate potential (Vg) is allowed to change according to variation of a source potential (Vs) of the drive transistor 3B, making it possible to keep a voltage Vgs between the gate g and the source s constant.

In some cases, the above-described functions of the pixel circuit 101 may be affected by variations in driving of the drive transistor 3B. For example, at the time of a boot strap operation, the variations in driving of the drive transistor 3B may cause variations in gain, resulting in influences on luminance. Such variations in driving of the drive transistor 3B may be caused by variations in transistor size due to etching variations in a plane in a manufacturing process, or non-uniformity in a plane of a channel material, and so on. In the present embodiment, by providing the auxiliary capacitor 3I in addition to the retention capacitor 3C, it is possible to restrain influences on display quality and to enhance the correction functions of the pixel circuit 101, even when there are variations in driving of the drive transistor 3B.

Here, in promoting micronization of a pixel pitch accompanying higher definition (an increase in the number of pixels) and downsizing of a display device, area per one pixel PX is becoming smaller and smaller. It is therefore desirable that the retention capacitor 3C and the auxiliary capacitor 3I be arranged within as small layout area as possible.

In the following, description will be given on some examples regarding an arrangement configuration of the retention capacitor 3C and the auxiliary capacitor 3I in the pixel circuit 101.

### (Example of Planar Arrangement, Part 1, Bottom-Gate Configuration)

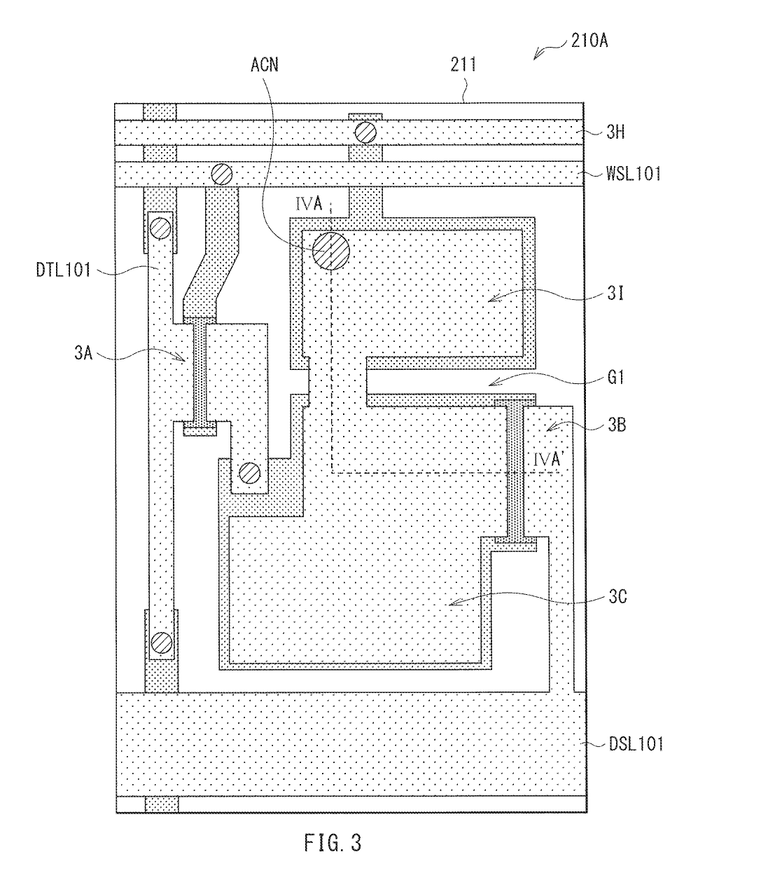

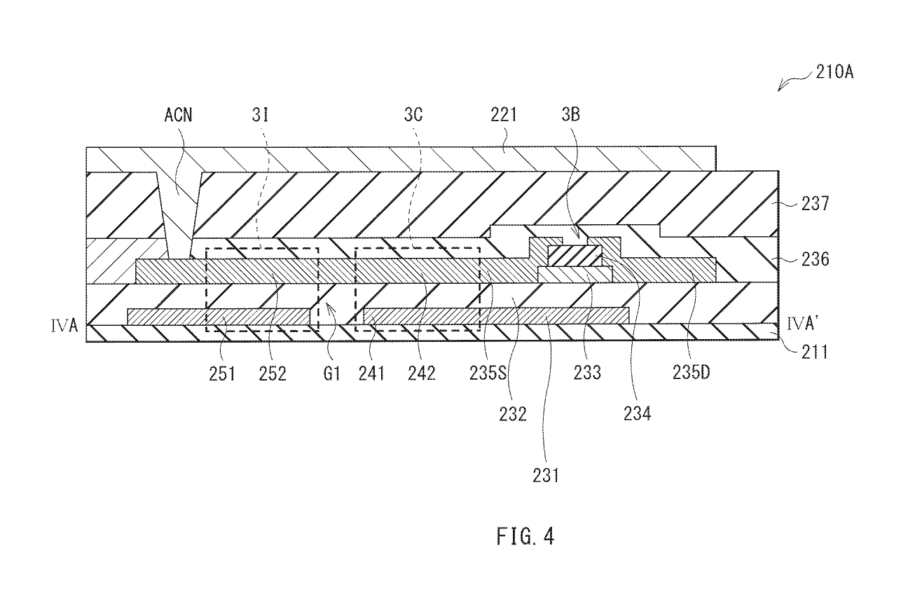

FIG. 3 illustrates an example of a planar arrangement configuration of the retention capacitor 3C and the auxiliary capacitor 3I illustrated in FIG. 2. FIG. 4 illustrates a cross-sectional configuration along an IVA-IVA′ line in FIG. 3. A substrate 210A may have a configuration in which, for example, on a base 211, the drive transistor 3B, the retention capacitor 3C, and the auxiliary capacitor 3I are arranged side by side in a plane.

The drive transistor 3B may be a bottom-gate type thin film transistor including, on the base 211 made of glass or the like, a gate electrode 231, a gate insulating film 232, a semiconductor layer 233, a stopper layer 234, a source electrode 235S and a drain electrode 235D, and a passivation layer 236 in this order. A surface of the substrate 210A on which the drive transistor 3B and so forth are formed may be planarized by a planarization layer 237. An anode electrode 221 (the anode of the light emitting element 3D) may be connected to the source electrode 235S.

The retention capacitor 3C may include, on the base 211, a bottom electrode 241, the gate insulating film 232, and a top electrode 242. The bottom electrode 241 of the retention capacitor 3C may be provided on a same layer as the gate electrode 231, and may be integral and continuous with the gate electrode 231. The top electrode 242 of the retention capacitor 3C may be provided on a same layer as the source electrode 235S, and may be integral and continuous with the source electrode 235S.

The auxiliary capacitor 3I may include, on the base 211, a bottom electrode 251, the gate insulating film 232, and a top electrode 252. The bottom electrode 251 of the auxiliary capacitor 3I may be provided on the same layer as the gate electrode 231, but may be uncontinuous with the gate electrode 231 and the bottom electrode 241 of the retention capacitor 3C. That is, the bottom electrode 251 of the auxiliary capacitor 3I may be provided as a separate layer from the gate electrode 231 and the bottom electrode 241 of the retention capacitor 3C. The top electrode 252 of the auxiliary capacitor 3I may be provided on the same layer as the source electrode 235S, and may be integral and continuous with the source electrode 235S.

It is to be noted that FIG. 4 represents a layer configuration from the base 211 to the anode electrode 221 of the light emitting element 3D, and layers above the anode electrode 221 of the light emitting element 3D are omitted. Out of the layers illustrated in FIG. 4, FIG. 3 represents the following layers: the base 211, the gate electrode 231, the bottom electrodes 241 and 251 that are on the same layer as the gate electrode 231, the semiconductor layer 233, the source electrode 235S and the drain electrode 235D, the top electrodes 242 and 252 that are on the same layer as the source electrode 235S and the drain electrode 235D, an anode contact ACN between the source electrode 235S and the anode electrode 211.

In the substrate 210A, the retention capacitor 3C and the auxiliary capacitor 3I are arranged side by side in a plane on the base 211. This contributes to reduction in short circuit defects and an enhanced yield. On the other hand, there is a loss of layout in a separation band G1 between the bottom electrode 241 of the retention capacitor 3C and the bottom electrode 251 of the auxiliary capacitor 3I.

### (Example of Planar Arrangement, Part 2, Double-Gate Configuration)

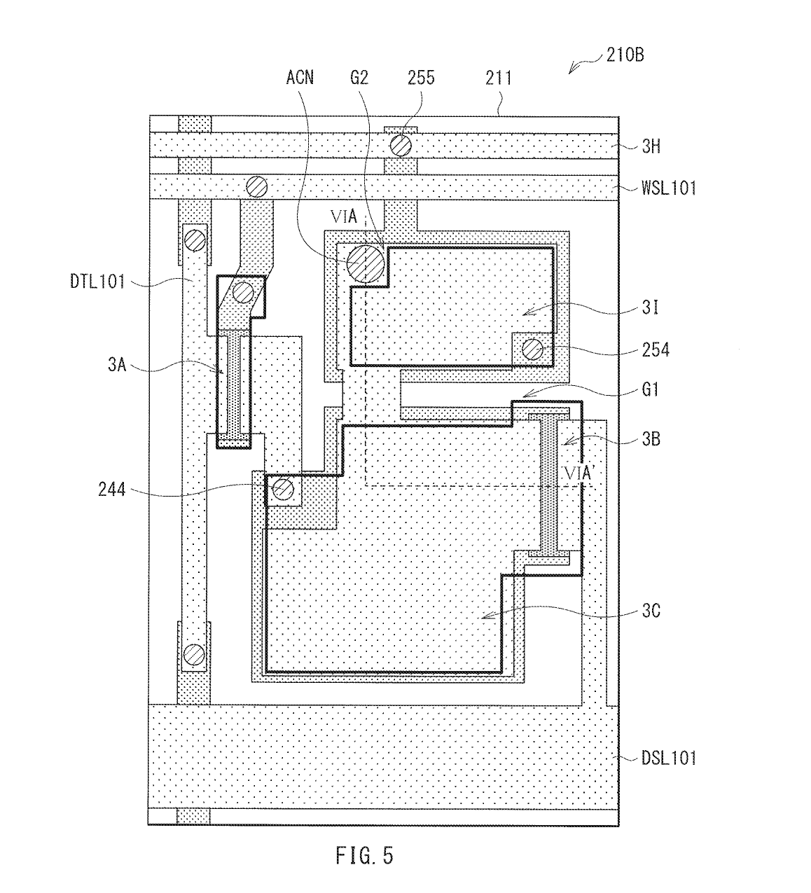

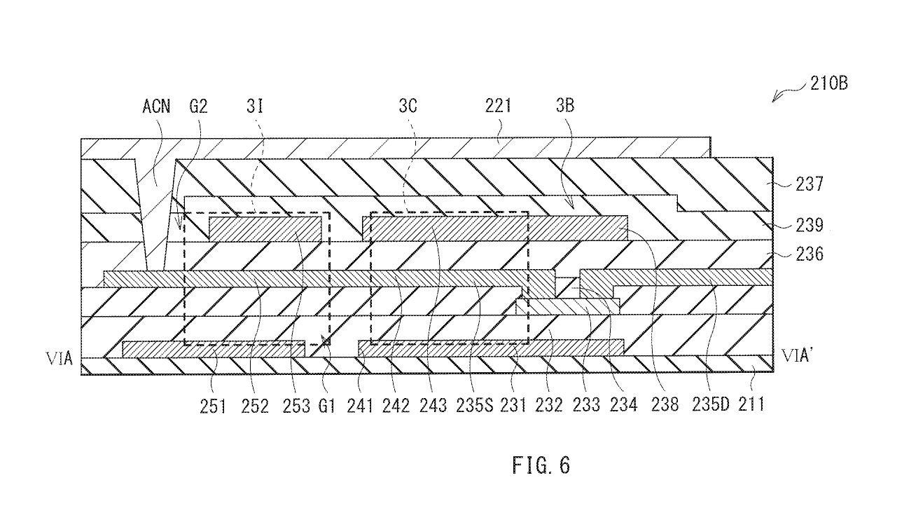

FIG. 5 illustrates another example of the planar arrangement configuration of the retention capacitor 3C and the auxiliary capacitor 3I illustrated in FIG. 2. FIG. 6 illustrates a cross-sectional configuration along a VIA-VIA′ line in FIG. 5. A substrate 210B may have a same configuration as that of the substrate 210A, except that the drive transistor 3B is of a double-gate type, that the retention capacitors 3C are doubly stacked, and that the auxiliary capacitors 3I are doubly stacked. In other words, the substrate 210B may have a similar configuration to that of the substrate 210A, in which the drive transistor 3B, the retention capacitor 3C, and the auxiliary capacitor 3I are arranged side by side in a plane on the base 211.

The drive transistor 3B may be a double-gate type thin film transistor including, on the base 211 made of glass or the like, a lower gate electrode 231, the gate insulating film 232, the semiconductor layer 233, the stopper layer 234, the source electrode 235S and the drain electrode 235D, a first passivation layer 236, an upper gate electrode 238, and a second passivation layer 239 in this order. A surface of the substrate 210B on which the drive transistor 3B and so forth are formed may be planarized by the planarization layer 237. The anode electrode 221 (the anode of the light emitting element 3D) may be connected to the source electrode 235S.

The retention capacitor 3C may include, on the base 211, a first bottom electrode 241, the gate insulating film 232 and the stopper layer 234, the top electrode 242, the first passivation layer 236, and a second bottom electrode 243. The first bottom electrode 241 and the second bottom electrode 243 may be connected to each other through a contact 244 illustrated in FIG. 5. The first bottom electrode 241 of the retention capacitor 3C may be connected to the lower gate electrode 231 (the gate g of the drive transistor 3B). The top electrode 242 of the retention capacitor 3C may be connected to the source electrode 235S (the source s of the drive transistor 3B). The second bottom electrode 243 may be connected to the upper gate electrode 238 (the gate g of the drive transistor 3B).

The auxiliary capacitor 3I may include, on the base 211, a first bottom electrode 251, the gate insulating film 232 and the stopper layer 234, the top electrode 252, the first passivation layer 236, and a second bottom electrode 253. The first bottom electrode 251 and the second bottom electrode 253 may be connected to each other through a contact 254 illustrated in FIG. 5. The first bottom electrode 251 of the auxiliary capacitor 3I may be provided on a same layer as the lower gate electrode 231, but may be uncontinuous with the lower gate electrode 231 and the bottom electrode 241 of the retention capacitor 3C. That is, the first bottom electrode 251 of the auxiliary capacitor 3I may be provided as a separate layer from the lower gate electrode 231 and the bottom electrode 241 of the retention capacitor 3C. The top electrode 252 of the auxiliary capacitor 3I may be connected to the source electrode 235S (the source s of the drive transistor 3B). The second bottom electrode 253 of the auxiliary capacitor 3I may be provided on a same layer as the upper gate electrode 238, but may be uncontinuous with the upper gate electrode 238 and the second bottom electrode 243 of the retention capacitor 3C. That is, the second bottom electrode 253 may be provided as a separate layer from the upper gate electrode 238 and the second bottom electrode 243 of the retention capacitor 3C. The first bottom electrode 251 and the second bottom electrode 253 of the auxiliary capacitor 3I may be connected to each other through the contact 254 (refer to FIG. 5). The first bottom electrode 251 and the second bottom electrode 253 may also be connected to the ground wire 3H and the cathode of the light emitting element 3D through a contact 255 (refer to FIG. 5).

It is to be noted that FIG. 6 represents a layer configuration from the base 211 to the anode electrode 221, and layers above the anode electrode 221 are omitted. Out of the layers illustrated in FIG. 6, FIG. 5 represents the following layers: the base 211, the lower gate electrode 231, the first bottom electrodes 241 and 251 that are on the same layer as the lower gate electrode 231, the semiconductor layer 233, the source electrode 235S and the drain electrode 235D, the top electrodes 242 and 252 that are on the same layer as the source electrode 235S and the drain electrode 235D, the upper gate electrode 238, the second bottom electrodes 243 and 253 that are on the same layer as the upper gate electrode 238, the anode contact ACN between the source electrode 235S and the anode electrode 221.

In the substrate 210B, similarly to the substrate 210A, there is a loss of layout in the separation band G1 between the first bottom electrode 241 of the retention capacitor 3C and the first bottom electrode 251 of the auxiliary capacitor 3I. Moreover, in addition, the substrate 210B is provided with the contact 254 (refer to FIG. 5) that connects the first bottom electrode 251 and the second bottom electrode 253 of the auxiliary capacitor 3I, and a separation band G2 between the anode contact ACN and the second bottom electrodes 243 and 253. Therefore, there is a possibility of an increase in the loss of layout, causing difficulties in obtaining large capacity.

### (Example of Stacked Arrangement)

As described above, in a case that the retention capacitor 3C and the auxiliary capacitor 3I are arranged side by side in a plane, it is difficult to eliminate the separation band G1 between the bottom electrode 241 of the retention capacitor 3C and the bottom electrode 251 of the auxiliary capacitor 3I. The present embodiment involves a substrate 10 in which a plurality of capacitive elements Cn are stacked on a base 11 vertically (in a direction of thickness of the base 11). Thus, the separation band G1 becomes unnecessary, making it possible to enhance layout efficiency. In the following, description will be given on the substrate 10 of the present embodiment.

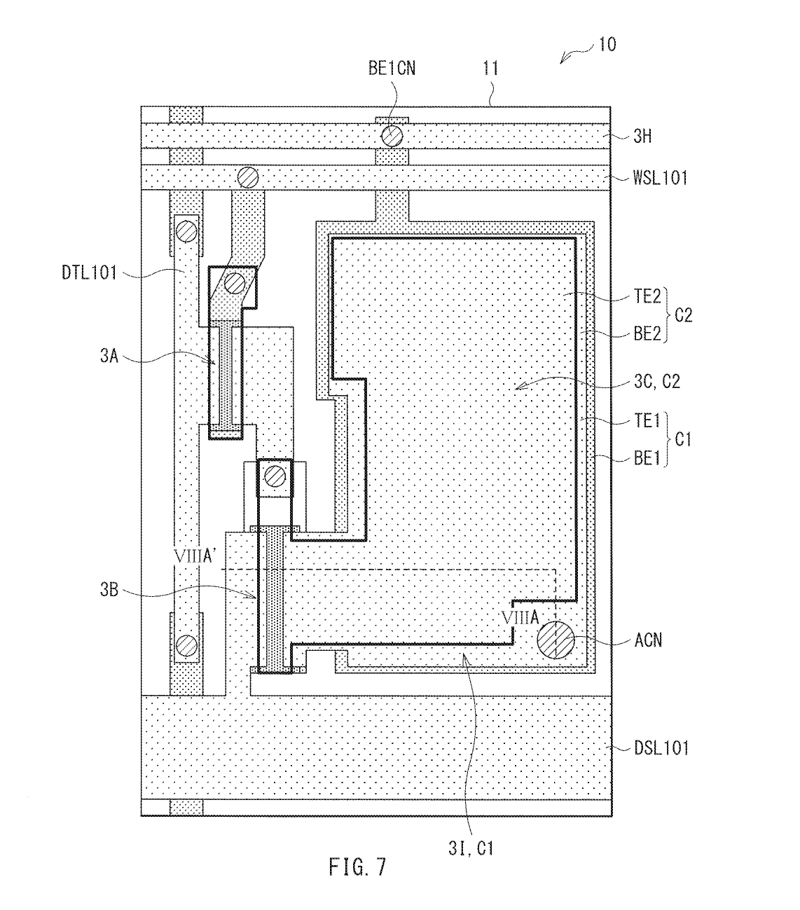

FIG. 7 illustrates an example in which the substrate 10 according to the present embodiment is applied to the planar arrangement configuration of the retention capacitor 3C and the auxiliary capacitor 3I illustrated in FIG. 2. FIG. 8 illustrates a cross-sectional configuration along a VIIIA-VIIIA′ line in FIG. 7. The substrate 10 includes the plurality of capacitive elements Cn on the base 11. The plurality of capacitive elements Cn are stacked on the base 11 in the direction of thickness of the base 11, and are different in position in a stacking direction Z. The plurality of capacitive elements Cn may include, for example, a lower capacitive element C1, an upper capacitive element C2, and an uppermost capacitive element C3 from the base 11 side in this order.

Further, the substrate 10 may preferably include a thin film transistor 30 on a side of the base 11 on which the plurality of capacitive elements Cn are provided. This makes it possible to apply the pixel circuit 101 illustrated in FIG. 2 to the plurality of capacitive elements Cn and the thin film transistor 30, attaining a use for a TFT array substrate for active matrix drive of the display device 100.

The thin film transistor 30 may be a double-gate type thin film transistor including, on the base 11 made of glass or the like, a lower gate electrode 31, a gate insulating film 32, a semiconductor layer 33, a stopper layer 34, a source electrode 35S and a drain electrode 35D, a first passivation layer 36, an upper gate electrode 38, and a second passivation layer 39 in this order. A surface of the substrate 10 on which the thin film transistor 30 is formed may be planarized by a planarization layer 37. It is to be noted that the thin film transistor 30 illustrated in FIG. 8 may correspond to the drive transistor 3B illustrated in FIG. 7, and an anode electrode 21 (the anode of the light emitting element 3D) may be connected to the source electrode 35S.

The lower capacitive element C1 may include, on the base 11, a bottom electrode BE1, the gate insulating film 32 and the stopper layer 34, and a top electrode TE1. The bottom electrode BE1 of the lower capacitive element C1 may be provided on a same layer as the lower gate electrode 31, but may be uncontinuous with the lower gate electrode 31. That is, the bottom electrode BE1 of the lower capacitive element C1 may be provided as a separate layer from the lower gate electrode 31. It is to be noted that the bottom electrode BE1 of the lower capacitive element C1 may be connected to the ground wiring 3H and the cathode of the light emitting element 3D through a contact BE1CN (refer to FIG. 7). The top electrode TE1 of the lower capacitive element C1 may be connected to the source electrode 35S (the source s of the drive transistor 3B).

In other words, the lower capacitive element C1 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

The upper capacitive element C2 may include, on the base 11, a bottom electrode BE2, the first passivation layer 36, and a top electrode TE2. The bottom electrode BE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be connected to the upper gate electrode 38 (the gate g of the drive transistor 3B).

In other words, the upper capacitive element C2 may be connected between the source s and the gate g of the drive transistor 3B, and may serve as the retention capacitor 3C in the pixel circuit 101 illustrated in FIG. 2.

As described above, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected to one another, but are connected to, for example, their respective wirings that are different from one another. Thus, in the substrate 10 and in the display device 100 including the substrate 10, it is possible to stack the plurality of capacitive elements C1 to C3 having different operations and functions, leading to enhanced layout efficiency.

Preferably, the lower capacitive element C1 and the upper capacitive element C2 may be capable of maintaining different potentials from one another. In this way, it is possible to allow the lower capacitive element C1 and the upper capacitive element C2 to have separate functions and roles. That is, by stacking, on the base 11, the lower capacitive element C1 and the upper capacitive element C2 having different functions from one another, it is possible to reduce area of the pixel PX and to provide sufficiently high capacitance in small layout area, attaining enhancement in performances of the pixel circuit 101. This promotes pursuit of high definition, micronization of a pixel pitch, and enhancement in capacitance.

Moreover, preferably, a charge and discharge period of the lower capacitive element C1 and a charge and discharge period of the upper capacitive element C2 may be different from one another. In the pixel circuit 101 illustrated in FIG. 2, as will be described later, the retention capacitor 3C and the auxiliary capacitor 3I are configured to perform charge and discharge operations in different periods from one another. By allowing the charge and discharge period of the lower capacitive element C1 (for example, the auxiliary capacitor 3I in the present embodiment) and the charge and discharge period of the upper capacitive element C2 (for example, the retention capacitor 3C in the present embodiment) to be different from one another, it is possible to cope with such driving of the pixel circuit 101.

Furthermore, as described above, since the lower capacitive element C1 serves as the auxiliary capacitor 3I while the upper capacitive element C2 serves as the retention capacitor 3C, it is possible to restrain an increase in the number of contacts, enhancing layout efficiency.

The uppermost capacitive element C3 may include, on the base 11, a bottom electrode BE3, the second passivation layer 39 and the planarization layer 37, and a top electrode TE3. The bottom electrode BE3 of the uppermost capacitive element C3 may be common to the top electrode TE2 of the upper capacitive element C2, and may be connected to the upper gate electrode 38 (the gate g of the drive transistor 3B). The top electrode TE3 of the uppermost capacitive element C3 may be the anode electrode 21 (the anode of the light emitting element 3D).

In other words, the uppermost capacitive element C3 may be connected between the source s and the gate g of the drive transistor 3B, and may serve as the retention capacitor 3C in the pixel circuit 101 illustrated in FIG. 2. By providing the uppermost capacitive element C3, it is possible to supplement the retention capacitor 3C, further enhancing the correction functions of the pixel circuit 101.

It is to be noted that FIG. 8 represents a layer configuration from the base 11 to the anode electrode 21, and layers above the anode electrode 21 are omitted. Out of the layers illustrated in FIG. 8, FIG. 7 represents the following layers: the base 11, the lower gate electrode 31 and the bottom electrode BE1 that is on the same layer as the lower gate electrode 31, the semiconductor layer 33, the source electrode 35S and the drain electrode 35D, the top electrode TE1 and the bottom electrode BE2 that are on the same layer as the source electrode 35S and the drain electrode 35D, the upper gate electrode 38 and the top electrode TE2 that is on the same layer as the upper gate electrode 38, and the anode contact ACN between the source electrode 35S and the anode electrode 21.

In the following, description will be given regarding materials of the base 11 and layers of the thin film transistor 30 of the substrate 10.

The base 11 may be configured of a glass substrate or a plastic film. Examples of plastic materials may include PET (polyethylene terephthalate), PEN (polyethylene naphthalate), or the like. Since in a sputtering method that will be mentioned later, an oxide semiconductor layer that will eventually serve as the semiconductor layer 33 is formed without heating the base 11, it is possible to use a low-cost plastic film. Moreover, the base 11 may be a metal substrate such as stainless steel (SUS) depending on purposes.

The lower gate electrode 31 may be provided in a selective region on the base 11, and is configured to control a carrier density (here, an electron density) in the semiconductor layer 33 by a gate voltage applied to the thin film transistor 30. The lower gate electrode 31 may have a thickness of, for example, 10 nm to 500 nm, specifically about 500 nm. The lower gate electrode 31 may be configured of a single-layered film made of one kind of a low-resistance metal such as aluminum (Al) or copper (Cu), titanium (Ti), molybdenum (Mo), and so forth, or a stacked film made of two or more kinds thereof. Since the lower gate electrode 31 may have preferably low resistance, a low-resistance metal such as aluminum (Al) or copper (Cu) may be preferably used as a constituent material thereof. Moreover, the lower gate electrode 31 may preferably be a stacked film in which a low-resistance metal layer made of aluminum (Al) or copper (Cu) and a low-resistance oxide layer that is formed on a surface of the low-resistance metal layer and is made of an oxide such as ITO, IZO, or IGZO. In this case, preferably, a barrier-metal layer made of titanium (Ti) or molybdenum (Mo) may be interposed in order to obtain proper contact between the low-resistance metal layer and the low-resistance oxide layer.

The gate insulating film 32 may be configured of a single-layered film or a stacked film of a silicon oxide film, a silicon nitride film, a silicon nitride oxide film, an aluminum oxide film, or the like. Among these, the silicon oxide film or the aluminum oxide film may be preferable since they are less likely to reduce a channel region of the semiconductor layer 33.

The semiconductor layer 33 may be provided, on the gate insulating film 32, in an island shape including the lower gate electrode 31 and its vicinity, and may have a function as an active layer of the thin film transistor 30. The semiconductor layer 33 may be configured of, for example, an oxide semiconductor. Here, an oxide semiconductor refers to a compound including an element such as indium, gallium, zinc, tin, or the like, and oxygen. Specifically, examples of amorphous oxide semiconductors may include indium gallium zinc oxide (IGZO), indium tin zinc oxide (ITZO), or the like. Examples of crystalline oxide semiconductors may include zinc oxide (ZnO), indium zinc oxide (IZO (registered trademark)), indium gallium oxide (IGO), indium tin oxide (ITO), indium oxide (InO), or the like.

The stopper layer 34 may be provided on the channel region of the semiconductor layer 33, and may have a function of restraining damage to the semiconductor layer 33 in etching of the source electrode 35S and the drain electrode 35D. The stopper layer 34 may have a thickness of, for example, about 200 nm, and may be configured of a single-layered film or a stacked film of a silicon oxide film, a silicon nitride film, a silicon nitride oxide film, an aluminum oxide film, or the like. Among these, the silicon oxide film or the aluminum oxide film may be preferable since they are less likely to reduce the semiconductor layer 33 made of an oxide semiconductor.

The source electrode 35S and the drain electrode 35D may have a thickness of, for example, about 500 nm, and may be configured of a stacked film of a barrier metal such as molybdenum (Mo) or titanium (Ti) and aluminum (Al), copper (Cu), or the like. Moreover, the source electrode 35S and the drain electrode 35D may be preferably configured of a low-resistance metal layer such as aluminum (Al) or copper (Cu), similarly to the lower gate electrode 31. Further, a stacked film of combination of a low-resistance layer made of aluminum (Al) or copper (Cu) and a barrier layer made of titanium (Ti) or molybdenum (Mo) may be also preferable. The use of such a stacked film enables driving with little wiring delay.

The first passivation layer 36 is configured to restrain moisture from intruding or diffusing in the semiconductor layer 33 made of an oxide semiconductor, enhancing electrical stability and reliability of the thin film transistor 30. The first passivation layer 36 may have a thickness of, for example, about 200 nm, and may be configured of a single-layered film or a stacked film of a silicon nitride film, a silicon nitride oxide film, or the like.

The upper gate electrode 38 may have a similar configuration to, for example, that of the lower gate electrode 31. The second passivation layer 39 may have a similar configuration to, for example, that of the first passivation layer 36.

The planarization layer 37 is provided for planarization by reducing unevenness due to the plurality of capacitive elements Cn and the thin film transistor 30 on the substrate 10. The planarization layer 37 may have a thickness of, for example, about 2 μm, and may be configured of an organic insulating film including acryl, polyimide, siloxane, or the like as a material. Moreover, as the planarization layer 37, a stacked film of a silicon oxide film, a silicon nitride film, or an aluminum oxide film and an organic insulating film including acryl, polyimide, siloxane, or the like as a material may be also used. In particular, the use of a stacked film of a silicon oxide film and an aluminum oxide film for the planarization layer 37 makes it possible to restrain moisture from intruding or diffusing in the semiconductor layer 33 made of an oxide semiconductor, further enhancing electrical stability and reliability of the thin film transistor 30.

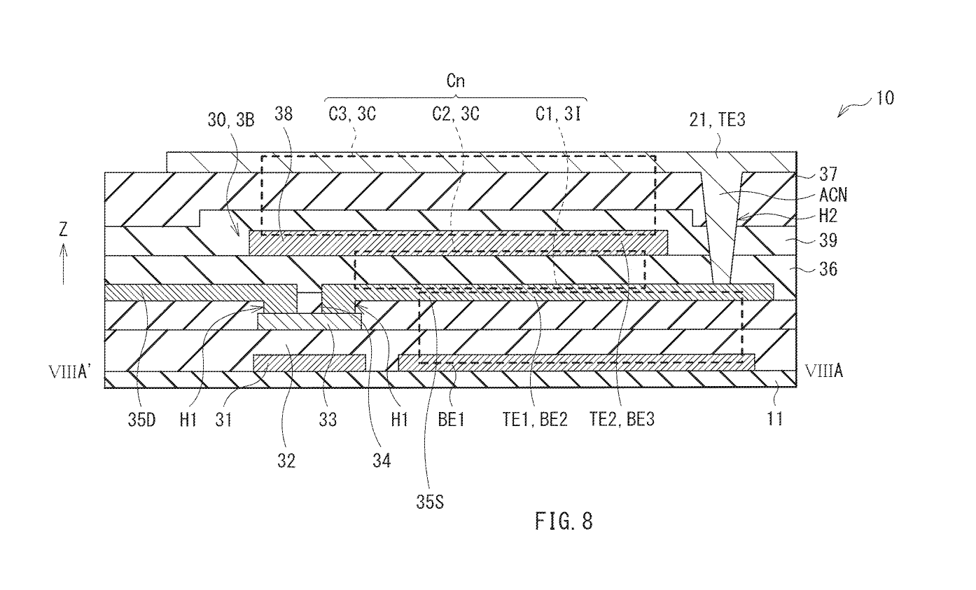

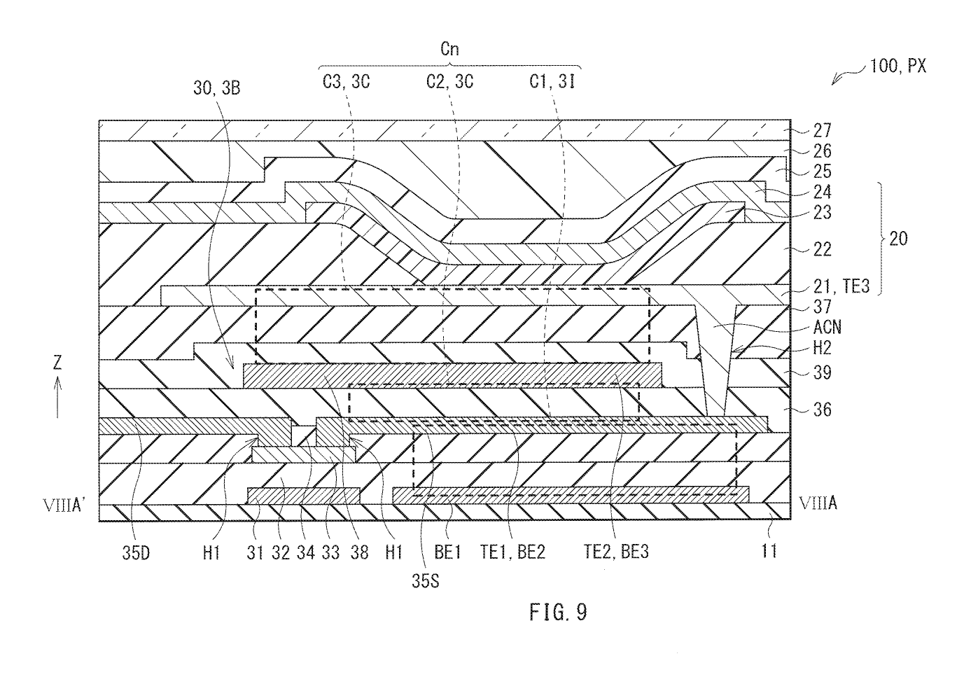

FIG. 9 illustrates a cross-sectional configuration of one pixel PX of the display device 100 including the substrate 10 illustrated in FIG. 8. The display device 100 may include, for example, a display element 20 on the substrate 10.

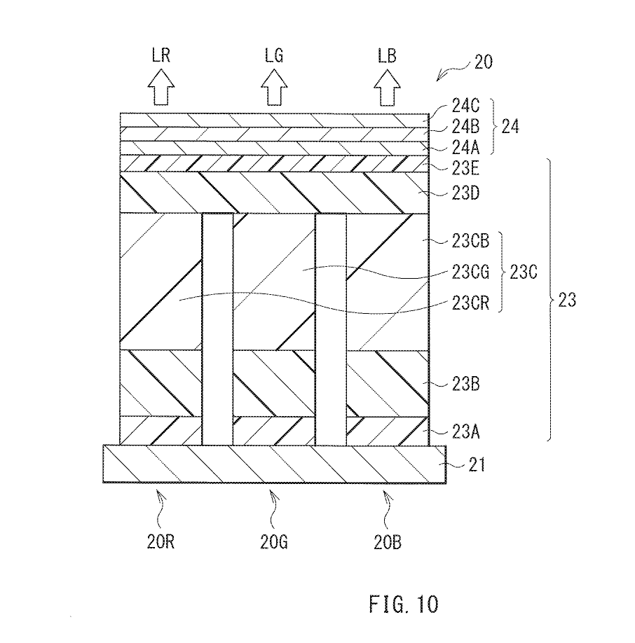

The display element 20 may be configured of, for example, an organic EL element, and may correspond to the light emitting element 3D illustrated in FIG. 2. Specifically, the display element 20 may be one of a red organic EL element 20R, a green organic EL element 20G, and a blue organic EL element 20B (refer to FIG. 10). The red organic EL element 20R is configured to generate red light. The green organic EL element 20G is configured to generate green light. The blue organic EL element 20B is configured to generate blue light.

The display element 20 may be provided on the planarization layer 37 of the substrate 10, and may have a configuration in which the anode electrode 21 (a first electrode), a barrier rib 22, an organic layer 23, and a cathode electrode 24 (a second electrode) are stacked in this order. The display element 20 may be an organic EL element of an upper surface emission type (of a top emission type) in which holes injected from the anode electrode 21 and electrons injected from the cathode electrode 24 recombine in a light emission layer 23C (to be described later) to generate emission light that is extracted on an opposite side from the substrate 10 (on the cathode electrode 24 side). The use of an organic EL element of an upper surface emission type makes it possible to enhance an aperture ratio of a light emitting section of the display device 100. It is to be noted that the display element 20 is not limited to an organic EL element of an upper surface emission type, but may be an organic EL element of a transparent type or a lower surface emission type (of a bottom emission type) in which light is extracted on the substrate 10 side.

The anode electrode 21 may be configured of a material of high reflectivity such as an aluminum-neodymium alloy, aluminum (Al), titanium (Ti), chromium (Cr), or the like, in a case that the display device 100 is, for example, of an upper surface emission type. Alternatively, in a case that the display device 100 is of a transparent type, a transparent material, for example, ITO, IZO (registered trademark), IGZO, or the like may be used for the anode electrode 21. The anode electrode 21 may be connected to the top electrode TE1 of the lower capacitive element C1 and the source electrode 35S, through a contact hole H2.

The barrier rib 22 may be configured of an organic material, for example, polyimide, novolac, or the like. The barrier rib 22 is also and is provided for obtaining sufficient insulation between the anode electrode 21 and the cathode electrode 24.

The organic layer 23 may have a configuration in which, for example, as illustrated in FIG. 10, a hole injection layer 23A, a hole transport layer 23B, the light emission layer 23C (a red light emission layer 23CR, a green light emission layer 23CG, and a blue light emission layer 23CB), an electron transport layer 23D, and an electron injection layer 23E are stacked in this order from the anode electrode 21 side. An upper surface of the organic layer 23 may be covered with the cathode electrode 24. The red light emission layer 23CR is configured to generate red light LR. The green light emission layer 23CG is configured to generate green light LG. The blue light emission layer 23CB is configured to generate blue light LB.

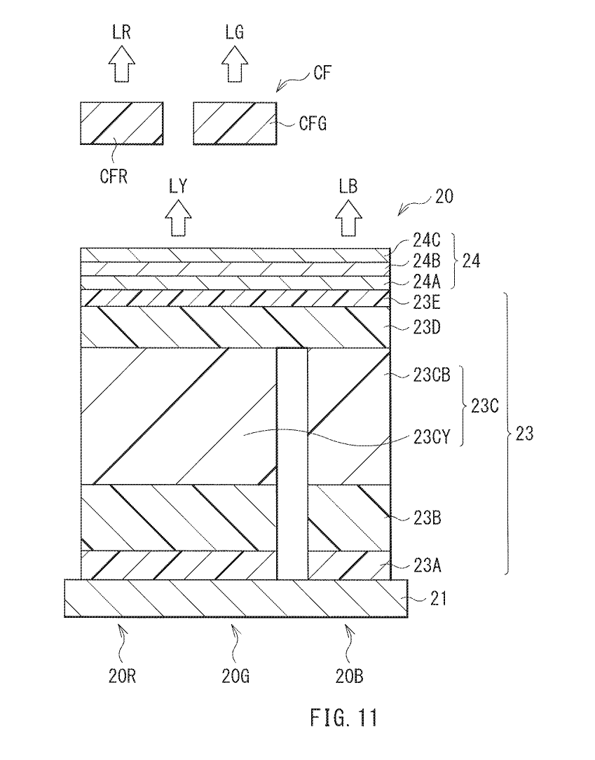

Alternatively, the organic layer 23 may have a configuration in which, for example, as illustrated in FIG. 11, the hole injection layer 23A, the hole transport layer 23B, the light emission layer 23C (a yellow light emission layer 23CY and the blue light emission layer 23CB), the electron transport layer 23D, and the electron injection layer 23E are stacked in this order from the anode electrode 21 side. In this case, the yellow light emission layer 23CY is configured to generate yellow light LY. The yellow light LY is configured to be color-separated into the red light LR and the green light LG by a color filter CF (a red filter CFR and a green filter CFG).

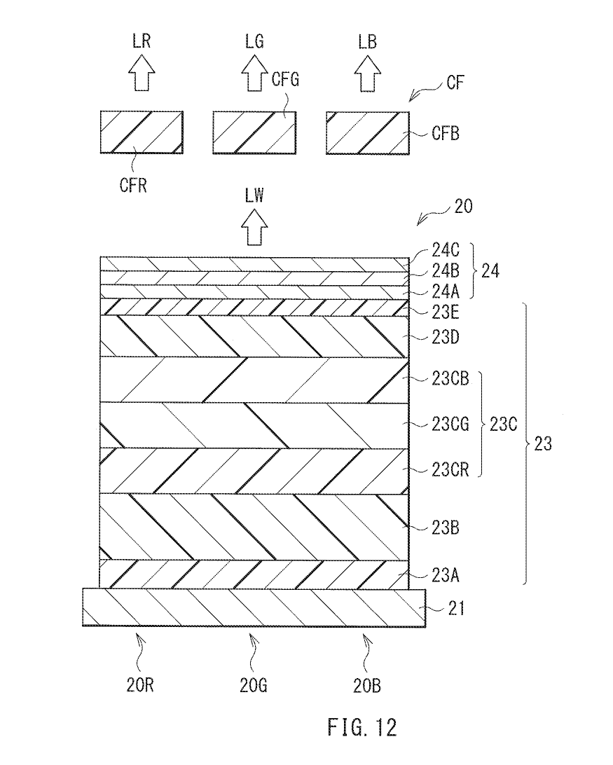

In another alternative, the light emission layer 23C may be a white light emission layer having a stacked configuration of, for example, as illustrated in FIG. 12, the red light emission layer 23CR, the blue light emission layer 23CB, and the green light emission layer 23CG. In this case, the light emission layer 23C is configured to generate white light LW. The white light LW is configured to be color-separated into the red light LR, the green light LG, and the blue light LB by the color filter CF (the red filter CFR, the green filter CFG, and a blue filter CFB).

It is to be noted that configurations of the organic layer 23 and the light emission layer 23C are not limited to examples illustrated in FIGS. 10 to 12. It goes without saying that the organic layer 23 and the light emission layer 23C may have other configurations.

In the organic layer 23, the hole injection layer 23A, the hole transport layer 23B, the electron transport layer 23D, and the electron injection layer 23E may be formed, for example, by a vacuum evaporation method, as common layers over the entire surface of the pixel array section 102 (refer to FIG. 1). On the other hand, the red light emission layer 23CR, the green light emission layer 23CG, and the yellow light emission layer 23CY may be formed for each color, for example, by a coating method. The blue light emission layer 23CB may be formed, for example, by a vacuum evaporation method, as a common layer over the entire surface of the pixel array section 102, or may be formed for each color, for example, by a coating method.

Thicknesses and constituent materials of the layers that constitute the organic layer 23 are not limited in particular, but examples may be as follows.

The hole injection layer 23A may be a buffer layer that is provided for enhancing hole injection efficiency into the light emission layer 23C and preventing leaks. A thickness of the hole injection layer 23A may be, for example, preferably 5 nm to 200 nm both inclusive, more preferably 8 nm to 150 nm both inclusive. A constituent material of the hole injection layer 23A may be selected appropriately in relation to the materials of the electrodes and adjacent layers. Examples may include polyaniline, polythiophene, polypyrrole, polyphenylene vinylene, poly(thienylene vinylene), polyquinoline, polyquinoxaline, and their derivatives, a conductive polymer such as a polymer that includes an aromatic amine structure in a main chain or in a side chain, metal phthalocyanine (such as copper phthalocyanine), carbon, and so forth. Examples of conductive polymers may include oligoaniline and polydioxythiophene such as poly(3,4-ethylenedioxythiophehe) (PEDOT).

The hole transport layer 23B is adapted to enhance a hole transport efficiency into the light emission layer 23C. A thickness of the hole transport layer 23B may be, for example, preferably 5 nm to 200 nm both inclusive, and more preferably 8 nm to 150 nm both inclusive, though it depends on the whole configuration of the element. As a constituent material of the hole transport layer 23B, a light emitting material that is soluble to an organic solvent may be adopted. Examples may include polyvinyl carbazole, polyfluorene, polyaniline, polysilane, or their derivatives, a polysiloxane derivative that includes an aromatic amine in a side chain or in a main chain, polythiophene and its derivatives, polypyrrole, Alq₃, and so forth.

In the light emission layer 23C, when an electric field is applied, there occurs recombination of holes and electrons, allowing light to be produced. A thickness of the light emission layer 23C may be, for example, preferably 10 nm to 200 nm both inclusive, and more preferably 20 nm to 150 nm both inclusive, though it depends on the whole configuration of the element. The light emission layer 23C may be a single layer or may have a laminated structure.

As a material of the light emission layer 23C, materials suitable for the respective light emission colors may be adopted. Examples may include a polyfluorene-based polymer derivative, a (poly)paraphenylene vinylene derivative, a polyphenylene derivative, a polyvinyl carbazole derivative, a polythiophene derivative, a pelylene-based pigment, a coumarin-based pigment, a rhodamine-based pigment, or the above-mentioned polymer doped with an organic EL material. Examples of materials to be doped may include rubrene, perylene, 9,10-diphenylanthracene, tetraphenyl butadiene, nile red, coumarin-6, and so forth. It is to be noted that the constituent materials of the light emission layer 23C may be a mixture of two or more kinds of the above-mentioned materials. The constituent materials of the light emission layer 23C are not limited to the above-mentioned materials of high molecular weight, but materials of low molecular weight may be used in combination. Examples of materials of low molecular weight may include benzene, styrylamine, triphenylamine, porphyrin, triphenylene, azatriphenylene, tetracyanoquinodimethane, triazole, imidazole, oxadiazole, polyaryl alkane, phenylenediamine, arylamine, oxazole, anthracene, fluorenone, hydrazone, stilbene, or their derivatives, or a monomer or an oligomer of a heterocyclic conjugated system such as a polysilane-based compound, a vinylcarbazole-based compound, a thiophene-based compound, or an aniline-based compound.

As the materials of the light emission layer 23C, in addition to the above-mentioned materials, a material having high light emission efficiency may be used as a light-emitting guest material. Examples may include an organic light emitting material such as a fluorescent material of low molecule weight, a phosphorescent pigment, or a metal complex.

It is to be noted that the light emission layer 23C may be a light emission layer having hole transporting property that also serves as the above-mentioned hole transport layer 23B. Alternatively, the light emission layer 23C may be a light emission layer having electron transporting property that also serves as the electron transport layer 23D, which will be described below.

The electron transport layer 23D and the electron injection layer 23E are adapted to enhance electron transport efficiency into the light emission layer 23C. A total thickness of the electron transport layer 23D and the electron injection layer 23E may be, for example, preferably 5 nm to 200 nm both inclusive, and more preferably 10 nm to 180 nm both inclusive, though it depends on the whole configuration of the element.

A material of the electron transport layer 23D may be preferably an organic material having excellent electron transporting performance. Enhancing the transport efficiency of the light emission layer 23C allows variation in light emission colors due to intensity of electric field to be restrained. Specifically, for example, an arylpyridine derivative and a benzoimidazole derivative may be preferably used. Thus, it is possible to maintain high electron supply efficiency at a low drive voltage. Examples of constituent materials of the electron injection layer 23E may include an alkali metal, an alkaline earth metal, a rare earth metal, and their oxides, composite oxides, fluorides, carbonates, and so forth.

The cathode electrode 24 may have a thickness of, for example, about 10 nm, and may be configured of a material having good light transmitting property and a small work function. Alternatively, a transparent conductive film using an oxide may allow the light extraction to be secured. In this case, ZnO, ITO, IZnO, InSnZnO, and so forth may be used. Furthermore, though the cathode electrode 24 may be a single layer, in examples illustrated in FIGS. 10 to 12, the cathode electrode 24 has a configuration in which, for example, a first layer 24A, a second layer 24B, and a third layer 24C are stacked in this order from the anode electrode 21 side.

The first layer 24A may be preferably configured of a material having a small work function and good light transmitting property. Specific examples may include an alkaline earth metal such as calcium (Ca), barium (Ba), or the like, an alkali metal such as lithium (Li), caesium (Cs), or the like, indium (In), magnesium (Mg), and silver (Ag). Furthermore, other examples may include an alkali metal oxide, an alkali metal fluoride, an alkaline earth metal oxide, an alkaline earth metal fluoride, specifically, Li₂O, Cs₂CO₃, Cs₂SO₄, MgF, LiF, CaF₂, or the like.

The second layer 24B may be configured of a material having light transmitting property and good electrical conductivity, such as a thin film Mg—Ag electrode or a Ca electrode. The third layer 24C may be preferably configured of a transparent lanthanoid-based oxide to restrain degradation of the electrode. This makes it possible to use the third layer 24C as a sealing electrode that allows light to be extracted through the upper surface. In the case of the bottom emission type, gold (Au), platinum (Pt), Au—Ge, or the like may be used for a material of the third layer 24C.

It is to be noted that the first layer 24A, the second layer 24B, and the third layer 24C may be formed by techniques such as a vacuum deposition method, a sputtering method, a plasma CVD (chemical vapor deposition) method, or the like. In a case that a driving method of the display device 100 is an active matrix method, the cathode electrode 24 may be formed as a continuous film on the substrate 10, constituting a common electrode to the display elements 20, in a state that the cathode electrode 24 is insulated from the anode electrode 21 by the barrier rib 22 and the organic layer 23.

The cathode electrode 24 may be a mixed layer that includes an organic light emitting material such as an aluminum quinoline complex, a styrylamine derivative, a phthalocyanine derivative. In this case, the cathode electrode 24 may further include an additional layer having light transmitting property such as Mg—Ag, as the third layer 24C (not illustrated). The cathode electrode 24 is not limited to the above-mentioned stacked structure, but it goes without saying that an optimum combination or stacked structure may be adopted according to the configuration of the device to be manufactured. For example, the configuration of the cathode electrode 24 according to the above-described present embodiment is a stacked structure of layers having respectively separated functions, in which an inorganic layer (the first layer 24A) that facilitates electron injection into the organic layer 23, an inorganic layer (the second layer 24B) that controls the electrode, and an inorganic layer (the third layer 24C) that protects the electrode are separated. However, the inorganic layer that facilitates electron injection into the organic layer 23 may also serve as the inorganic layer that controls the electrode. Alternatively, these layers may constitute a single layer.

Furthermore, in a case that the display element 20 has a cavity structure, the cathode electrode 24 may be preferably configured of a semitransparent and semireflecting material. This makes it possible to allow multiple interference of produced light between a light reflecting plane on the anode electrode 21 side and a light reflecting plane on the cathode electrode 24 side, allowing the light to be extracted on the cathode electrode 24 side. In this case, an optical distance between the light reflecting plane on the anode electrode 21 side and the light reflecting plane on the cathode electrode 24 side may be determined by a wavelength of the light to be extracted. The thickness of each layer may be assumed to be set to satisfy the optical distance. In such a display element of the upper surface light emission type, the positive use of the cavity structure allows improvement in the light extraction efficiency to the outside and the control of the light emission spectrum.

Above the display element 20, there may be provided, for example, a protective layer 25, an adhesive layer 26, and a sealing substrate 27, which are adapted to seal the display element 20 (a solid sealing structure).

The protective layer 25 is adapted to prevent moisture from intruding into the organic layer 23. The protective layer 25 may be configured of a material having low permeability and low water permeability and may have a thickness of, for example, 2 μm to 3 μm both inclusive. A material of the protective layer 25 may be either an insulating material or a conductive material. Examples of insulating materials may include inorganic amorphous insulating material such as amorphous silicon (α-Si), amorphous silicon carbide (α-SiC), amorphous silicon nitride (α-Si₁₋ₓNₓ), amorphous carbon (α-C), and so forth. Such inorganic amorphous insulating materials have low water permeability since they do not constitute grains, making a good protective film.

The sealing substrate 27 may be disposed on the cathode electrode 24 side of the display element 20, and is adapted to seal the display element 20 together with the adhesive layer 26. The sealing substrate 27 may be configured of a transparent material with respect to the light produced in the display element 20, specifically, glass, or the like. The sealing substrate 27 may be provided with, for example, a color filter and a light shielding film as a black matrix (both not illustrated), allowing the light produced in the display element 20 to be extracted and absorbing external light that is reflected by wirings between the display elements 20 to improve contrast.

The color filter may include the red filter, the green filter, and the blue filter (neither illustrated), which are arranged in order. The red filter, the green filter, and the blue filter are formed in, for example, a square shape with little space between them. The red filter, the green filter, and the blue filter each may be configured of a resin mixed with a pigment. Selection of a pigment allows adjustment of light transmitting property so that light transmittance in a target wavelength region, i.e. red, green, or blue, is high while light transmittance in other wavelength regions are low.

The light shielding film may be configured of a black resin film that is mixed with, for example, a black colorant and has an optical density of 1 or more, or a thin film filter that utilizes interference in thin films. Among them, the configuration with the black resin film may be preferable, allowing low-cost and easy fabrication. The thin film filter may have, for example, a lamination of one or more layers of thin films that are configured of a metal, a metal nitride, or a metal oxide, allowing light to be attenuated utilizing interference in thin films. Specific examples of the thin film filters may include an alternate lamination of chromium (Cr) and chromium (III) oxide (Cr₂O₃).

The substrate 10 and the display device 100 including the substrate 10 may be manufactured, for example, as follows.

### (Processes to Form the Substrate 10)

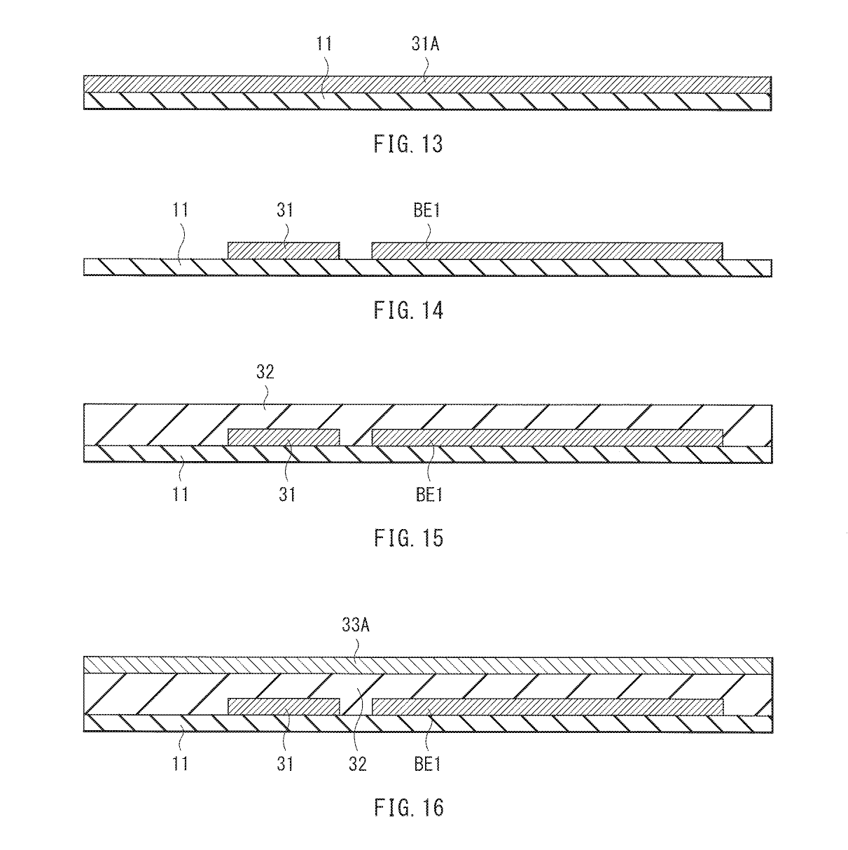

FIGS. 13 to 26 illustrate a method of manufacturing the substrate 10 in the order of procedure. First, as illustrated in FIG. 13, the base 11 that is configured of the above-mentioned material is prepared. On the base 11, a conductive material film 31A is formed by, for example, a sputtering method. As the conductive material film 31A, for example, a laminated film of an oxide semiconductor layer such as ITO, IZO (registered trademark), or IGZO, a low-resistance metal layer such as molybdenum (Mo), titanium (Ti), aluminum (Al), or copper (Cu), and a barrier metal layer such as titanium (Ti) may be formed with a thickness of about 300 nm.

Next, as illustrated in FIG. 14, for example, by photolithography and etching, the conductive material layer 31A is patterned into a predetermined shape, to form the lower gate electrode 31 and the bottom electrode BE1 of the lower capacitive element C1.

Subsequently, as illustrated in FIG. 15, on the lower gate electrode 31 and the bottom electrode BE1 of the lower capacitive element C1, the gate insulating film 32 is formed. Examples of methods of forming the gate insulating film 32 may include forming a laminated film of a silicon nitride film or a silicon oxide film by a plasma CVD method, and forming a silicon nitride film, a silicon oxide film, an aluminum oxide film, or an aluminum nitride film by a sputtering method or the like with a thickness of about 400 nm.

As an example of a plasma CVD method, a silicon nitride film may be formed by a plasma CVD method using a gas of silane, ammonia, nitrogen, or the like as a material gas, and then a silicon oxide film may be formed by a plasma CVD method using a gas including silane or dinitrogen oxide as a material gas. As a target for sputtering, silicon may be used. A silicon oxide film or a silicon nitride film may be formed by reactive plasma sputtering using oxygen, vapor, or nitrogen in a discharge atmosphere of sputtering.

After this, as illustrated in FIG. 16, on the insulating film 32, an oxide semiconductor material film 33A is formed. At this occasion, a preferable film thickness may be 5 to 100 nm both inclusive in consideration of efficiency in supplying oxygen by a subsequent anneal process. In a case that the oxide semiconductor material film 33A is made of indium gallium zinc oxide (IGZO), a DC sputtering method with indium gallium zinc oxide ceramic as a target may be used for forming the oxide semiconductor material film 33A; the oxide semiconductor material film 33A may be formed on the base 11 by plasma discharge by a mixed gas of argon and oxygen. It is to be noted that the mixed gas of argon and oxygen may be introduced after the inside of the vacuum vessel is evacuated before plasma discharge until a degree of vacuum becomes 1*10⁻⁴ Pa or less. In a case of using zinc oxide as an oxide semiconductor, it is possible to form a zinc oxide film that eventually serves as the oxide semiconductor material film 33A, by using an RF sputtering method with zinc oxide ceramic as a target, or a sputtering method using a DC power source in a gas atmosphere including argon and oxygen using a zinc metal target.

At this occasion, by varying a flow ratio of argon and oxygen, it is possible to control a carrier density in the oxide semiconductor film that eventually serves as a channel.

After forming the oxide semiconductor material film 33A, as illustrated in FIG. 17, for example, by photolithography and etching, the oxide semiconductor material film 33A is patterned into a predetermined shape, to form the semiconductor layer 33 made of an oxide semiconductor. Since oxide semiconductors are easily soluble in acids or alkalis, oxide semiconductors are generally processed by wet etching; however, dry etching may be also possible.

In a case of using, as the oxide semiconductor material film 33A, ZnO or a crystalline material that is made of indium, gallium, zirconium, tin, or the like, with a higher ratio of indium or zinc than other constituent elements, a crystallizing anneal process may be carried out at this stage to provide resistance to etching solvents.

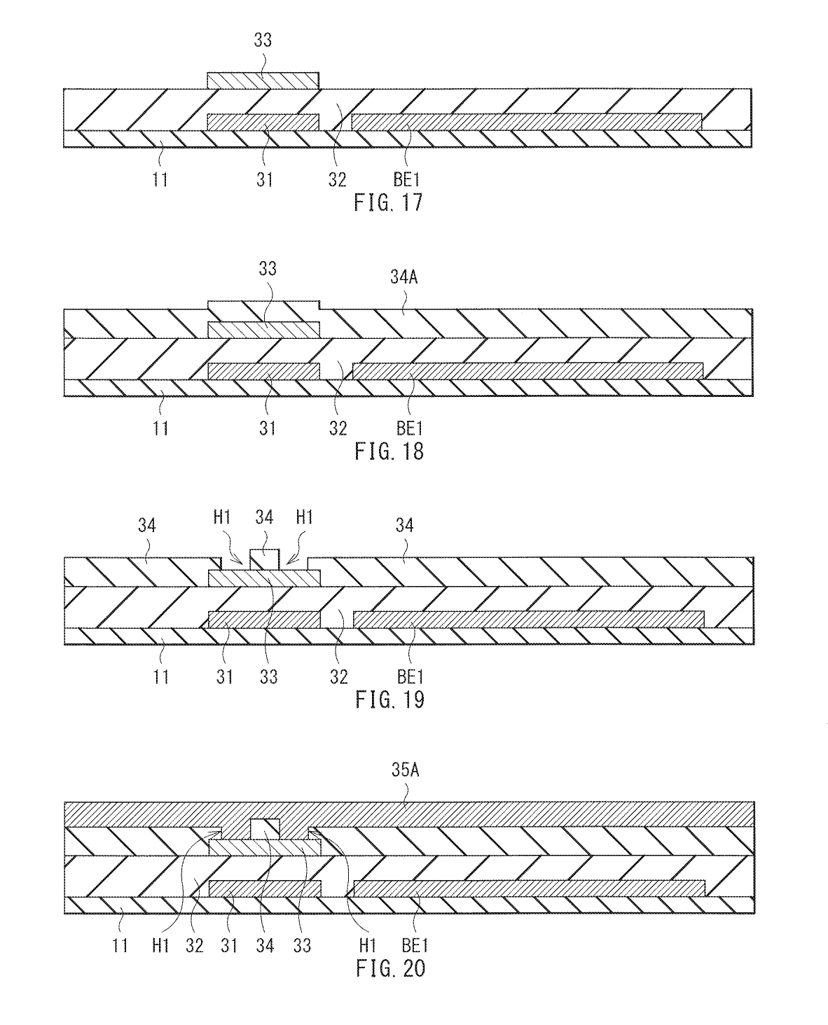

After forming the semiconductor layer 33, as illustrated in FIG. 18, on the semiconductor layer 33, a stopper material film 34A is formed. Examples of methods of depositing the stopper material film 34A may include forming a laminated film of a silicon nitride film or a silicon oxide film by a plasma CVD method, or forming a silicon nitride film, a silicon oxide film, an aluminum oxide film, or an aluminum nitride film by a sputtering method or the like with a thickness of about 200 nm.

After forming the stopper material film 34A, as illustrated in FIG. 19, for example, by photolithography and etching, the stopper material film 34A is patterned into a predetermined shape, to form the stopper layer 34 having a contact hole H1.

After forming the stopper layer 34, as illustrated in FIG. 20, on the stopper layer 34, the conductive material film 35A is formed. As a method of forming the conductive material film 35A, for example, by a sputtering method, a laminated film of an oxide semiconductor such as ITO, IZO (registered trademark), IGZO, or the like, a low-resistance metal layer such as molybdenum (Mo), titanium (Ti), aluminum (Al), copper (Cu), or the like, and a barrier metal layer such as titanium (Ti) or the like may be formed with a thickness of about 500 nm.

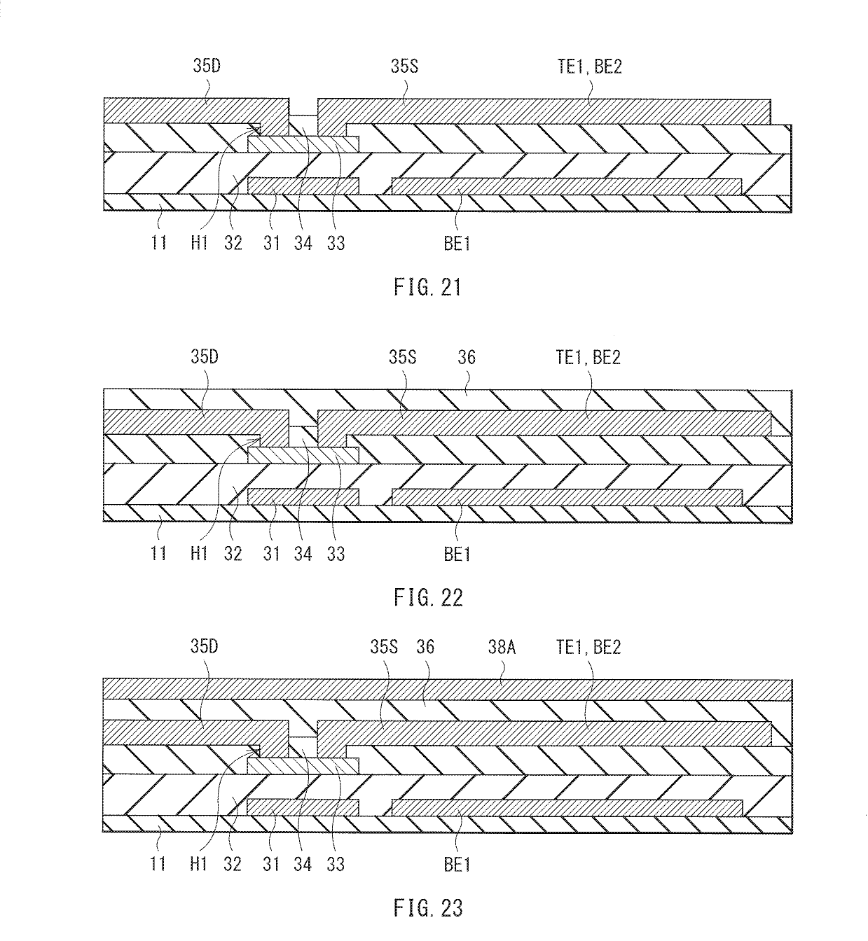

After forming the conductive material film 35A, as illustrated in FIG. 21, for example, by photolithography and etching, the conductive material film 35A is patterned into a predetermined shape, to form the source electrode 35S and the drain electrode 35D. At this occasion, the top electrode TE1 of the lower capacitive element C1 and the bottom electrode BE2 of the upper capacitive element C2 are formed integrally and continuously with the source electrode 35S.

After forming the source electrode 35S and the drain electrode 35D, as illustrated in FIG. 22, for example, by a plasma CVD method, the first passivation layer 36 made of a silicon nitride film, a silicon nitride oxide film or a lamination thereof is formed.

After forming the first passivation layer 36, as illustrated in FIG. 23, on the first passivation layer 36, a conductive material film 38A is formed. As a method of forming the conductive material film 38A, for example, by a sputtering method, a laminated film of an oxide semiconductor such as ITO, IZO (registered trademark), IGZO, or the like, a low-resistance metal layer such as molybdenum (Mo), titanium (Ti), aluminum (Al), copper (Cu), or the like, and a barrier metal layer such as titanium (Ti) or the like may be formed with a thickness of about 500 nm.

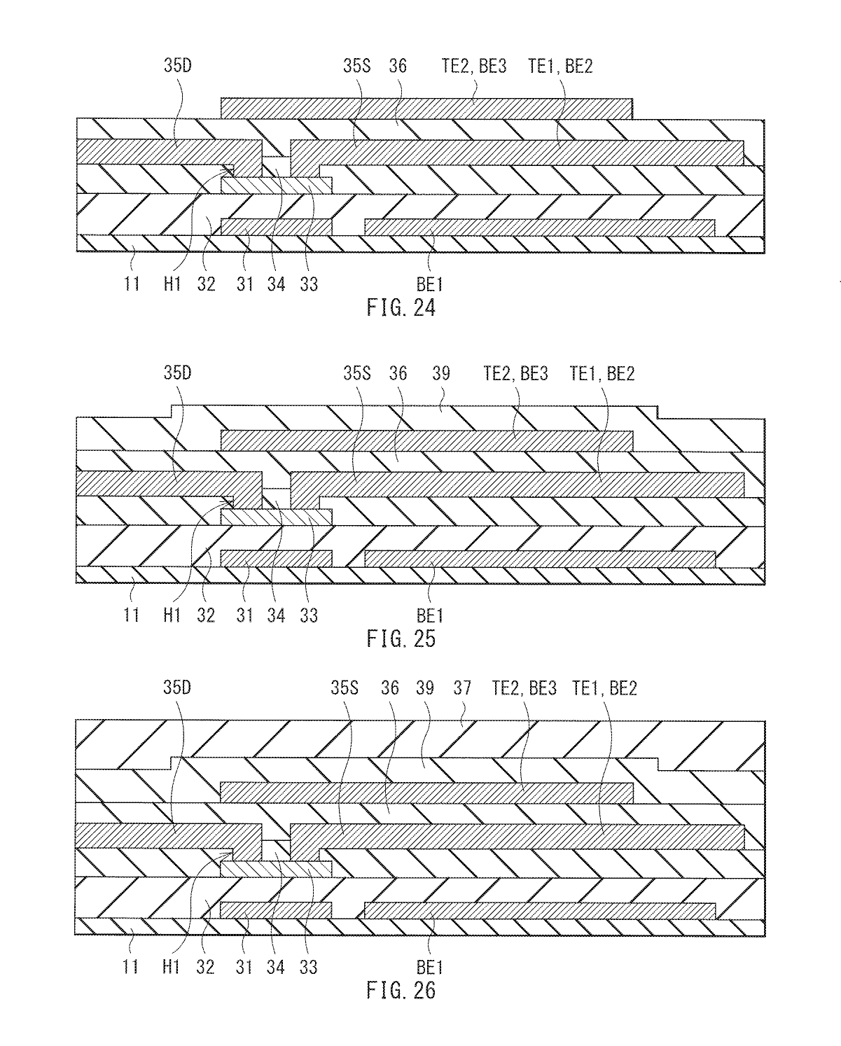

After forming the conductive material film 38A, as illustrated in FIG. 24, for example, by photolithography and etching, the conductive material film 38A is patterned into a predetermined shape, to form the upper gate electrode 38. At this occasion, the top electrode TE2 of the upper capacitive element C2 and the bottom electrode BE3 of the uppermost capacitive element C3 are formed integrally and continuously with the upper gate electrode 38.

After forming the upper gate electrode 38, as illustrated in FIG. 25, for example, by a plasma CVD method, the second passivation layer 39 made of a silicon nitride film, a silicon nitride oxide film, or a lamination thereof is formed. Thus, the substrate 10 as illustrated in FIGS. 7 and 8 is completed.

### (Processes to Form the Display Element 20)

After forming the substrate 10, as illustrated in FIG. 26, the planarization layer 37 is formed on the substrate 10. As the planarization layer 37, for example, an organic film with a thickness of about 2 μm made of an organic material such as polyimide, acrylic, or siloxane, or a laminated film of an organic film and a silicon oxide film, a silicon oxynitride film, a silicon nitride film, an aluminum oxide film, or a lamination thereof may be formed. At this occasion, the silicon oxide film, the silicon oxynitride film, or the silicon nitride film may be formed by a plasma CVD method. The aluminum oxide film may be formed by a reactive sputtering method by a DC or AC power source with aluminum as a target, by atomic layer deposition method, or the like.

Subsequently, a contact hole H2 is provided in the planarization layer 37 by, for example, photolithography and etching. After this, on the planarization layer 37, a laminated film of, for example, molybdenum (Mo) and aluminum (Al) is formed with a thickness of 500 nm by, for example, a sputtering method. Then, the laminated film is patterned into a predetermined shape by photolithography and etching. In this way, the anode electrode 21 is formed.

After this, the barrier rib 22 is formed. Then, the hole injection layer 23A and the hole transport layer 23B of the organic layer 23 are formed by, for example, a vacuum evaporation method, over the entire surface of the pixel array section 102.

After forming the hole transport layer 23B, the light emission layer 23C is formed. For example, in a case of FIG. 10, the red light emission layer 23CR and the green light emission layer 23CG are formed for each color by a coating method such as a liquid droplet ejection method. It is to be noted that, as illustrated in FIG. 11, in a method of using the yellow light emission layer 23CY and color-separating by the color filter CF, the coating process is finished when only the yellow light emission layer 23CY is formed. This is advantageous in terms of cost reduction.

After this, for example, by a vacuum evaporation method, the blue light emission layer 23CB, the electron transport layer 23D, and the electron injection layer 23E of the organic layer 23, the cathode electrode 24, and the protective layer 25 are formed over the entire surface of the pixel array section 102. After this, the sealing substrate 27 is bonded with the adhesive layer 26. Thus, the display device 100 as illustrated in FIG. 9 is completed.

The display device 100 operates, for example, as follows.

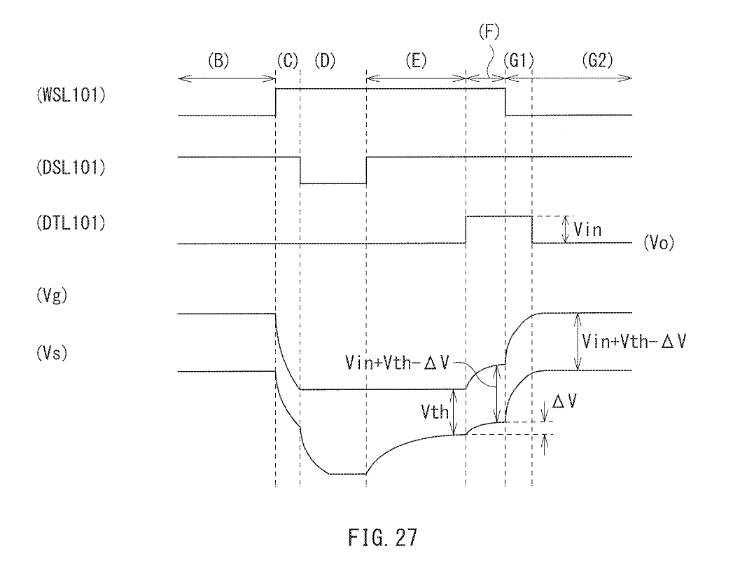

FIG. 27 is a timing chart provided for explanation of operations of the pixel circuit 101 illustrated in FIG. 2, indicating a potential change of the scan line (WSL101), a potential change of the power line (DSL101), and a potential change of the signal line (DTL101) along a common time axis. Moreover, in parallel with these potential changes, changes of the gate potential (Vg) and the source potential (Vs) of the drive transistor 3B are also indicated.

This timing chart is divided, for convenience, into periods such as (B) to (G1) and (G2) in accordance with transitions of the operations of the pixel circuit 101. In a light emission period (B), the light emitting element 3D is in a light emitting status. After this, a new field of the line sequential scanning starts; first, in a first period (C), the gate potential Vg of the drive transistor 3B is initialized. Moving on to a next period (D), the source potential Vs is also initialized. By initializing the gate potential Vg and the source potential Vs of the drive transistor 3B, preparation of the threshold voltage correction operation is completed. Subsequently, in a threshold value correction period (E), the threshold voltage correction operation is actually carried out, and a voltage corresponding to the threshold voltage Vth is maintained between the gate g and the source s of the drive transistor 3B. Specifically, the voltage corresponding to Vth is written in the retention capacitor 3C connected between the gate g and the source s of the drive transistor 3B. After this, moving on to a sampling period/a mobility correction period (F), the signal potential Vin of the picture signal is written in the retention capacitor 3C in a form where the signal potential Vin is added to Vth, while a voltage ΔV for the mobility correction is subtracted from a voltage maintained by the retention capacitor 3C. Subsequently, moving on to light emission periods (G1) and (G2), the light emitting element 3D emits light with luminance according to the signal potential Vin. At this occasion, since the signal potential Vin is adjusted by the voltage corresponding to the threshold voltage Vth and the voltage ΔV for mobility correction, the light emission luminance of the light emitting element 3D is not affected by variations in the threshold voltage Vth or the mobility μ of the drive transistor 3B. It is to be noted that the boot strap operation is carried out in an early stage (G1) of the light emission period, and the gate potential Vg and the source potential Vs of the drive transistor 3B is raised, while keeping the gate-source voltage Vgs=Vin+Vth−ΔV of the drive transistor 3B constant.

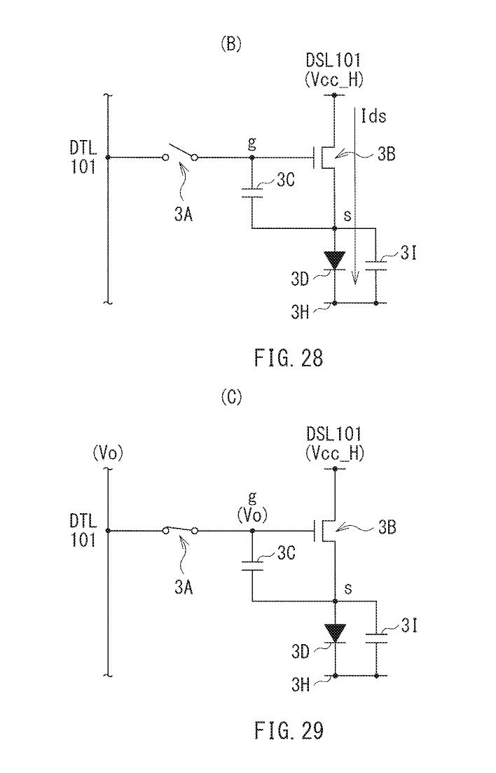

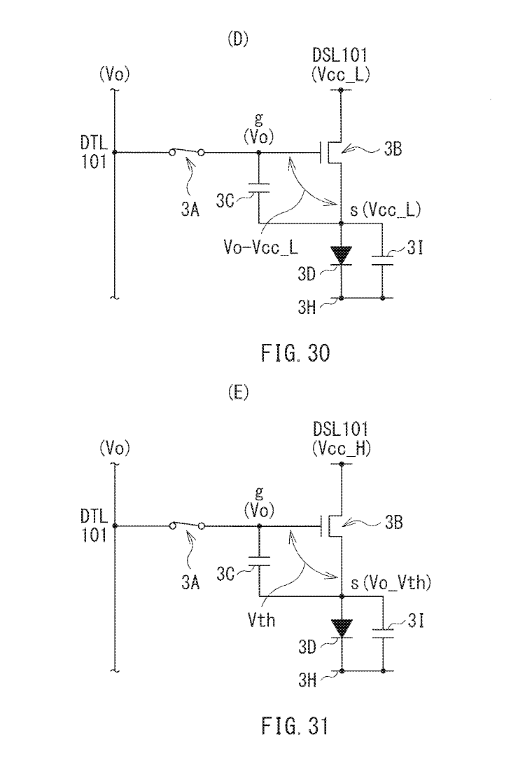

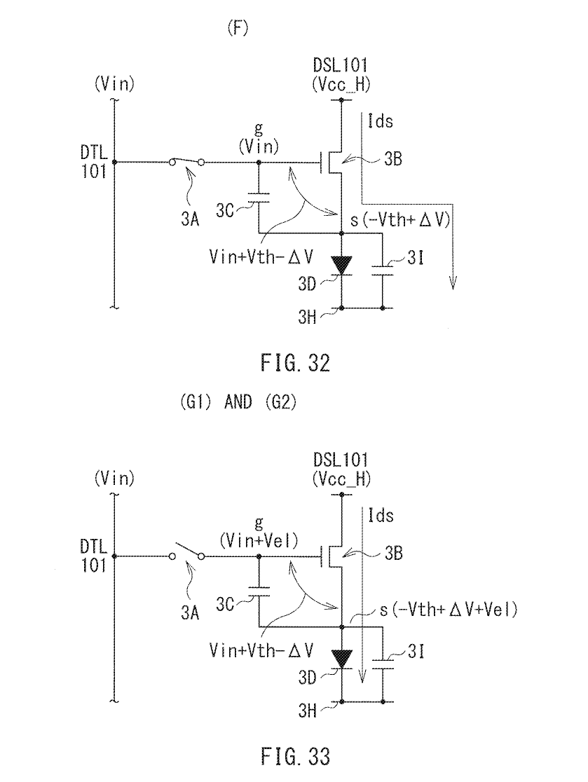

Description will continue on the details of the operations of the pixel circuit 101 with reference to FIGS. 28 to 33. It is to be noted that FIG. 28 corresponds to the period (B) of the timing chart illustrated in FIG. 27. FIG. 29 corresponds to the period (C) of the timing chart illustrated in FIG. 27. FIG. 30 corresponds to the period (D) of the timing chart illustrated in FIG. 27. FIG. 31 corresponds to the period (E) of the timing chart illustrated in FIG. 27. FIG. 32 corresponds to the period (F) of the timing chart illustrated in FIG. 27. FIG. 33 corresponds to the periods (G1) and (G2) of the timing chart illustrated in FIG. 27.

First, as illustrated in FIG. 28, in the light emission period (B), the power line DSL101 is at a high potential Vcc_H (a first potential), and the drive transistor 3B is supplying a drive current Ids to the light emitting element 3D. The drive current Ids passes through the light emitting element 3D, from the power line DSL101 at the high potential Vcc_H, through the drive transistor 3B, and flows into the common ground wiring 3H.

Next, when the period (C) starts, as illustrated in FIG. 29, the scan line WSL101 transits on the high potential side, to allow the sampling transistor 3A to be in an ON state, and to allow the gate potential Vg of the drive transistor 3B to be initialized (reset) to a reference potential Vo of the signal line DTL101.

Subsequently, moving on to the period (D), as illustrated in FIG. 30, the potential of the power line DSL101 transits from the high potential Vcc_H (the first potential) to a potential Vcc_L (the second potential) that is sufficiently lower than the reference potential Vo of the signal line DTL101. This allows the source potential Vs of the drive transistor 3B to be initialized (reset) to the potential Vcc_L that is sufficiently lower than the reference potential Vo of the signal line DTL101. Specifically, the low potential Vcc_L (the second potential) of the power line DSL101 is set so that the gate-source voltage Vgs of the drive transistor 3B (a difference between the gate potential Vg and the source potential Vs) is larger than the threshold voltage Vth of the drive transistor 3B.

After this, moving on to the threshold value correction period (E), as illustrated in FIG. 31, the potential of the power line DSL101 transits from the low potential Vcc_L to the high potential Vcc_H, to allow the source potential Vs of the drive transistor 3B to start rising. When the gate-source voltage Vgs of the drive transistor 3B eventually becomes the threshold voltage Vth, the current is cut off. In this way, the voltage corresponding to the threshold voltage Vth of the drive transistor 3B is written in the retention capacitor 3C. This is the threshold voltage correction operation. At this occasion, the potential of the common ground wiring 3H is set so that the light emitting element 3D is cut off, in order to allow the current to flow mainly on the retention capacitor 3C side, and not to flow on the light emitting element 3D side.

Subsequently, moving on to the sampling period/the mobility correction period (F), as illustrated in FIG. 32, the potential of the signal line DTL101 transits from the reference potential Vo to the signal potential Vin at the first timing, and the gate potential Vg of the drive transistor 3B becomes Vin. At this occasion, since the light emitting element 3D is in a cut off state (a high impedance state) in the beginning, the drain current Ids of the drive transistor 3B flows into the auxiliary capacitor 3I. This allows the auxiliary capacitor 3I to start charging. Accordingly, the source potential Vs of the drive transistor 3B start rising, and the gate-source voltage Vgs of the drive transistor 3B becomes Vin+Vth−ΔV at the second timing. In this way, sampling of the signal potential Vin and adjustment of an amount of correction ΔV are carried out. As Vin is higher, Ids becomes larger, and so does an absolute value of ΔV. Consequently, it is possible to perform the mobility correction according to a luminance level of light emission. Moreover, in a case that Vin is constant, the larger the mobility μ of the drive transistor 3B is, the larger the absolute value of ΔV becomes. In other words, the larger the mobility μ is, the larger a negative feedback amount ΔV becomes; it is therefore possible to eliminate variation in mobility μ for each pixel.

Finally, in the light emission period (G1), as illustrated in FIG. 33, the scan line WSL101 transits on the low potential side, to allow the sampling transistor 3A to be in an OFF state. This allows the gate g of the drive transistor 3B to be disconnected from the signal line DTL101. At the same time, the drain current Ids starts to flow in the light emitting element 3D. In this way, an anode potential of the light emitting element 3D is raised according to the drive current Ids. The rise of the anode potential of the light emitting element 3D is nothing other than a rise of the source potential Vs of the drive transistor 3B. When the source potential Vs of the drive transistor 3B is raised, the gate potential Vg of the drive transistor 3B is also raised accordingly due to the boot strap operation of the retention capacitor 3C. An amount of the rise of the gate potential Vg is equal to an amount of the rise of the source potential Vs. Therefore, during the light emission period, the gate-source voltage Vgs of the drive transistor 3B is kept constant at Vin+Vth−ΔV.

In the light emission period (G2), the source potential Vs and the gate potential Vg of the drive transistor 3B stop rising, and are maintained as they are.

Table 1 summarizes, based on the description above, the difference in charge and discharge periods of the retention capacitor 3C and the auxiliary capacitor 3I.

TABLE 1

| | (E) | (F) | (G1) | (G2) |
|---|---|---|---|---|
| The retention capacitor 3C | Input | Input | Maintain | Maintain |
| The auxiliary capacitor 3I | Input | Input | Input | Maintain |

Charge of the retention capacitor 3C is started in the threshold value correction period (E). At this occasion, the light emitting element 3D is cut off, but a current flowing on the light emitting element 3D side is not completely restrained, and there occurs charge of the auxiliary capacitor 3I. In the next sampling period/the mobility correction period (F), the charge of the auxiliary capacitor 3I is started. In the early stage of the light emission period (G1), only the charge of the auxiliary capacitor 3I is carried out.

As described above, the retention capacitor 3C is configured to perform the operation of the threshold value correction, and allows writing to be performed in the periods (E) and (F). On the other hand, the auxiliary capacitor 3I is configured to increase time margin of the mobility correction, and allows writing to be performed in the periods (E), (F), and (G1). In short, the retention capacitor 3C and the auxiliary capacitor 3I allow writing to be performed in different periods.

Here, in the present embodiment, the charge and discharge period of the lower capacitive element C1 and the charge and discharge period of the upper capacitive element C2 are different from each other. Accordingly, by allowing the upper capacitive element C2 to perform the threshold value correction operation as the retention capacitor 3C and by allowing the lower capacitive element C1 to increase time margin of the mobility correction as the auxiliary capacitor 3I, it is possible to cope with the driving of the pixel circuit 101 involving the threshold value correction and the mobility correction as described above.

As described above, in the present embodiment, the plurality of capacitive elements Cn are stacked on the base 11. The plurality of capacitive elements Cn include the lower capacitive element C1 and the upper capacitive element C2 that are different in position in the stacking direction. The bottom electrode BE1 of the lower capacitive element C1 and the top electrode TE2 of the upper capacitive element C2 are electrically independent from one another. Hence, it is possible to stack the plurality of capacitive elements Cn having different operations and functions, leading to enhanced layout efficiency. It is therefore possible to arrange the plurality of capacitive elements Cn in small layout area, regardless of reduction in area per one pixel PX in promoting miniaturization of the pixel pitch accompanying higher definition (the increase in the number of pixels) and downsizing of the display device 100.

Moreover, the lower capacitive element C1 and the upper capacitive element C2 are configured to be capable of maintaining different potentials from one another. Hence, it is possible to stack, on the base 11, the lower capacitive element C1 and the upper capacitive element C2 having different functions, making it possible to reduce area of the pixel PX while attaining enhancement in circuit performance.

Furthermore, when the lower capacitive element C1 serves as the auxiliary capacitor 3I while the upper capacitive element C2 serves as the retention capacitor 3C, it is possible to restrain an increase in the number of contacts, enhancing layout efficiency.

### Second Embodiment

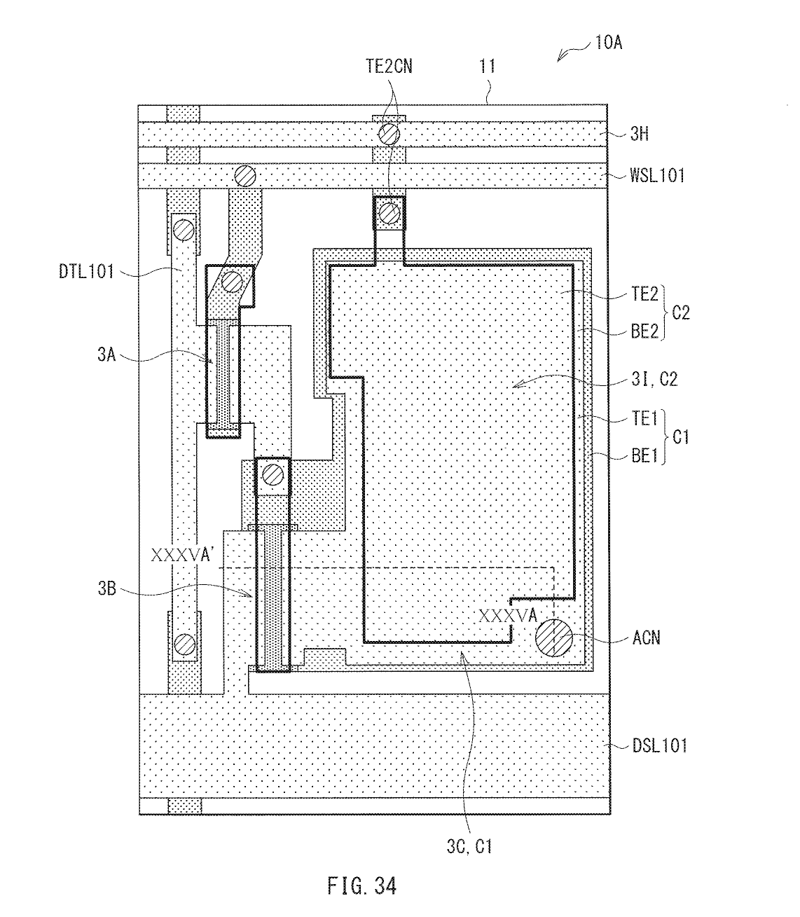

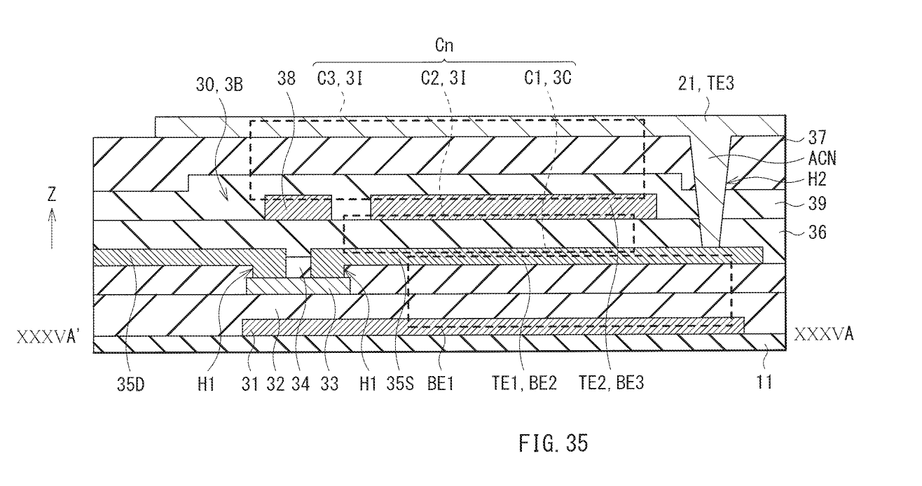

FIG. 34 illustrates an example in which a substrate 10A according to a second embodiment of the present disclosure is applied to the planar arrangement configuration of the retention capacitor 3C and the auxiliary capacitor 3I illustrated in FIG. 2. FIG. 35 illustrates a cross-sectional configuration along a XXXVA-XXXVA′ line in FIG. 34. The substrate 10A may have a same configuration as that of the substrate 10 according to the above-described first embodiment, except that the lower capacitive element C1 is the retention capacitor 3C while the upper capacitive element C2 is the auxiliary capacitor 3I. Therefore, description will be given with similar components denoted by similar reference numerals.

Specifically, the substrate 10A includes the plurality of capacitive elements Cn on the base 11, similarly to the first embodiment. The plurality of capacitive elements Cn are stacked on the base 11 in the direction of thickness of the base 11, and are different in position in the stacking direction Z from one another. The plurality of capacitive elements Cn may include, for example, the lower capacitive element C1, the upper capacitive element C2, and the uppermost capacitive element C3 in this order from the base 11 side.

Furthermore, similarly to the first embodiment, the substrate 10A may preferably include the thin film transistor 30 on the side of the base 11 on which the plurality of capacitive elements Cn are provided. The configuration of the thin film transistor 30 may be similar to that of the first embodiment. It is to be noted that the thin film transistor 30 illustrated in FIG. 35 corresponds to the drive transistor 3B illustrated in FIG. 34, and the anode electrode 21 (the anode of the light emitting element 3D) is connected to the source electrode 35S.

The lower capacitive element C1 may include, on the base 11, the bottom electrode BE1, the gate insulating film 32 and the stopper layer 34, and the top electrode TE1. The bottom electrode BE1 of the lower capacitive element C1 may be connected to the lower gate electrode 31 (the gate g of the drive transistor 3B). The top electrode TE1 of the lower capacitive element C1 may be connected to the source electrode 35S (the source s of the drive transistor 3B).

In other words, the lower capacitive element C1 may be connected between the source s and the gate g of the drive transistor 3B, and may serve as the retention capacitor 3C in the pixel circuit 101 illustrated in FIG. 2.

The upper capacitive element C2 may include, on the base 11, the bottom electrode BE2, the first passivation layer 36, and the top electrode TE2. The bottom electrode BE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be provided on the same layer as the upper gate electrode 38, but may be uncontinuous with the upper gate electrode 38. That is, the top electrode TE2 of the upper capacitive element C2 may be provided as a separate layer from the upper gate electrode 38. It is to be noted that the top electrode TE2 of the upper capacitive element C2 may be connected to the ground wiring 3H and the cathode of the light emitting element 3D through a contact TE2CN (refer to FIG. 34).

In other words, the upper capacitive element C2 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

Similarly to the first embodiment, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected to one another, but are connected to, for example, their respective wirings that are different from one another. Thus, in the substrate 10A and in the display device 100 including the substrate 10A, it is possible to stack the plurality of capacitive elements C1 to C3 having different operations and functions, leading to enhanced layout efficiency.

Preferably, the lower capacitive element C1 and the upper capacitive element C2 may be capable of maintaining different potentials from one another, similarly to the first embodiment.

Moreover, similarly to the first embodiment, preferably, the charge and discharge period of the lower capacitive element C1 and the charge and discharge period of the upper capacitive element C2 may be different from one another.

Furthermore, as described above, since the lower capacitive element C1 serves as the retention capacitor 3C while the upper capacitive element C2 serves as the auxiliary capacitor 3I, it is possible to reduce a possibility that the retention capacitor 3C fluctuates depending on the thickness of the first passivation layer 36. Accordingly, it is possible to restrain influences on luminance due to gain fluctuation in the boot strap operation.

The uppermost capacitive element C3 may include, on the base 11, the bottom electrode BE3, the second passivation layer 39 and the planarization layer 37, and the top electrode TE3. The bottom electrode BE3 of the uppermost capacitive element C3 may be common to the top electrode TE2 of the upper capacitive element C2, and may be connected to the ground wiring 3H and the cathode of the light emitting element 3D. The top electrode TE3 of the uppermost capacitive element C3 may be the anode electrode 21 (the anode of the light emitting element 3D).

In other words, the uppermost capacitive element C3 may be connected between the source s and the ground wiring 3H (the cathode of the light emitting element 3D) in parallel with the light emitting element 3D, and may serve as the auxiliary capacitor 3I in the pixel circuit 101 illustrated in FIG. 2. By providing the uppermost capacitive element C3, it is possible to supplement the auxiliary capacitor 3I, further enhancing the correction functions of the pixel circuit 101.

It is to be noted that FIG. 35 represents the layer configuration from the base 11 to the anode electrode 21, and layers above the anode electrode 21 are omitted. Out of the layers illustrated in FIG. 35, FIG. 34 represents the following layers: the base 11, the lower gate electrode 31 and the bottom electrode BE1 that is on the same layer as the lower gate electrode 31, the semiconductor layer 33, the source electrode 35S and the drain electrode 35D, the top electrode TE1 and the bottom electrode BE2 that are on the same layer as the source electrode 35S and the drain electrode 35D, the upper gate electrode 38 and the top electrode TE2 that is on the same layer as the upper gate electrode 38, and the anode contact ACN between the source electrode 35S and the anode electrode 21.

The substrate 10A and the display device 100 including the substrate 10A may be manufactured similarly to the manufacturing method of the above-described first embodiment, except for the shape and the connection relation of the bottom electrode BE1 of the lower capacitive element C1 and the top electrode TE2 of the upper capacitive element C2.

### (Processes to Form the Substrate 10A)

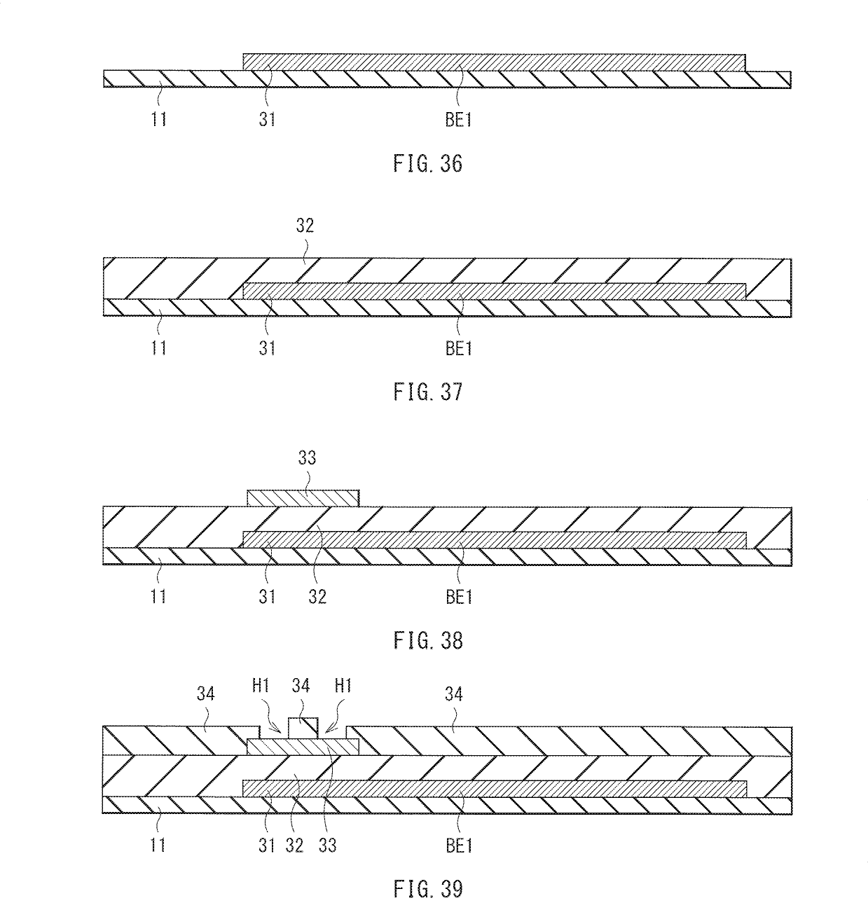

FIGS. 36 to 44 illustrate a method of manufacturing the substrate 10A in the order of procedure. It is to be noted that the same processes as those of the first embodiment will be described with reference to FIGS. 13 to 26.

First, similarly to the first embodiment, by the process illustrated in FIG. 13, the base 11 that is configured of the above-mentioned material is prepared. On the base 11, the conductive material film 31A is formed by, for example, a sputtering method.

Next, as illustrated in FIG. 36, for example, by photolithography and etching, the conductive material layer 31A is patterned into a predetermined shape, to form the lower gate electrode 31 and the bottom electrode BE1 of the lower capacitive element C1.

Subsequently, as illustrated in FIG. 37, similarly to the first embodiment, by the process illustrated in FIG. 15, the gate insulating film 32 is formed on the lower gate electrode 31 and the bottom electrode BE1 of the lower capacitive element C1.

After this, similarly to the first embodiment, by the process illustrated in FIG. 16, the oxide semiconductor material film 33A is formed on the gate insulating film 32.

After forming the oxide semiconductor material film 33A, as illustrated in FIG. 38, for example, by photolithography and etching, the oxide semiconductor material film 33A is patterned into a predetermined shape, to form the semiconductor layer 33 made of an oxide semiconductor.

After forming the semiconductor layer 33, similarly to the first embodiment, by the process illustrated in FIG. 18, the stopper material film 34A is formed on the semiconductor layer 33.

After forming the stopper material film 34A, as illustrated in FIG. 39, for example, by photolithography and etching, the stopper material film 34A is patterned into a predetermined shape, to form the stopper layer 34 having the contact hole H1.

After forming the stopper layer 34, similarly to the first embodiment, by the process illustrated in FIG. 20, the conductive material film 35A is formed on the stopper layer 34.

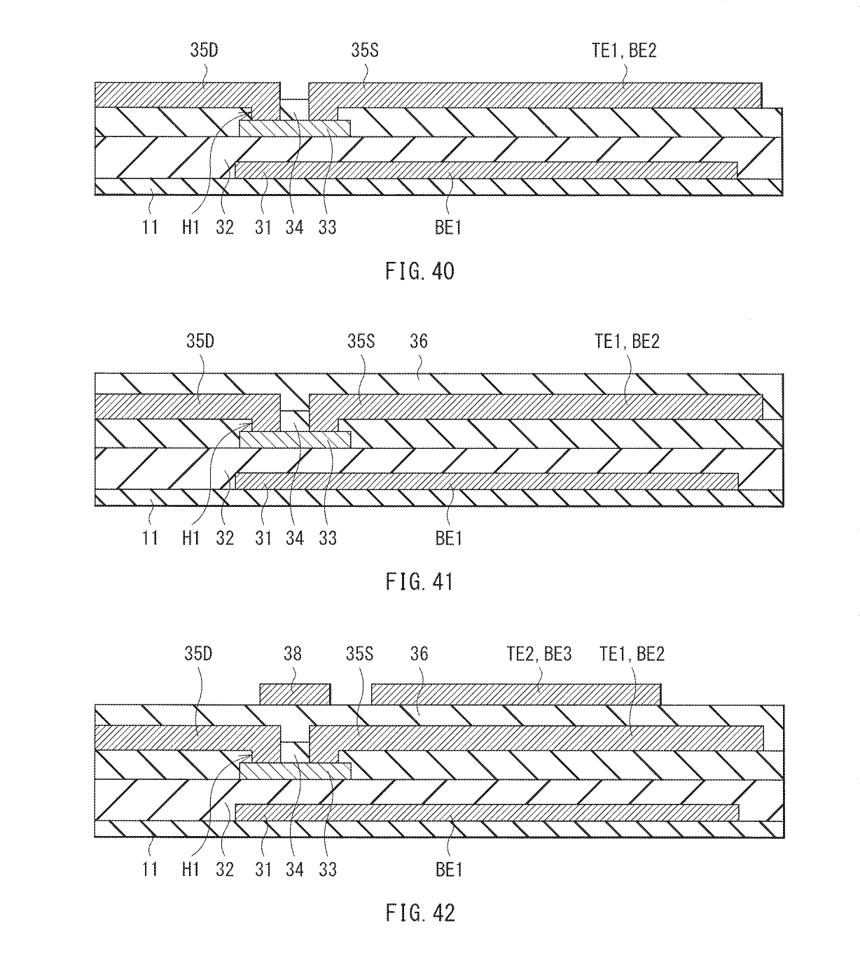

After forming the conductive material film 35A, as illustrated in FIG. 40, for example, by photolithography and etching, the conductive material film 35A is patterned into a predetermined shape, to form the source electrode 35S and the drain electrode 35D. At this occasion, the top electrode TE1 of the lower capacitive element C1 and the bottom electrode BE2 of the upper capacitive element C2 are formed integrally and continuously with the source electrode 35S.

After forming the source electrode 35S and the drain electrode 35D, as illustrated in FIG. 41, for example, by a plasma CVD method, the first passivation layer 36 made of a silicon nitride film, a silicon nitride oxide film, or a lamination thereof is formed.

After forming the first passivation layer 36, similarly to the first embodiment, by the process illustrated in FIG. 23, the conductive material film 38A is formed on the first passivation layer 36.

After forming the conductive material film 38A, as illustrated in FIG. 42, for example, by photolithography and etching, the conductive material film 38A is patterned into a predetermined shape, to form the upper gate electrode 38. At this occasion, the top electrode TE2 of the upper capacitive element C2 and the bottom electrode BE3 of the uppermost capacitive element C3 are formed as a separate layer that is uncontinuous with the upper gate electrode 38.

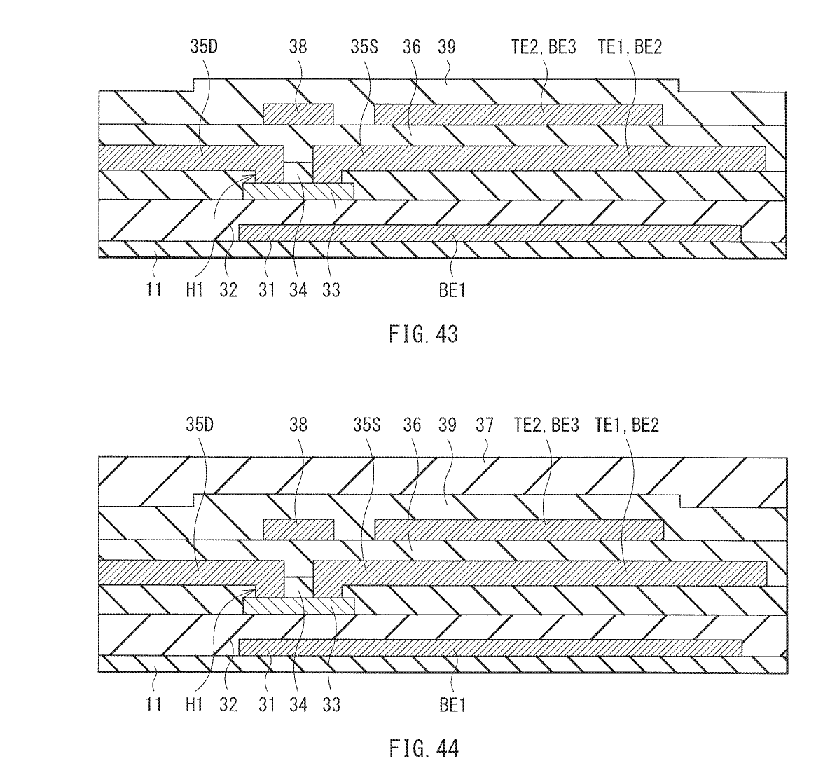

After forming the upper gate electrode 38, as illustrated in FIG. 43, for example, by a plasma CVD method, the second passivation layer 39 made of a silicon nitride film, a silicon nitride oxide film, or a lamination thereof is formed. Thus, the substrate 10A as illustrated in FIGS. 34 and 35 is completed.

### (Processes to Form the Display Element 20)

After forming the substrate 10A, as illustrated in FIG. 44, the planarization layer 37 is formed on the substrate 10A. The material and the formation method of the planarization layer 37 may be similar to those of the first embodiment.

Subsequently, similarly to the first embodiment, a contact hole H2 is provided in the planarization layer 37 by, for example, photolithography and etching. Then, the anode electrode 21 is formed on the planarization layer 37.

After this, similarly to the first embodiment, the barrier rib 22, the organic layer 23, the cathode electrode 24, and the protective layer 25 are formed in this order. After this, the sealing substrate 27 is bonded with the adhesive layer 26. Thus, the display device 100 including the substrate 10A is completed.

The display device 100 operates similarly to the first embodiment.

As described above, in the present embodiment, the lower capacitive element C1 serves as the retention capacitor 3C while the upper capacitive element C2 serves as the auxiliary capacitor 3I. Hence, it is possible to reduce a possibility that the retention capacitor 3C fluctuates depending on the thickness of the first passivation layer 36. It is therefore possible to restrain influences on luminance due to gain fluctuation in the boot strap operation.

### Modification Example 1

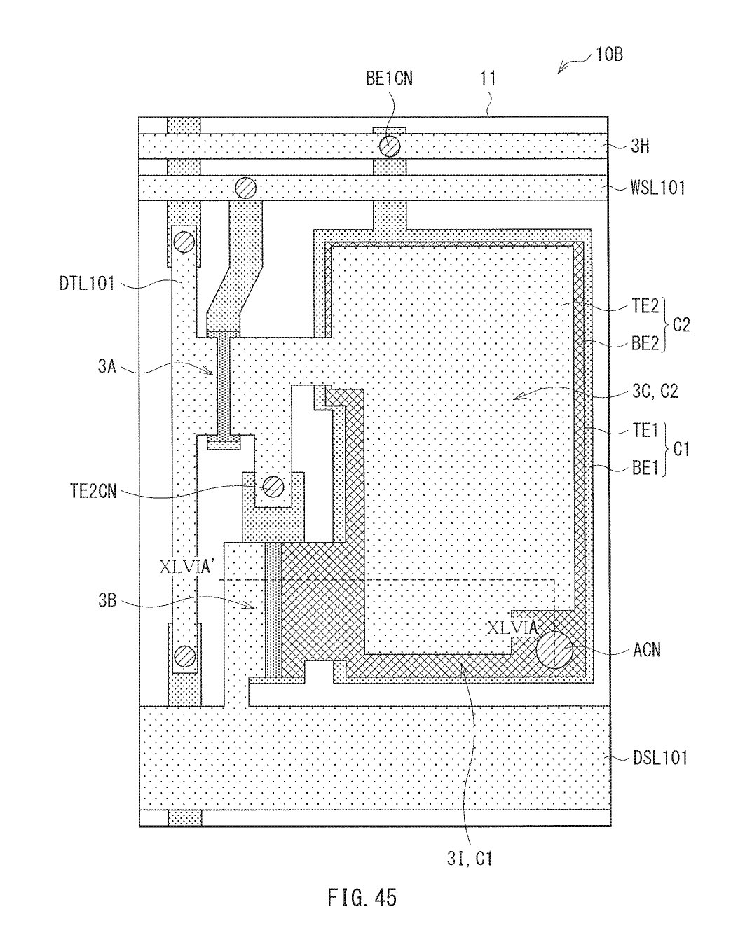

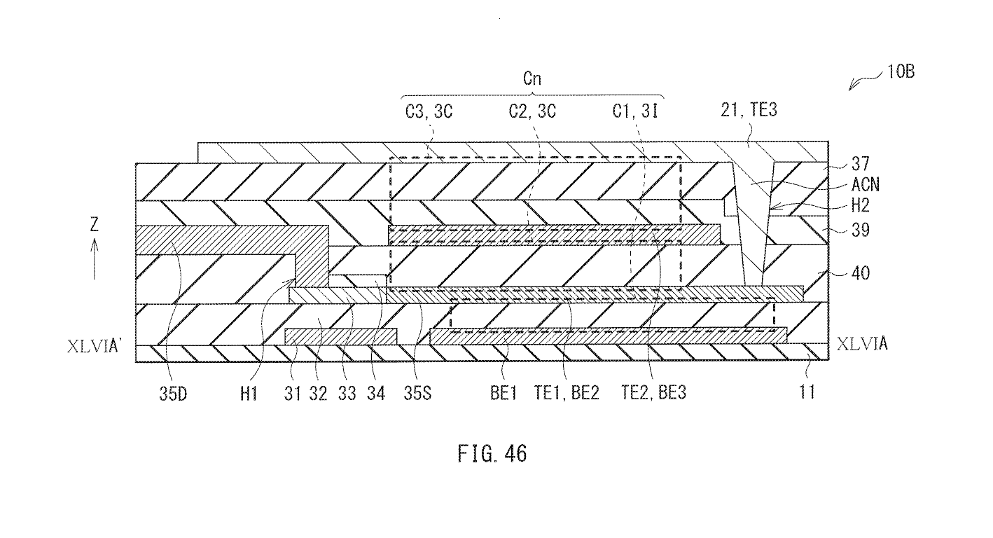

FIG. 45 illustrates an example in which a substrate 10B according to a modification example 1 of the present disclosure is applied to the planar arrangement configuration of the retention capacitor 3C and the auxiliary capacitor 3I illustrated in FIG. 2. FIG. 46 illustrates a cross-sectional configuration along a XLVIA-XLVIA′ line in FIG. 45. The substrate 10B may have a same configuration as that of the substrate 10 according to the above-described first embodiment, except that the top electrode TE1 of the lower capacitive element C1 and the bottom electrode BE1 of the upper capacitive element C2 are configured of an oxide semiconductor having a lower resistance value than that of the semiconductor layer 33.

Specifically, the substrate 10B includes, on the base 11, the plurality of capacitive elements Cn, similarly to the first embodiment. The plurality of capacitive elements Cn are stacked on the base 11 in the direction of thickness of the base 11, and are different in position in the stacking direction Z. The plurality of capacitive elements Cn may include, for example, the lower capacitive element C1, the upper capacitive element C2, and the uppermost capacitive element C3 in this order from the base 11 side.

Furthermore, similarly to the first embodiment, the substrate 10B may preferably include the thin film transistor 30 on the side of the base 11 on which the plurality of capacitive elements Cn are provided.

The thin film transistor 30 according to the present modification example may be, for example, a thin film transistor of a bottom gate type that includes, on the base 11, the gate electrode 31, the gate insulating film 32, the semiconductor layer 33, the stopper layer 34, an interlayer insulating film 40, the source electrode 35S and the drain electrode 35D, and the passivation layer 39 in this order. A surface of the base 11 on which the thin film transistor 30 is formed may be planarized by the planarization layer 37. It is to be noted that the thin film transistor 30 illustrated in FIG. 46 corresponds to the drive transistor 3B illustrated in FIG. 45. The anode electrode 21 (the anode of the light emitting element 3D) is connected to the source electrode 35S.

Moreover, in the present modification example, the source electrode 35S may be configured of an oxide semiconductor having a lower resistance value than that of the semiconductor layer 33. Specifically, the semiconductor layer 33 may be configured of, for example, IGZO while the source electrode 35S may be configured of, for example, n⁺IGZO. The source electrode 35S may be lowered in resistance with an increased electron density in the oxide semiconductor, for example, due to a reducing action of hydrogen in the film and hydrogen plasma during deposition in the manufacturing process that will be described later.

The lower capacitive element C1 may include, on the base 11, the bottom electrode BE1, the gate insulating film 32, and the top electrode TE1. The bottom electrode BE1 of the lower capacitive element C1 may be provided on the same layer as the gate electrode 31, but may be uncontinuous with the gate electrode 31. That is, the bottom electrode BE1 of the lower capacitive element C1 may be provided as a separate layer from the lower gate electrode 31. It is to be noted that the bottom electrode BE1 of the lower capacitive element C1 may be connected to the ground wiring 3H and the cathode of the light emitting element 3D through a contact BE1CN (refer to FIG. 45). The top electrode TE1 of the lower capacitive element C1 may be connected to the source electrode 35S (the source s of the drive transistor 3B).

In other words, the lower capacitive element C1 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

The upper capacitive element C2 may include, on the base 11, the bottom electrode BE2, the interlayer insulating film 40, and the top electrode TE2. The bottom electrode BE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be provided on the same layer as the drain electrode 35D, but may be uncontinuous with the drain electrode 35D. That is, the top electrode TE2 of the upper capacitive element C2 may be provided as a separate layer from the drain electrode 35D. It is to be noted that the top electrode TE2 of the upper capacitive element C2 may be connected to the gate electrode 31 (the gate g of the drive transistor 3B) through a contact TE2CN (refer to FIG. 45).

In other words, the upper capacitive element C2 may be connected between the source s and the gate g of the drive transistor 3B, and may serve as the retention capacitor 3C in the pixel circuit 101 illustrated in FIG. 2.

Similarly to the first embodiment, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected to one another, but are connected to, for example, their respective wirings that are different from one another. Thus, in the substrate 10B and the display device 100 including the substrate 10B, it is possible to stack the plurality of capacitive elements C1 to C3 having different operations and functions, leading to enhanced layout efficiency.

Preferably, the lower capacitive element C1 and the upper capacitive element C2 may be capable of maintaining different potentials from one another, similarly to the first embodiment.

Moreover, similarly to the first embodiment, preferably, the charge and discharge period of the lower capacitive element C1 and the charge and discharge period of the upper capacitive element C2 may be different from one another.

Furthermore, as described above, since the lower capacitive element C1 serves as the auxiliary capacitor 3I while the upper capacitive element C2 serves as the retention capacitor 3C, it is possible to restrain an increase in the number of contacts, enhancing layout efficiency.

The uppermost capacitive element C3 may include, on the base 11, the bottom electrode BE3, the passivation layer 39 and the planarization layer 37, and the top electrode TE3. The bottom electrode BE3 of the uppermost capacitive element C3 may be common to the top electrode TE2 of the upper capacitive element C2, and may be connected to the gate electrode 31 (the gate g of the drive transistor 3B). The top electrode TE3 of the uppermost capacitive element C3 may be the anode electrode 21 (the anode of the light emitting element 3D).

In other words, the uppermost capacitive element C3 may be connected between the source s and the gate g of the drive transistor 3B, and may serve as the retention capacitor 3C in the pixel circuit 101 illustrated in FIG. 2. By providing the uppermost capacitive element C3, it is possible to supplement the retention capacitor 3C, further enhancing the correction functions of the pixel circuit 101.

It is to be noted that FIG. 46 represents the layer configuration from the base 11 to the anode electrode 21, and layers above the anode electrode 21 are omitted. Out of the layers illustrated in FIG. 46, FIG. 45 represents the following layers: the base 11, the gate electrode 31 and the bottom electrode BE1 that is on the same layer as the gate electrode 31, the semiconductor layer 33, the source electrode 35S, the top electrode TE1 and the bottom electrode BE2 that are on the same layer as the source electrode 35S, the drain electrode 35D, the top electrode TE2 that is on the same layer as the drain electrode 35D, and the anode contact ACN between the source electrode 35S and the anode electrode 21.

The substrate 10B and the display device 100 including the substrate 10B may be manufactured, for example, as follows.

### (Processes to Form the Substrate 10B)

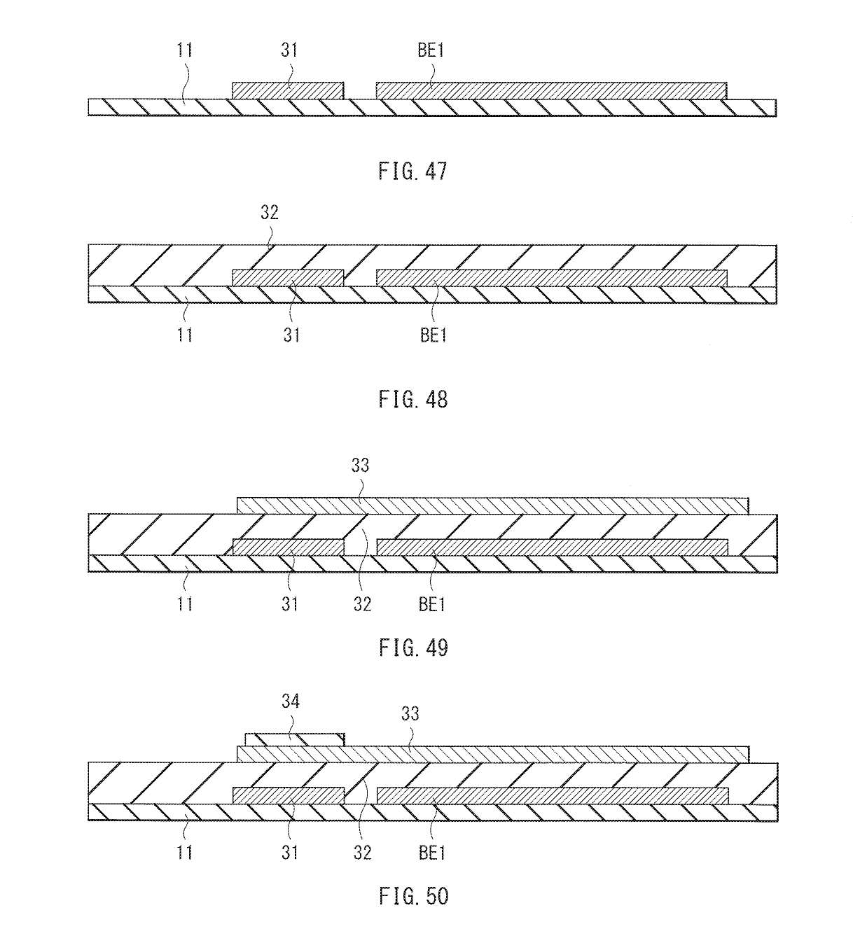

FIGS. 47 to 56 illustrate a method of manufacturing the substrate 10B in the order of procedure. It is to be noted that the same processes as those of the first embodiment will be described with reference to FIGS. 13 to 26.

First, similarly to the first embodiment, by the process illustrated in FIG. 13, the base 11 that is configured of the above-mentioned material is prepared. On the base 11, the conductive material film 31A is formed by, for example, a sputtering method.

Next, as illustrated in FIG. 47, for example, by photolithography and etching, the conductive material film 31A is patterned into a predetermined shape, to form the gate electrode 31 and the bottom electrode BE1 of the lower capacitive element C1.

Subsequently, as illustrated in FIG. 48, similarly to the first embodiment, by the process illustrated in FIG. 15, the gate insulating film 32 is formed on the gate electrode 31 and the bottom electrode BE1 of the lower capacitive element C1.

After this, similarly to the first embodiment, by the process illustrated in FIG. 16, the oxide semiconductor material film 33A is formed on the gate insulating film 32.

After forming the oxide semiconductor material film 33A, as illustrated in FIG. 49, for example, by photolithography and etching, the oxide semiconductor material film 33A is patterned into a predetermined shape, to form the semiconductor layer 33 made of an oxide semiconductor.

After forming the semiconductor layer 33, similarly to the first embodiment, by the process illustrated in FIG. 18, the stopper material film 34A is formed on the semiconductor layer 33.

After forming the stopper material film 34A, as illustrated in FIG. 50, for example, by photolithography and etching, the stopper material film 34A is patterned into a predetermined shape, to form the stopper layer 34.

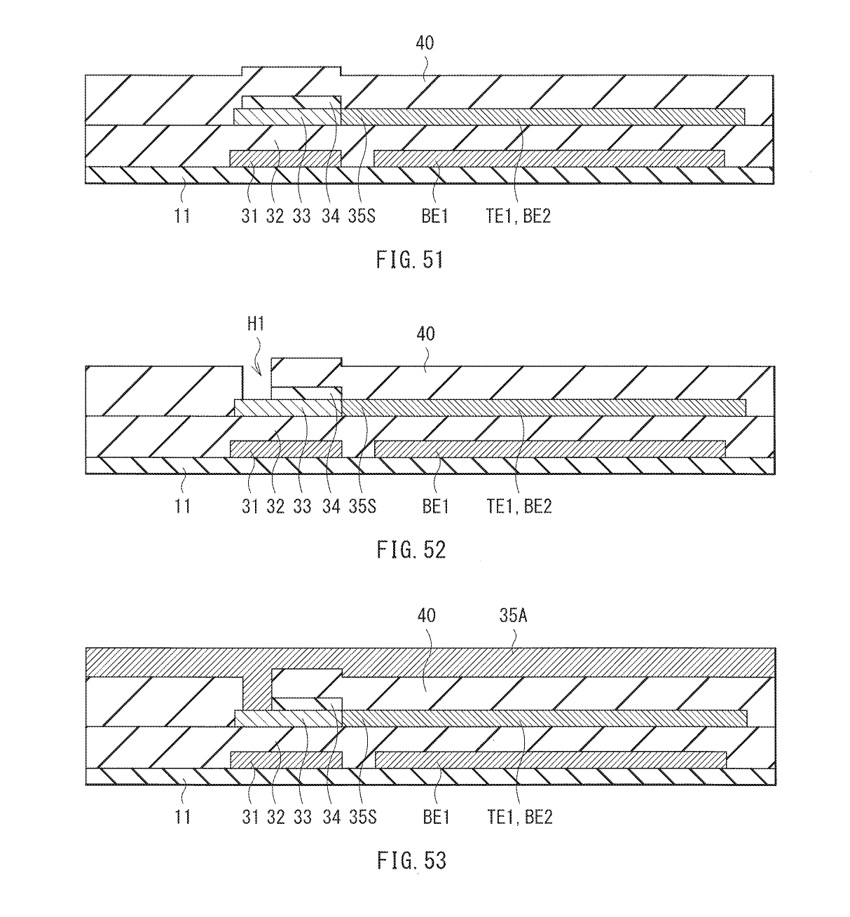

After forming the stopper layer 34, as illustrated in FIG. 51, the interlayer insulating film 40 is formed on the semiconductor layer 33 and the stopper layer 34 by, for example, a plasma CVD method. The interlayer insulating film 40 may be made of a silicon nitride film, a silicon nitride oxide film, or a lamination thereof. At this occasion, a region of the semiconductor layer 33 that is exposed from the stopper layer 34 (the region that is in contact with the interlayer insulating film 40) is lowered in resistance with an increased electron density, due to a reducing action of hydrogen in the film and hydrogen plasma during deposition. In this way, the source electrode 35S, the top electrode TE1 of the lower capacitive element C1, and the bottom electrode BE2 of the upper capacitive element C2 are formed.

After forming the interlayer insulating film 40, as illustrated in FIG. 52, for example, by photolithography and etching, the contact hole H1 is provided in the interlayer insulating film 40 and the stopper layer 34.

Subsequently, as illustrated in FIG. 53, similarly to the first embodiment, by the process illustrated in FIG. 20, the conductive material film 35A is formed on the interlayer insulating film 40.

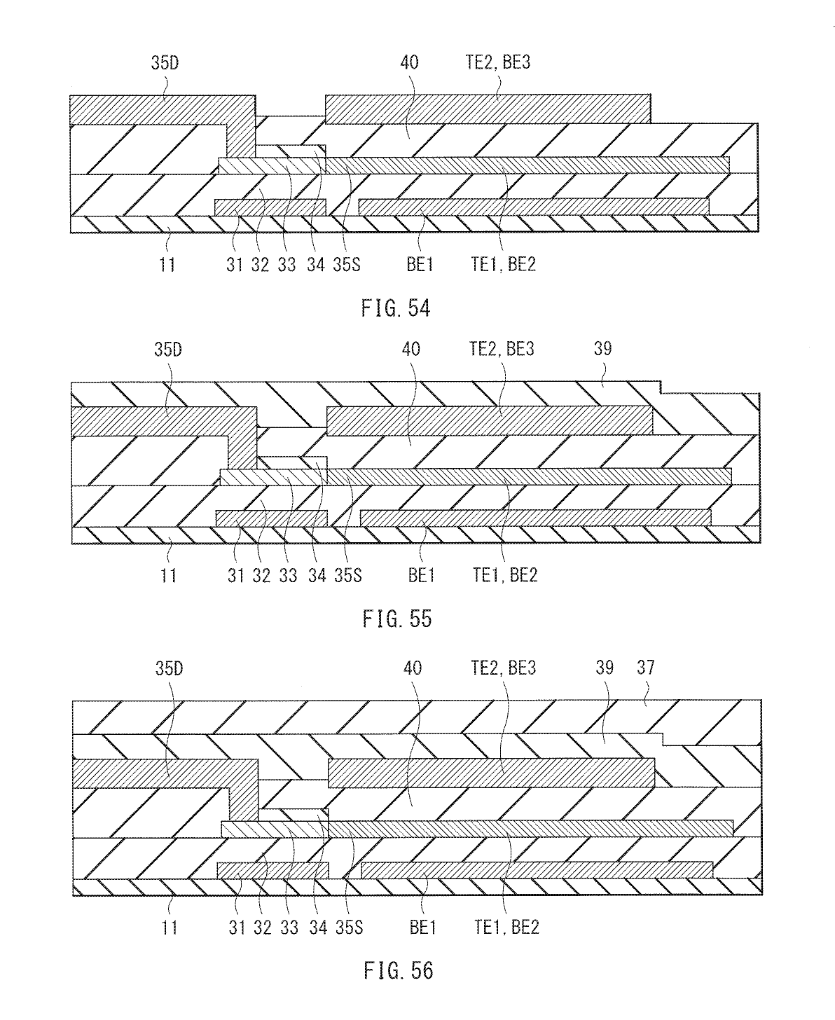

After forming the conductive material film 35A, as illustrated in FIG. 54, for example, by photolithography and etching, the conductive material film 35A is patterned into a predetermined shape, to form the drain electrode 35D, the top electrode TE2 of the upper capacitive element C2, and the bottom electrode BE3 of the uppermost capacitive element C3.

After this, as illustrated in FIG. 54, for example, by a plasma CVD method, the passivation layer 39 made of a silicon nitride film, a silicon nitride oxide film, or a lamination thereof is formed. Thus, the substrate 10B as illustrated in FIGS. 45 and 46 is completed.

### (Processes to Form the Display Element 20)

After forming the substrate 10B, as illustrated in FIG. 55, the planarization layer 37 is formed on the substrate 10B. The material and the formation method of the planarization layer 37 may be similar to those of the first embodiment.

Subsequently, similarly to the first embodiment, a contact hole H2 is provided in the planarization layer 37 by, for example, photolithography and etching. Then, the anode electrode 21 is formed on the planarization layer 37.

After this, similarly to the first embodiment, the barrier rib 22, the organic layer 23, the cathode electrode 24, and the protective layer 25 are formed in this order. After this, the sealing substrate 27 is bonded with the adhesive layer 26. Thus, the display device 100 including the substrate 10B is completed.

The display device 100 operates similarly to the first embodiment.

As described above, in the present modification example, the top electrode TE1 of the lower capacitive element C1 and the bottom electrode BE2 of the upper capacitive element C2 are configured of the oxide semiconductor having the lower resistance value than that of the semiconductor layer 33. Hence, it is possible to form the top electrode TE1 of the lower capacitive element C1 and the bottom electrode BE2 of the upper capacitive element C2 by lowering the resistance of a part of the semiconductor layer 33. Accordingly, it is possible to eliminate processes to form a conductive film, leading to simplification of a manufacturing process.

### Modification Example 2

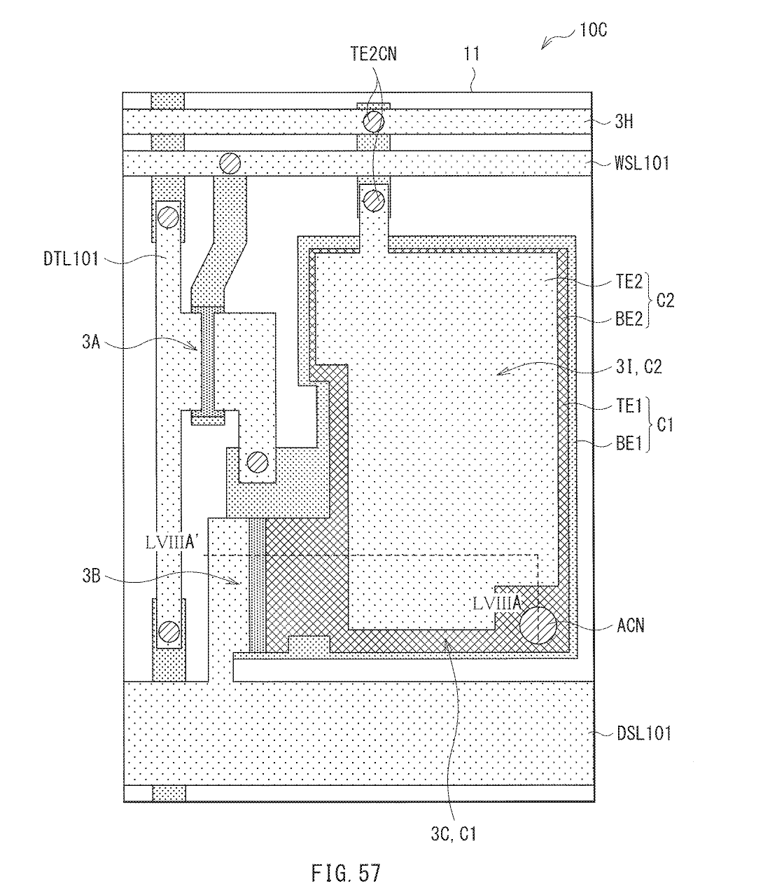

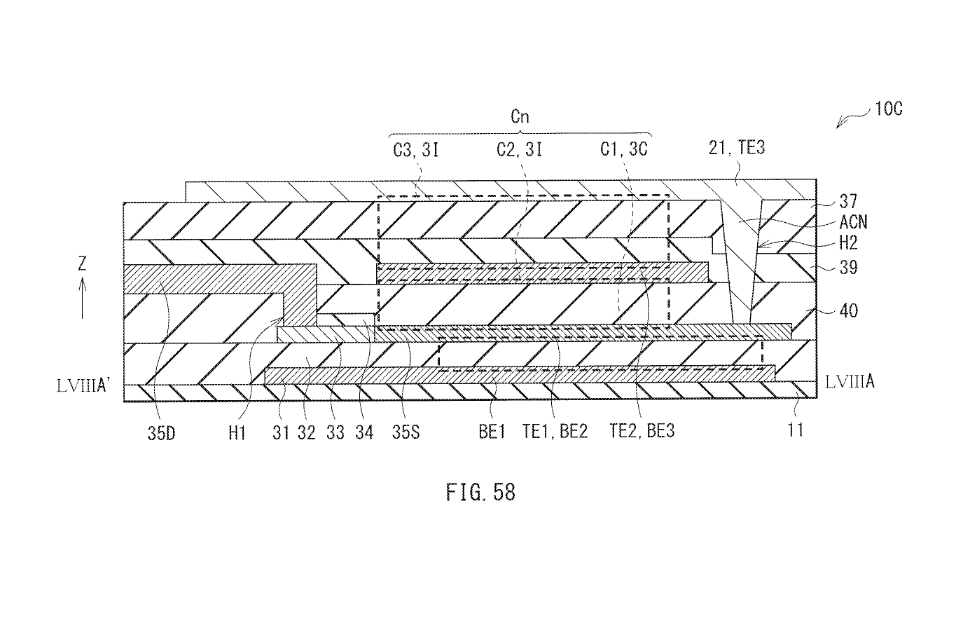

FIG. 57 illustrates an example in which a substrate 10C according to a modification example 2 of the present disclosure is applied to the planar arrangement configuration of the retention capacitor 3C and the auxiliary capacitor 3I illustrated in FIG. 2. FIG. 58 illustrates a cross-sectional configuration along a LVIIA-LVIIA′ line in FIG. 57. The present modification example involves, in the above-described modification example 1, allowing the lower capacitive element C1 to serve as the retention capacitor 3C and allowing the upper capacitive element C2 to serve as the auxiliary capacitor 3I. Otherwise, the substrate 10C may have a similar configuration to that of the substrate 10B according to the above-described modification example 1.

The lower capacitive element C1 may include, on the base 11, the bottom electrode BE1, the gate insulating film 32, and the top electrode TE1. The bottom electrode BE1 of the lower capacitive element C1 may be connected to the gate electrode 31 (the gate g of the drive transistor 3B). The top electrode TE1 of the lower capacitive element C1 may be connected to the source electrode 35S (the source s of the drive transistor 3B).

In other words, the lower capacitive element C1 may be connected between the source s and the gate g of the drive transistor 3B, and may serve as the retention capacitor 3C in the pixel circuit 101 illustrated in FIG. 2.

The upper capacitive element C2 may include, on the base 11, the bottom electrode BE2, the interlayer insulating film 40, and the top electrode TE2. The bottom electrode BE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be provided on the same layer as the drain electrode 35D, but may be uncontinuous with the drain electrode 35D. That is, the top electrode TE2 of the upper capacitive element C2 may be provided as a separate layer from the drain electrode 35D. It is to be noted that the top electrode TE2 of the upper capacitive element C2 may be connected to the ground wiring 3H and the cathode of the light emitting element 3D through a contact TE2CN (refer to FIG. 57).

In other words, the upper capacitive element C2 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

Similarly to the first embodiment, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected, but are connected to, for example, their respective wirings that are different from one another. Thus, in the substrate 10C and the display device 100 including the substrate 10C, it is possible to stack the plurality of capacitive elements C1 to C3 having different operations and functions, leading to enhanced layout efficiency.

Preferably, the lower capacitive element C1 and the upper capacitive element C2 may be capable of maintaining different potentials from one another, similarly to the first embodiment.

Moreover, similarly to the first embodiment, preferably, the charge and discharge period of the lower capacitive element C1 and the charge and discharge period of the upper capacitive element C2 may be different from one another.

Furthermore, as described above, since the lower capacitive element C1 serves as the retention capacitor 3C while the upper capacitive element C2 serves as the auxiliary capacitor 3I, it is possible to reduce a possibility that the retention capacitor 3C fluctuates depending on the thickness of the interlayer insulating film 40. Accordingly, it is possible to restrain influences on luminance due to gain fluctuation in the boot strap operation.

The uppermost capacitive element C3 may include, on the base 11, the bottom electrode BE3, the passivation layer 39 and the planarization layer 37, and the top electrode TE3. The bottom electrode BE3 of the uppermost capacitive element C3 may be common to the top electrode TE2 of the upper capacitive element C2, and may be connected to the ground wiring 3H and the cathode of the light emitting element 3D. The top electrode TE3 of the uppermost capacitive element C3 may be the anode electrode 21 (the anode of the light emitting element 3D).

In other words, the uppermost capacitive element C3 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2. By providing the uppermost capacitive element C3, it is possible to supplement the auxiliary capacitor 3I, further enhancing the correction functions of the pixel circuit 101.

It is to be noted that FIG. 58 represents the layer configuration from the base 11 to the anode electrode 21, and layers above the anode electrode 21 are omitted. Out of the layers illustrated in FIG. 58, FIG. 57 represents the following layers: the base 11, the gate electrode 31 and the bottom electrode BE1 that is on the same layer as the gate electrode 31, the semiconductor layer 33, the source electrode 35S, the top electrode TE1 and the bottom electrode BE2 that are on the same layer as the source electrode 35S, the drain electrode 35D, the top electrode TE2 that is on the same layer as the drain electrode 35D, and the anode contact ACN between the source electrode 35S and the anode electrode 21.

The substrate 10C and the display device 100 including the substrate 10C may be manufactured similarly to the manufacturing method of the above-described modification example 1, except for the shape and the connection relation of the bottom electrode BE1 of the lower capacitive element C1 and the top electrode TE2 of the upper capacitive element C2.

The display device 100 operates similarly to the first embodiment.

Effects of the present modification example are similar to those of the modification example 1 and the second embodiment.

### Modification Example 3

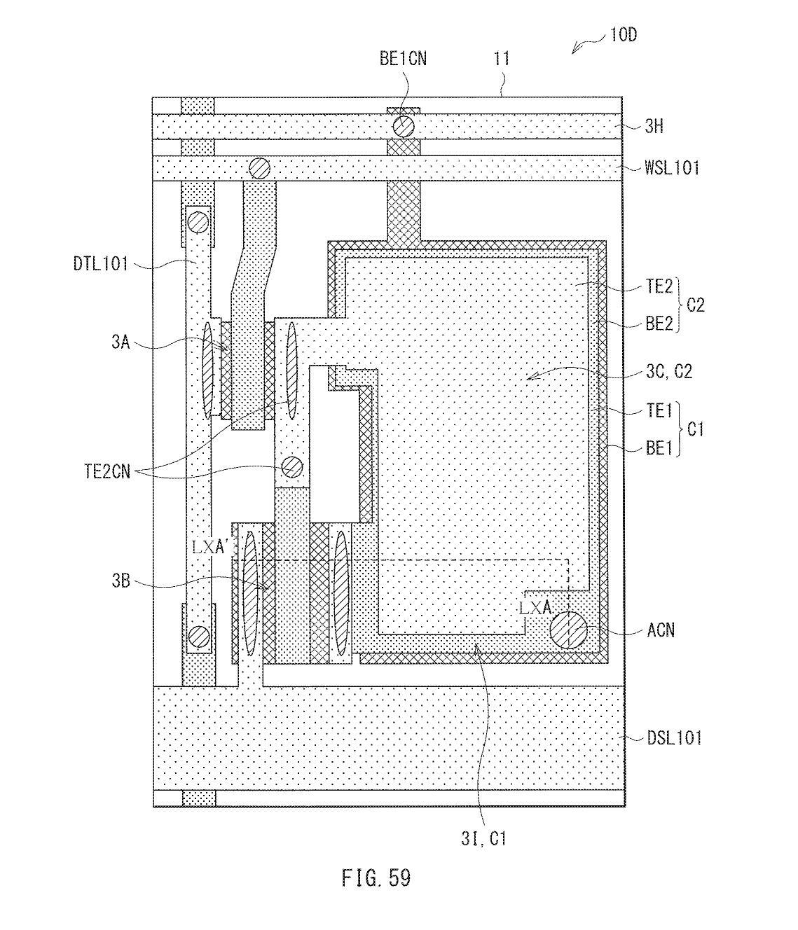

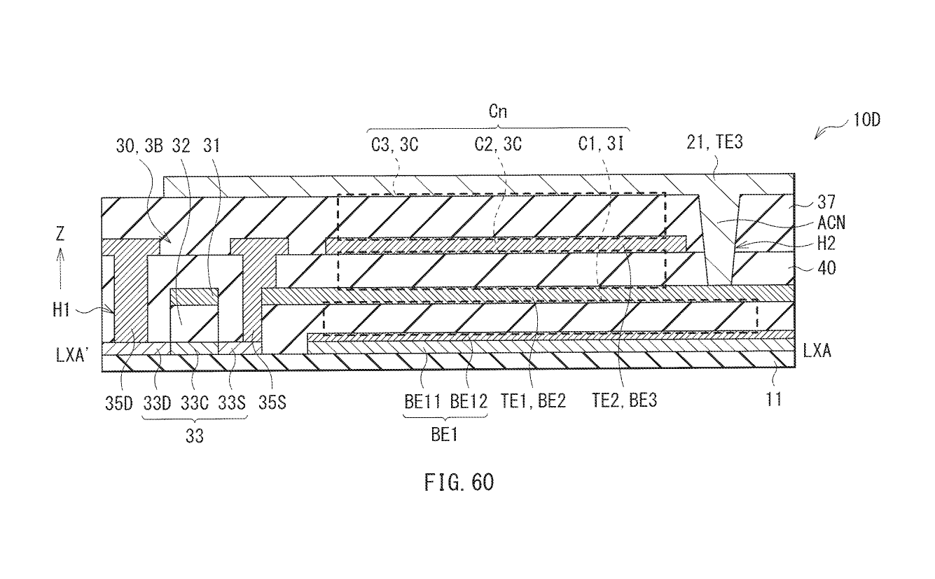

FIG. 59 illustrates an example in which a substrate 10D according to a modification example 3 of the present disclosure is applied to the planar arrangement configuration of the retention capacitor 3C and the auxiliary capacitor 3I illustrated in FIG. 2. FIG. 60 illustrates a cross-sectional configuration along an LXA-LXA′ line in FIG. 59. The substrate 10D may have a same configuration as that of the substrate 10B according to the above-described modification example 1, except that the thin film transistor 30 is of a top gate type, and that the bottom electrode BE1 of the lower capacitive element C1 is configured of an oxide semiconductor having a lower resistance value than that of a channel region of the semiconductor layer 33.

The thin film transistor 30 according to the present modification example may be, for example, a thin film transistor of a top gate type that includes, on the base 11, the semiconductor layer 33, the gate insulating film 32, the gate electrode 31, the interlayer insulating film 40, and the source electrode 35S and the drain electrode 35D in this order. The surface of the base 11 on which the thin film transistor 30 is formed may be planarized by the planarization layer 37. It is to be noted that the thin film transistor 30 illustrated in FIG. 60 corresponds to the drive transistor 3B illustrated in FIG. 59. The anode electrode 21 (the anode of the light emitting element 3D) is connected to the source electrode 35S.

Moreover, in the present modification example, a region of the semiconductor layer 33 on which the gate insulating film 32 and the gate electrode 31 are formed may constitute a channel region 33C. The semiconductor layer 33 may include a source region 33S and a drain region 33D on both sides of the channel region 33C. The source region 33S and the drain region 33D may be configured of an oxide semiconductor having a lower resistance value than that of the channel region 33C. Specifically, the channel region 33C of the semiconductor layer 33 may be configured of, for example, IGZO while the source region 33S and the drain region 33D may be configured of, for example, n⁺IGZO. The source region 33S and the drain region 33D may be lowered in resistance with an increased electron density in the oxide semiconductor, for example, due to a reducing action of hydrogen in the interlayer insulating film 40 and hydrogen plasma during deposition in the manufacturing process.

The lower capacitive element C1 may include, on the base 11, the bottom electrode BE1, the gate insulating film 32, and the top electrode TE1. The bottom electrode BE1 of the lower capacitive element C1 may be provided on the same layer as the semiconductor layer 33, but may be uncontinuous with the semiconductor layer 33. That is, the bottom electrode BE1 of the lower capacitive element C1 may be provided as a separate layer from the semiconductor layer 33. It is to be noted that the bottom electrode BE1 of the lower capacitive element C1 may be connected to the ground wiring 3H and the cathode of the light emitting element 3D through the contact BE1CN (refer to FIG. 59). The top electrode TE1 of the lower capacitive element C1 may be connected to the source electrode 35S (the source s of the drive transistor 3B).

In other words, the lower capacitive element C1 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

The bottom electrode BE1 of the lower capacitive element C1 may preferably have a laminated structure of a semiconductor layer BE11 made of an oxide semiconductor and a metal layer BE12. Thus, the metal layer BE12 allows voltage dependence of capacitance to be reduced, as compared to a case that the bottom electrode BE1 is configured of only an oxide semiconductor. It is therefore possible to obtain sufficient capacitance regardless of a bias voltage.

Preferably, the metal layer BE12 may be configured of, for example, titanium (Ti), molybdenum (Mo), aluminum (Al), or a lamination thereof.

The semiconductor layer BE11 may be preferably configured of crystalline indium gallium oxide (IGO), indium zinc oxide (IZO), or the like. Alternatively, the semiconductor layer BE11 may be preferably configured of amorphous indium tin zinc oxide (ITZO). In this way, it is possible to prevent the semiconductor layer BE11 below from being etched by a mixed chemical of phosphoric acid, nitric acid, and acetic acid when a metal material film that eventually serves as the metal layer BE12 is wet etched with the mixed chemical. It is to be noted that, in a case that the semiconductor layer BE11 is configured of indium gallium zinc oxide (IGZO) as generally used, it is possible to allow the semiconductor layer BE11 to remain selectively by processing the metal material film that eventually serves as the metal layer BE12 by dry etching.

The upper capacitive element C2 may include, on the base 11, the bottom electrode BE2, the interlayer insulating film 40, and the top electrode TE2. The bottom electrode BE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be provided on the same layer as the source electrode 35S and the drain electrode 35D, but may be uncontinuous with the source electrode 35S and the drain electrode 35D. That is, the top electrode TE2 of the upper capacitive element C2 may be provided as a separate layer from the source electrode 35S and the drain electrode 35D. It is to be noted that the top electrode TE2 of the upper capacitive element C2 may be connected to the gate electrode 31 (the gate g of the drive transistor 3B) through a contact TE2CN (refer to FIG. 59).

In other words, the upper capacitive element C2 may be connected between the source s and the gate g of the drive transistor 3B, and may serve as the retention capacitor 3C in the pixel circuit 101 illustrated in FIG. 2.

Similarly to the first embodiment, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected to one another, but are connected to, for example, their respective wirings that are different from one another. Thus, in the substrate 10D and the display device 100 including the substrate 10D, it is possible to stack the plurality of capacitive elements C1 to C3 having different operations and functions, leading to enhanced layout efficiency.

Preferably, the lower capacitive element C1 and the upper capacitive element C2 may be capable of maintaining different potentials from one another, similarly to the first embodiment.

Moreover, similarly to the first embodiment, preferably, the charge and discharge period of the lower capacitive element C1 and the charge and discharge period of the upper capacitive element C2 may be different from one another.

Furthermore, as described above, since the lower capacitive element C1 serves as the retention capacitor 3C while the upper capacitive element C2 serves as the auxiliary capacitor 3I, it is possible to reduce a possibility that the retention capacitor 3C fluctuates depending on the thickness of the interlayer insulating film 40. It is therefore possible to restrain influences on luminance due to gain fluctuation in the boot strap operation.

The uppermost capacitive element C3 may include, on the base 11, the bottom electrode BE3, the planarization layer 37, and the top electrode TE3. The bottom electrode BE3 of the uppermost capacitive element C3 may be common to the top electrode TE2 of the upper capacitive element C2, and may be connected to the gate electrode 31 (the gate g of the drive transistor 3B). The top electrode TE3 of the uppermost capacitive element C3 may be the anode electrode 21 (the anode of the light emitting element 3D).

In other words, the uppermost capacitive element C3 may be connected between the source s and the gate g of the drive transistor 3B, and may serve as the retention capacitor 3C in the pixel circuit 101 illustrated in FIG. 2. By providing the uppermost capacitive element C3, it is possible to supplement the retention capacitor 3C, further enhancing the correction functions of the pixel circuit 101.

It is to be noted that FIG. 60 represents the layer configuration from the base 11 to the anode electrode 21, and layers above the anode electrode 21 are omitted. Out of the layers illustrated in FIG. 60, FIG. 59 represents the following layers: the base 11, the semiconductor layer 33 and the bottom electrode BE1 that is on the same layer as the semiconductor layer 33, the gate electrode 31, the top electrode TE1 and the bottom electrode BE2 that are on the same layer as the gate electrode 31, the source electrode 35S and the drain electrode 35D, the top electrode TE2 that is on the same layer as the source electrode 35S and the drain electrode 35D, and the anode contact ACN between the source electrode 35S and the anode electrode 21.

The substrate 10D and the display device 100 including the substrate 10D may be manufactured, for example, as follows.

### (Processes to Form the Substrate 10D)

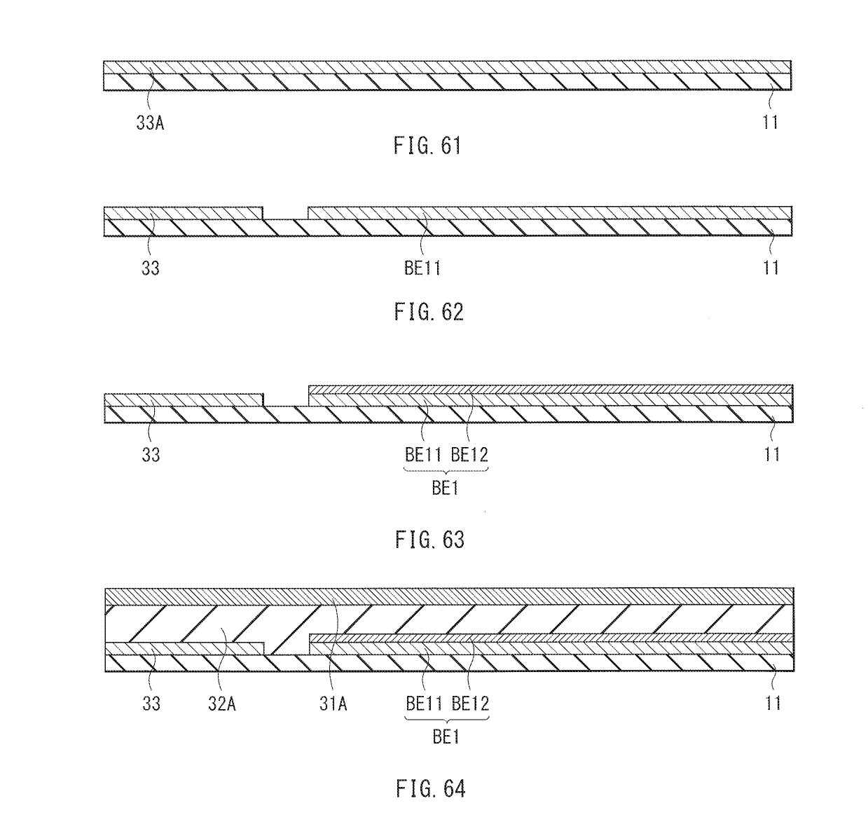

FIGS. 61 to 70 illustrate a method of manufacturing the substrate 10D in the order of procedure. It is to be noted that the same processes as those of the first embodiment will be described with reference to FIGS. 13 to 26.

First, as illustrated in FIG. 61, the base 11 that is configured of the above-mentioned material is prepared. On the base 11, the oxide semiconductor material film 33A is formed with a thickness of about 50 nm by, for example, a sputtering method.

Next, as illustrated in FIG. 62, for example, by photolithography and etching, the oxide semiconductor material film 33A is patterned into an island shape. Thus, the semiconductor layer 33 and the semiconductor layer BE11 of the bottom electrode BE1 of the lower capacitive element C1 are formed.

Subsequently, for example, by a sputtering method, a metal material film (not illustrated) is deposited with a thickness of about 50 nm. The metal material film may be configured of molybdenum (Mo), aluminum (Al), or a laminated film thereof. After this, the metal layer BE 12 is formed on the semiconductor layer BE11 through photolithography and an etching process. In this way, as illustrated in FIG. 63, the bottom electrode BE1 having the laminated structure of the semiconductor layer BE11 and the metal layer BE12 is formed.

In order to form the bottom electrode BE1 having such a laminated structure, preferably, the semiconductor layer BE11 made of an oxide semiconductor remains after the metal layer BE12 is etched. In a case that the metal material film is etched with a mixed chemical of phosphoric acid, nitric acid, and acetic acid, crystalline indium gallium oxide (IGO) indium zinc oxide (IZO), or the like, or amorphous indium tin zinc oxide (ITZO) may be used as a material of the semiconductor layer BE11. This makes it possible to prevent the semiconductor layer BE11 below from being etched by the mixed chemical, allowing the semiconductor layer BE to remain after the metal material film is etched.

On the other hand, in a case of using, as a material of the semiconductor layer BE11, indium gallium zinc oxide (IGZO) as generally used, it is possible to allow the semiconductor layer BE11 to remain selectively by processing the metal material film by dry etching.

Subsequently, as illustrated in FIG. 64, a gate insulating material film 32A is formed with a thickness of about 300 nm over the entire surface of the base 11 by, for example, a plasma CVD method. The gate insulating material film 32A may be configured of a silicon oxide film, an aluminum oxide film, or the like. The silicon oxide film may be formed by a reactive sputtering method as well as a plasma CVD method. On the other hand, the aluminum oxide film may be formed by a reactive sputtering method, a CVD method, or an atomic layer deposition method.

After this, similarly as illustrated in FIG. 64, a gate electrode material film 31A is formed with a thickness of about 300 nm on the gate insulating material film 32A by, for example, a sputtering method. The gate electrode material film 31A may be configured of, for example, a laminated film of an oxide semiconductor layer such as ITO, IZO, or IGZO, a low-resistance metal layer such as molybdenum (Mo), titanium (Ti), aluminum (Al), or copper (Cu), and a metal layer such as titanium (Ti).

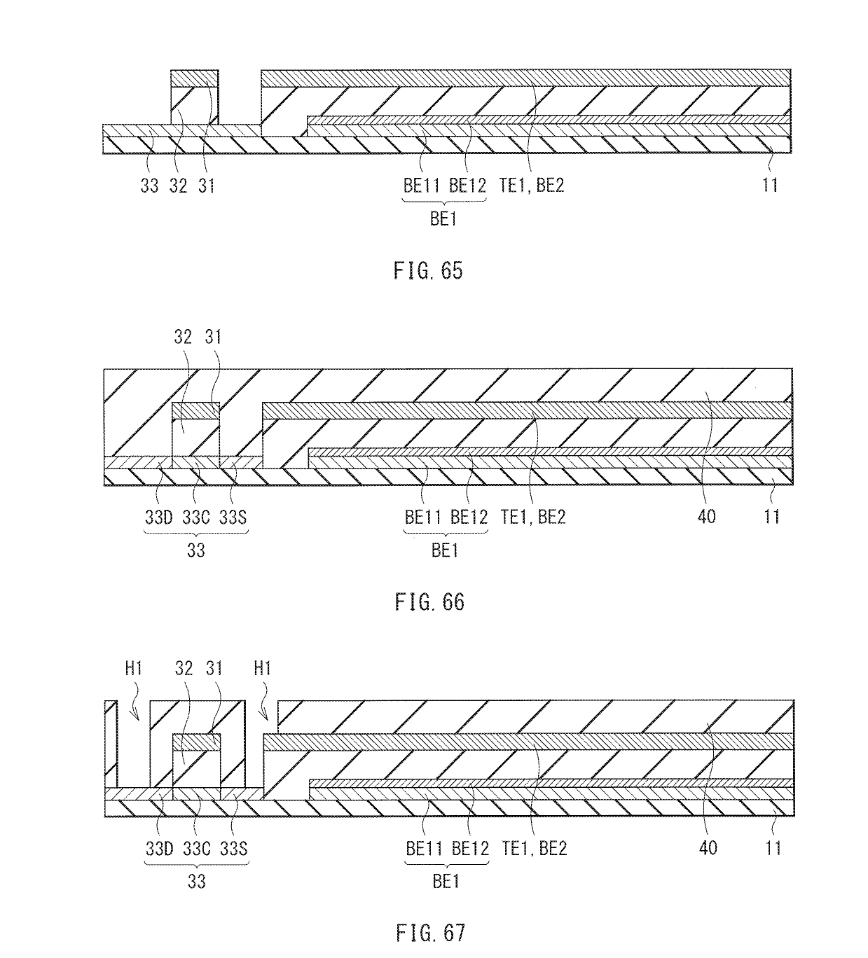

After forming the gate electrode material film 31A, for example, by photolithography and etching, the gate electrode material film 31A is patterned into a desired shape, to form the gate electrode 31 above the channel region 33C of the semiconductor layer 33 as illustrated in FIG. 65. At the same time, the top electrode TE1 of the lower capacitive element C1 and the bottom electrode BE2 of the upper capacitive element C2 are formed.

Subsequently, similarly as illustrated in FIG. 65, the gate insulating material film 32A is etched with the gate electrode 31 as a mask, to form the gate insulating film 32. At this occasion, in a case that the semiconductor layer 33 is made of a crystallized material such as ZnO, IZO, or IGO, it is possible to process the gate insulating film 32 easily with a quite large etching selective ratio using a chemical such as hydrofluoric acid when etching the gate insulating film 32. In this way, the gate insulating film 32 and the gate electrode 31 are formed in the same shape in this order on the channel region 33C of the semiconductor layer 33.

After this, as illustrated in FIG. 66, the interlayer insulating film 40 is formed by, for example, a plasma CVD method. The interlayer insulating film 40 may be made of a silicon nitride film, a silicon oxide film, or a silicon nitride oxide film. The source region 33S and the drain region 33D of the semiconductor layer 33 are lowered in resistance with an increased electron density, due to a reducing action of hydrogen in the interlayer insulating film 40 and hydrogen plasma during deposition in the manufacturing process. It is to be noted that the channel region 33C is not affected by the reducing action and maintains a function as a semiconductor since the gate insulating film 32 and the gate electrode 31 are formed on the channel region 33C.

After forming the interlayer insulating film 40, as illustrated in FIG. 67, for example, by photolithography and etching, the contact hole H1 is provided in the interlayer insulating film 40.

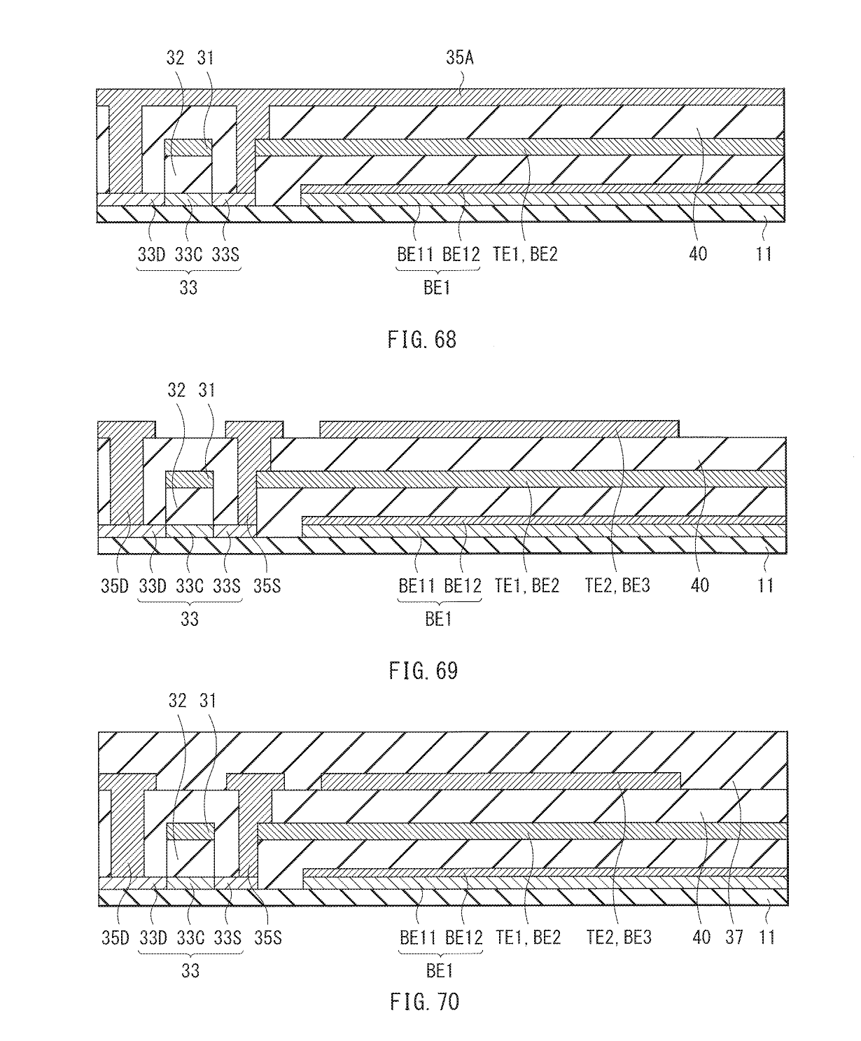

Subsequently, as illustrated in FIG. 68, the conductive material film 35A is formed on the interlayer insulating film 40.

After this, as illustrated in FIG. 69, for example, by photolithography and etching, the conductive material film 35A is patterned into a predetermined shape, to form the source electrode 35S and the drain electrode 35D. At this occasion, the top electrode TE2 of the upper capacitive element C2 and the bottom electrode BE3 of the uppermost capacitive element C3 are formed. Thus, the substrate 10D as illustrated in FIGS. 59 and 60 is completed.

### (Processes to Form the Display Element 20)

After forming the substrate 10D, as illustrated in FIG. 70, the planarization layer 37 is formed on the substrate 10D. The material and the formation method of the planarization layer 37 may be similar to those of the first embodiment.

Subsequently, similarly to the first embodiment, the contact hole H2 is provided in the planarization layer 37 by, for example, photolithography and etching. Then, the anode electrode 21 is formed on the planarization layer 37. The anode electrode 21 serves as the top electrode TE3 of the uppermost capacitive element C3.

After this, similarly to the first embodiment, the barrier rib 22, the organic layer 23, the cathode electrode 24, and the protective layer 25 are formed in this order. After this, the sealing substrate 27 is bonded with the adhesive layer 26. Thus, the display device 100 including the substrate 10D is completed.

The display device 100 operates similarly to the first embodiment.

Effects of the present modification example are similar to those of the modification example 1 and the first embodiment.

### Modification Example 4

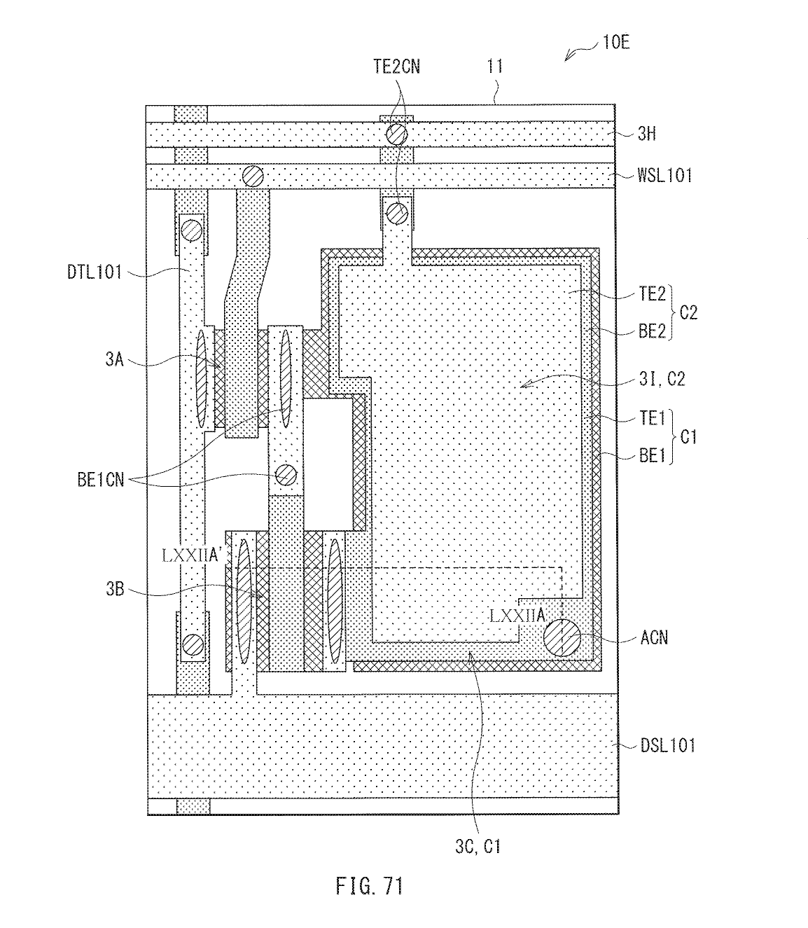

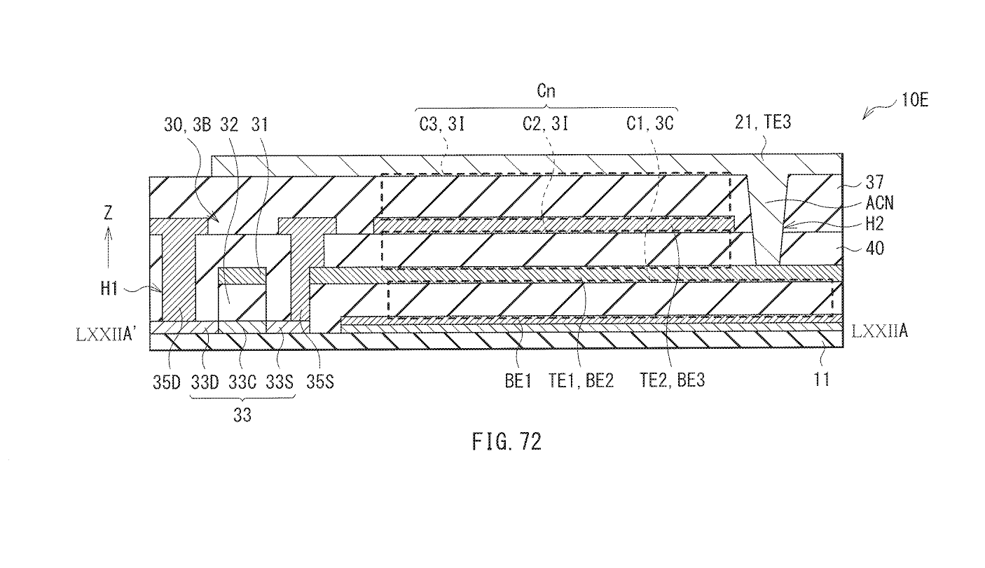

FIG. 71 illustrates an example in which a substrate 10E according to a modification example 4 of the present disclosure is applied to the planar arrangement configuration of the retention capacitor 3C and the auxiliary capacitor 3I illustrated in FIG. 2. FIG. 72 illustrates a cross-sectional configuration along a LXXIIA-LXXIIA′ line in FIG. 71. The present modification example involves, in the substrate 10D according to the above-described modification example 3, allowing the lower capacitive element C1 to serve as the retention capacitor 3C and allowing the upper capacitive element C2 to serve as the auxiliary capacitor 3I. Otherwise, the substrate 10E may have a similar configuration to that of the substrate 10D according to the above-described modification example 3.

The lower capacitive element C1 may include, on the base 11, the bottom electrode BE1, the gate insulating film 32, and the top electrode TE1. The bottom electrode BE1 of the lower capacitive element C1 may be provided on the same layer as the semiconductor layer 33, but may be uncontinuous with the semiconductor layer 33. That is, the bottom electrode BE1 of the lower capacitive element C1 may be provided as a separate layer from the semiconductor layer 33. It is to be noted that the bottom electrode BE1 of the lower capacitive element C1 may be connected to the gate electrode 31 (the gate g of the drive transistor 3B) through the contact BE1CN (refer to FIG. 71). The top electrode TE1 of the lower capacitive element C1 may be connected to the source electrode 35S (the source s of the drive transistor 3B).

In other words, the lower capacitive element C1 may be connected between the source s and the gate g of the drive transistor 3B, and may serve as the retention capacitor 3C in the pixel circuit 101 illustrated in FIG. 2.

The upper capacitive element C2 may include, on the base 11, the bottom electrode BE2, the interlayer insulating film 40, and the top electrode TE2. The bottom electrode TE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be provided on the same layer as the source electrode 35S and the drain electrode 35D, but may be uncontinuous with the source electrode 35S and the drain electrode 35D. That is, the top electrode TE2 of the upper capacitive element C2 may be provided as a separate layer from the source electrode 35S and the drain electrode 35D. It is to be noted that the top electrode TE2 of the upper capacitive element C2 may be connected to the ground wiring 3H and the cathode of the light emitting element 3D through a contact TE2CN (refer to FIG. 71).

In other words, the upper capacitive element C2 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

Similarly to the first embodiment, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected, but are connected to, for example, their respective wirings that are different from one another. Thus, in the substrate 10E and the display device 100 including the substrate 10E, it is possible to stack the plurality of capacitive elements C1 to C3 having different operations and functions, leading to enhanced layout efficiency.

Preferably, the lower capacitive element C1 and the upper capacitive element C2 may be capable of maintaining different potentials from one another, similarly to the first embodiment.

Moreover, similarly to the first embodiment, preferably, the charge and discharge period of the lower capacitive element C1 and the charge and discharge period of the upper capacitive element C2 may be different from one another.

Furthermore, as described above, since the lower capacitive element C1 serves as the retention capacitor 3C while the upper capacitive element C2 serves as the auxiliary capacitor 3I, it is possible to reduce a possibility that the retention capacitor 3C fluctuates depending on the thickness of the interlayer insulating film 40. Accordingly, it is possible to restrain influences on luminance due to gain fluctuation in the boot strap operation.

The uppermost capacitive element C3 may include, on the base 11, the bottom electrode BE3, the planarization layer 37, and the top electrode TE3. The bottom electrode BE3 of the uppermost capacitive element C3 may be common to the top electrode TE2 of the upper capacitive element C2, and may be connected to the ground wiring 3H and the cathode of the light emitting element 3D. The top electrode TE3 of the uppermost capacitive element C3 may be the anode electrode 21 (the anode of the light emitting element 3D).

In other words, the uppermost capacitive element C3 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2. By providing the uppermost capacitive element C3, it is possible to supplement the auxiliary capacitor 3I, further enhancing the correction functions of the pixel circuit 101.

It is to be noted that FIG. 72 represents the layer configuration from the base 11 to the anode electrode 21, and layers above the anode electrode 21 are omitted. Out of the layers illustrated in FIG. 72, FIG. 71 represents the following layers: the base 11, the semiconductor layer 33 and the bottom electrode BE1 that is on the same layer as the semiconductor layer 33, the gate electrode 31, the top electrode TE1 and the bottom electrode BE2 that are on the same layer as the gate electrode 31, the source electrode 35S and the drain electrode 35D, the top electrode TE2 that is on the same layer as the source electrode 35S and the drain electrode 35D, and the anode contact ACN between the source electrode 35S and the anode electrode 21.

The substrate 10E and the display device 100 including the substrate 10E may be manufactured similarly to the manufacturing method of the above-described modification example 3, except for the shape and the connection relation of the bottom electrode BE1 of the lower capacitive element C1 and the top electrode TE2 of the upper capacitive element C2.

The display device 100 operates similarly to the first embodiment.

Effects of the present modification example are similar to those of the modification example 3 and the second embodiment.

### Modification Example 5

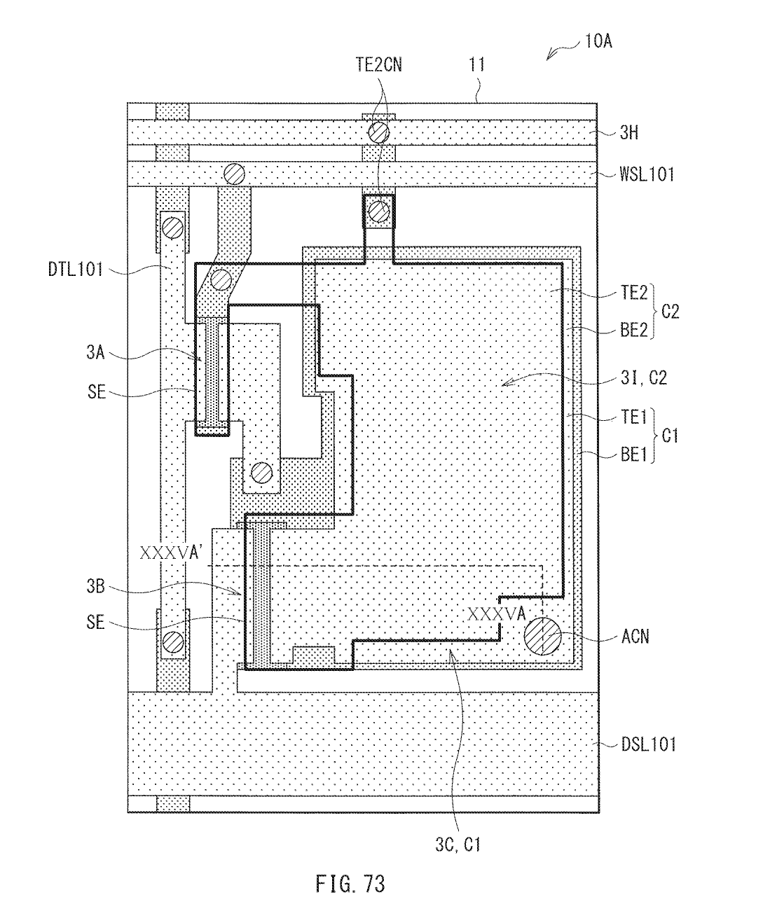

FIG. 73 illustrates an example in which a substrate 1 OF according to a modification example 5 of the present disclosure is applied to the planar arrangement configuration of the retention capacitor 3C and the auxiliary capacitor 3I illustrated in FIG. 2. The substrate 1 OF may have a same configuration as that of the substrate 10A according to the above-described second embodiment, except that the top electrode TE2 of the upper capacitive element C2 is connected to a shield electrode SE of the writing transistor 3A and/or the drive transistor 3B. Therefore, description will be given with similar components denoted by similar reference numerals.

The writing transistor 3A and/or the drive transistor 3B may have the shield electrode SE so that the shield electrode SE covers the respective channel regions. The writing transistor 3A and/or the drive transistor 3B may be a thin film transistor of a bottom gate type that does not include the upper gate electrode 38 as described in the first and the second embodiments, but includes only the lower gate electrode 31.

The upper capacitive element C2 may include, on the base 11, the bottom electrode BE2, the first passivation layer 36, and the top electrode TE2. The bottom electrode BE2 of the upper capacitive element C2 may be common to the top electrode TE1 of the lower capacitive element C1, and may be connected to the source electrode 35S (the source s of the drive transistor 3B). The top electrode TE2 of the upper capacitive element C2 may be provided on the same layer as the shield electrode SE, and may be connected to the shield electrode SE. It is to be noted that the top electrode TE2 of the upper capacitive element C2 may be connected to the ground wiring 3H and the cathode of the light emitting element 3D through a contact TE2CN (refer to FIG. 73). Accordingly, the shield electrode SE is supplied with a cathode potential.

In other words, the upper capacitive element C2 may be connected between the source s of the drive transistor 3B and the ground wiring 3H (the cathode of the light emitting element 3D) in parallel with the light emitting element 3D, and may serve as the auxiliary capacitor 3I in the pixel circuit 101 illustrated in FIG. 2.

Similarly to the first embodiment, the bottom electrode BE1 of the lower capacitive element C1 and the top electrode TE2 of the upper capacitive element C2 are electrically independent from one another. In other words, the bottom electrode BE1 of the lower capacitive element C1 and the top electrode TE2 of the upper capacitive element C2 are not electrically connected, but are connected to, for example, their respective wirings that are different from one another. Thus, in the substrate 10F and the display device 100 including the substrate 10F, it is possible to stack the plurality of capacitive elements C1 to C3 having different operations and functions, leading to enhanced layout efficiency.

### Modification Examples 6 and 7

Thus far, description has been given on the display device 100 using organic EL display. However, the present disclosure may also be applied to a case of using the plurality of capacitive elements Cn having different operations and functions in other display devices such as liquid crystal display or electrophoretic display.

### Modification Example 6

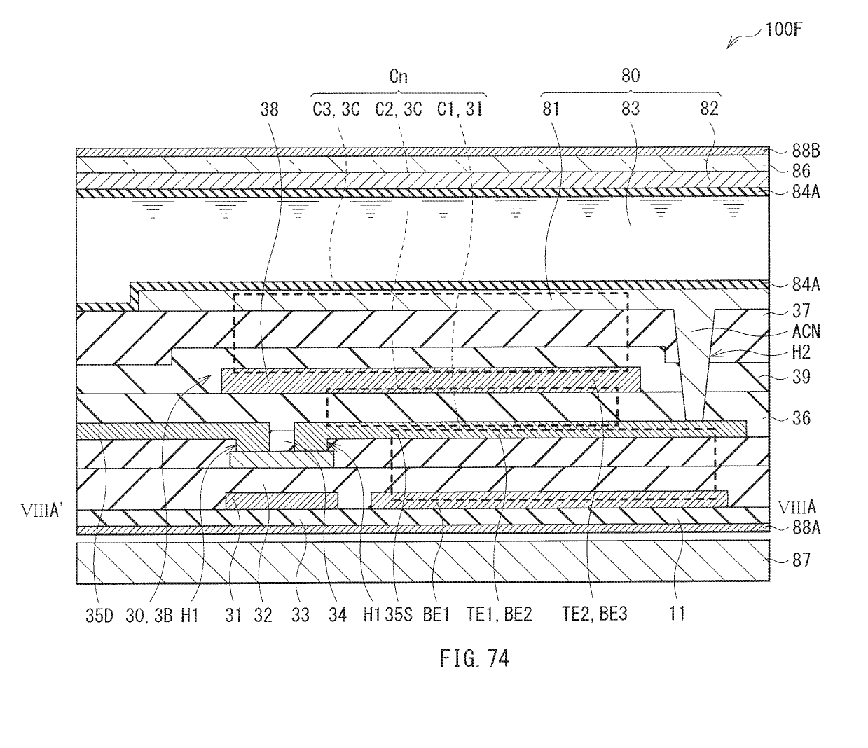

FIG. 74 illustrates a cross-sectional configuration of a display device 100F according to a modification example 6 of the present disclosure. The present modification example involves a display element 80 that is configured of a liquid crystal display element. Otherwise, the display device 100F has similar configurations, functions and effects to those of the display device 100 according to the above-described embodiment, and may be manufactured similarly to the above-described embodiment. Therefore, description will be given with similar components denoted by same reference numerals.

The display element 80 may have a configuration in which, for example, a liquid crystal layer 83 is sealed between a pixel electrode 81 and an opposite electrode 82. The faces on the liquid crystal layer 83 side of the pixel electrode 81 and the opposite electrode 82 may be provided with orientation films 84A and 84B. The pixel electrode 81 may be provided for each pixel and may be connected to the source electrode 35S through the contact hole ACN provided in the planarization layer 37. The opposite electrode 82 may be provided, on an opposite substrate 86, as a common electrode to a plurality of pixels and is configured to be maintained at, for example, a common potential. The liquid crystal layer 83 may be configured of a liquid crystal that is to be driven by, for example, a vertical alignment (VA) mode, a twisted nematic (TN) mode, an in plane switching (IPS) mode, or the like.

Moreover, below the base 11, there may be provided a backlight 87. On the backlight 87 side of the base 11 and on the opposite substrate 86, polarization plates 88A and 88B may be attached.

### Modification Example 7

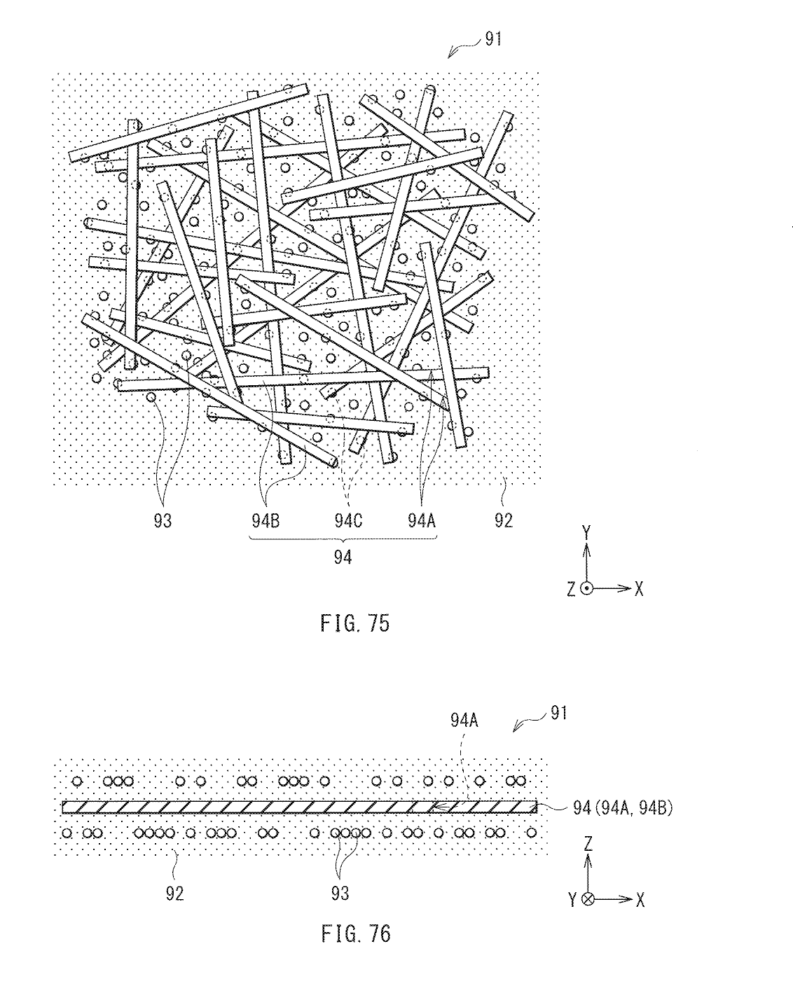

FIG. 75 illustrates a planar configuration of an electrophoretic element 91 that constitutes a display element of a display device according to a modification example 7 of the present disclosure. FIG. 76 illustrates a cross-sectional configuration of the electrophoretic element 91. The electrophoretic element 91 is adapted to produce contrast utilizing an electrophoretic phenomenon and may be applied to various electronic apparatuses such as display devices. The electrophoretic element 91 may include, in an insulating liquid 92, a phoretic particle 93 (a first particle) and a porous layer 94 having a pore 94A. It is to be noted that FIGS. 75 and 76 schematically illustrate a configuration of the electrophoretic element 91 and the illustration may be different from actual dimentions or shapes.

The insulating liquid 92 may be configured of, for example, an organic solvent such as paraffin or isoparaffin. For the insulating liquid 92, either one kind of organic solvent or a plurality of kinds of organic solvents may be used. A viscosity and a refractive index of the insulating liquid 92 may be preferably as low as possible. Lowering the viscosity of the insulating liquid 92 allows mobility (response speed) of the phoretic particle 93 to be enhanced. In accordance with this, energy (power consumption) for movement of the phoretic particle 93 is reduced. Lowering the refractive index of the insulating liquid 92 allows an increase in a difference in refractive index between the insulating liquid 92 and the porous layer 94, leading to higher reflectivity of the porous layer 94.

The phoretic particle 93 dispersed in the insulating liquid 92 may be one charged particle, or two or more charged particles. Such a charged photeric particle 93 is adapted to move through the pore 94A in response to electric field. The phoretic particle 93 has an arbitrary optical reflective characteristic (light reflectivity). A difference between the light reflectivity of the phoretic particle 93 and the light reflectivity of the porous layer 94 allows contrast to be produced. For example, the phoretic particle 93 may perform bright display while the porous layer 94 may perform dark display. Alternatively, the phoretic particle 93 may perform dark display while the porous layer 94 may perform bright display.

When viewing the electrophoretic element 91 from the outside, in the case that the phoretic particle 93 performs bright display, the phoretic particle 93 is visually recognized in, for example, white color or near white color. In the case that the phoretic particle 93 performs dark display, the phoretic particle 93 is visually recognized in, for example, black color or near black color. The color of the phoretic particle 93 is not limited as long as it is possible to produce contrast.

The phoretic particle 93 may be configured of, for example, an organic pigment, an inorganic pigment, a dye, a carbon material, a metal material, a metal oxide, particles (powder) of glass or a polymer material (a resin), and so forth. For the phoretic particle 93, either one kind of these, or two or more kinds of these may be used. It may be possible to configure the phoretic particle 93 of a crushed particle, a capsule particle, and so forth of a resin solid content that includes the above-mentioned particle. It is to be noted that materials that correspond to the above-mentioned carbon material, the metal material, the metal oxide, the glass, or the polymer material are excluded from the materials that correspond to the organic pigment, the inorganic pigment, or the dye. A particle diameter of the phoretic particle 93 may be, for example, 30 nm to 300 nm both inclusive.

Selection of a specific material of the phoretic particle 93 may be made, for example, according to a role the phoretic particle 93 plays in producing contrast. In the case that the phoretic particle 93 performs bright display, for example, the metal oxide such as titanium oxide, zinc oxide, zirconium oxide, barium titanate, or potassium titanate, or the like may be used for the phoretic particle 93. In the case that the phoretic particle 93 performs dark display, for example, the carbon material such as carbon black, the metal oxide such as a copper-chromium oxide, a copper-manganese oxide, a copper-iron-manganese oxide, a copper-chromium-manganese oxide, and a copper-iron-chromium oxide, or the like may be used for the phoretic particle 93. Among them, the carbon material may be preferably used for the phoretic particle 93. The phoretic particle 93 made of the carbon material exhibits excellent chemical stability, mobility, and light absorbing property.

An amount (a concentration) of the phoretic particle 93 contained in the insulating liquid 92 may be, though not being limited in particular, 0.1 percent by weight to 10 percent by weight both inclusive, for example. In this concentration range, shielding property and mobility of the phoretic particle 93 are secured. Specifically, when the amount of the phoretic particle 93 contained is smaller than 0.1 percent by weight, the phoretic particle 93 hardly shield (conceal) the porous layer 94, causing a possibility of difficulty in generating sufficient contrast. On the other hand, when the amount of the phoretic particle 93 contained is larger than 10 percent by weight, dispersion property of the phoretic particle 93 is lowered. Therefore, there is a possibility of difficulty in phoresis of the phoretic particle 93, causing condensation.

The porous layer 94 is adapted to be capable of shielding the phoretic particle 93, and may include a fibrous structure 94B and non-phoretic particle 94C (a second particle) that is supported by the fibrous structure 94B. The porous layer 94 may be a three-dimensional structure (an irregular network structure such as nonwoven fabric) formed by the fibrous structure 94B, and may be provided with a plurality of gaps (the pores 94A). The fibrous structure 94B constitutes the three-dimensional structure of the porous layer 94, allowing light (external light) to be irregularly reflected (multiply-scattered) and increasing reflectivity of the porous layer 94. Therefore, it is possible to obtain high reflectivity even in a case that a thickness of the porous layer 94 is small. This makes it possible to improve contrast of the electrophoretic element 91 and to reduce the energy for the movement of the phoretic particle 93. Moreover, an average pore diameter of the pore 94A becomes larger, and the number of the pores 94A provided in the porous layer 94 is increased. Thus, the movement of the phoretic particle 93 through the pore 94A is facilitated, increasing response speed and further reducing the energy for the movement of the phoretic particle 93. The thickness of the porous layer 94 may be, for example, 5 μm to 100 μm both inclusive.

The fibrous structure 94B may be a fibrous substance having a sufficient length with respect to a fiber diameter (diameter). For example, a plurality of fibrous structures 94B may be collected and randomly overlapped to constitute the porous layer 94. One fibrous structure 94B may be randomly entangled to constitute the porous layer 94. Alternatively, the porous layer 94 formed of one fibrous structure 94B and the porous layer 94 formed of the plurality of fibrous structures 94B may be mixedly present.

The fibrous structure 94B may be configured of, for example, a polymer material such as nylon or an inorganic material such as titanium oxide, or the like. The fibrous structure 94B may extend, for example, linearly. The fibrous structure 94B may have whatever shape. For example, the fibrous structure 94B may shrink, or bends halfway. Alternatively, the fibrous structure 94B may be branched halfway.

For the fibrous structure 94B, one that has different light reflectivity from that of the phoretic particle 93 may be preferably used. Thus, it is possible to easily generate contrast due to a difference in light reflectivity between the porous layer 94 and the phoretic particle 93. The fibrous structure 94B that exhibits light transparency (that is, colorless and transparent) in the insulating liquid 92 may also be used.

The pore 94A is configured by overlap of the plurality of the fibrous structures 94B or by entanglement of one fibrous structure 94B. The pore 94A may preferably have an average pore diameter as large as possible in order to facilitate the movement of the phoretic particle 93 through the pore 94A. The average pore diameter of the pore 94A may be, for example, 0.1 μm to 10 μm both inclusive.

The non-phoretic particle 94C is fixed to the fibrous structure 94B, and has different light reflectivity from that of the phoretic particle 93. The non-phoretic particle 94C may be configured of a same material as that of the above-mentioned phoretic particle 93. Specifically, in a case that the non-phoretic particle 94C (the porous layer 94) performs bright display, a same material as that of the phoretic particle 93 in a case that the phoretic particle 93 performs bright display may be used. In a case that the non-phoretic particle 94C (the porous layer 94) performs dark display, a same material as that of the phoretic particle 93 in a case that the phoretic particle 93 performs dark display may be used. In a case that the porous layer 94 performs bright display, the non-phoretic particle 94C may be preferably configured of a metal oxide. Thus, it is possible to obtain excellent chemical stability, fixation and light reflectivity. In particular, the non-phoretic particle 94C may be preferably configured of a metal oxide having a high refractive index, for example, titanium oxide of rutile type. The constituent material of the non-phoretic particle 94C may be same as or different from that of the phoretic particle 93. The non-phoretic particle 94C may be fully buried inside of the fibrous structure 94B, or alternatively, may be partially exposed from the fibrous structure 94B. A color that is visually recognized externally when the non-phoretic particle 94C performs bright display or dark display is similar to that as described above with respect to the phoretic particle 93.

The porous layer 94 may be manufactured as follows, for example. First, a constituent material of the fibrous structure 94B such as a polymer material or the like is dissolved in an organic solvent or the like, preparing a spinning solution. Next, the non-phoretic particle 94C is added to the spinning solution, and the solution is sufficiently stirred to allow the non-phoretic particle 94C to be dispersed. Finally, spinning is carried out by, for example, an electrostatic spinning method from the spinning solution. Thus, the non-phoretic particle 94C is fixed to the fibrous structure 94B to form the porous layer 94. In order to form the pore 94A in the porous layer 94, a polymer film may be subjected to a piercing process using laser. Alternatively, a cloth knitted of a synthetic fiber or the like, or an open-cell porous polymer, or the like may also be used for the porous layer 94.

The electrophoretic element 91 is adapted, as described above, to generate contrast due to the difference between the light reflectivity of the phoretic particle 93 and the light reflectivity of the porous layer 94. Specifically, out of the phoretic particle 93 and the porous layer 94, the light reflectivity of what performs bright display is higher than the light reflectivity of what performs dark display. Preferably, the light reflectivity of the non-phoretic particle 94C is higher than that of the phoretic particle 93, allowing the porous layer 94 to perform bright display and allowing the phoretic particle 93 to perform dark display. By performing such display, the light reflectivity in performing bright display is allowed to be remarkably increased utilizing the irregular reflection of light by the porous layer 94 (the three-dimensional structure). Therefore, in accordance with this, the contrast is remarkably enhanced.

In the electrophoretic element 91, within a range where an electric field is applied, the phoretic particle 93 moves through the pore 94A of the porous layer 94. In correspondence with a region where the phoretic particle 93 have moved and a region where the phoretic particle 93 have not moved, either bright display or dark display is performed, allowing an image to be displayed.

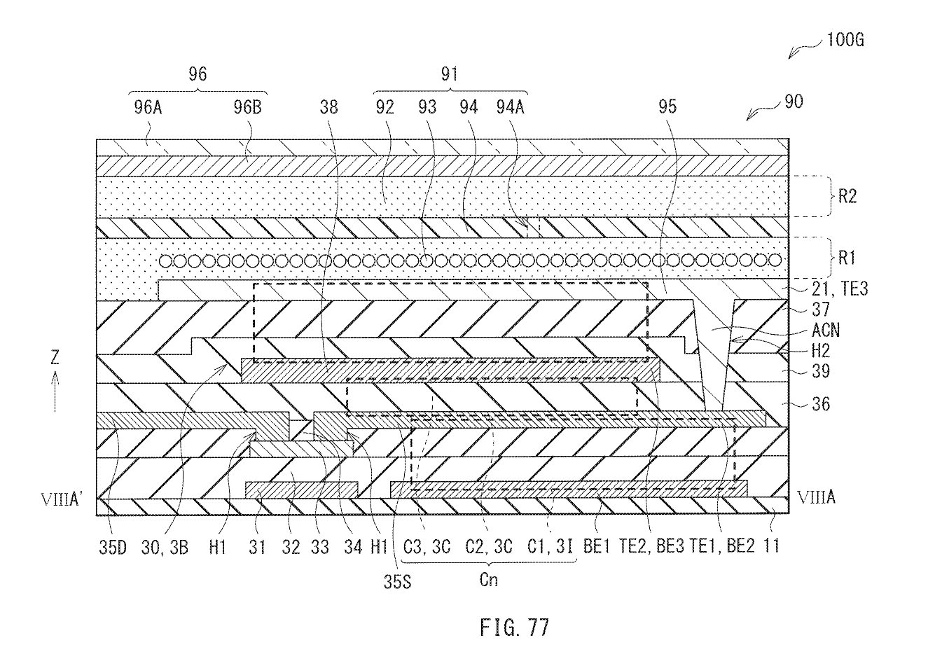

FIG. 77 illustrates a cross-sectional configuration of a display device 100G using the electrophoretic element 91 as the display element. The display device 100G is an electrophoretic display device (a so-called electronic paper display device) that is adapted to display an image (for example, character information and so forth) utilizing the electrophoretic phenomenon. The display device 100G may include, for example, on the substrate 10, a display element 90 that is configured of the electrophoretic element 91.

The display element 90 may include a pixel electrode 95, the above-described electrophoretic element 91, and an opposite substrate 96. A spacer (not illustrated) may be interposed between the planarization layer 37 on the substrate 10 and the opposite substrate 96.

The pixel electrode 95 may be formed of, for example, a metal material such as gold (Au), silver (Ag), or copper (Cu). The pixel electrode 95 may be connected to the source electrode 35S through the contact hole H2. The pixel electrode 95 may be arranged, for example, in a matrix or in a segment shape according to a pixel layout.

The opposite substrate 96 may include, for example, a plate member 96A such as glass and an opposite electrode 96B made of a light transmitting conductive material (a transparent electrode material) such as ITO. The opposite electrode 96B may be formed on an entire surface (a surface facing the base 11) of the plate member 96A. The opposite electrode 96B may be arranged, similarly to the pixel electrode 95, in a matrix or in a segment shape.

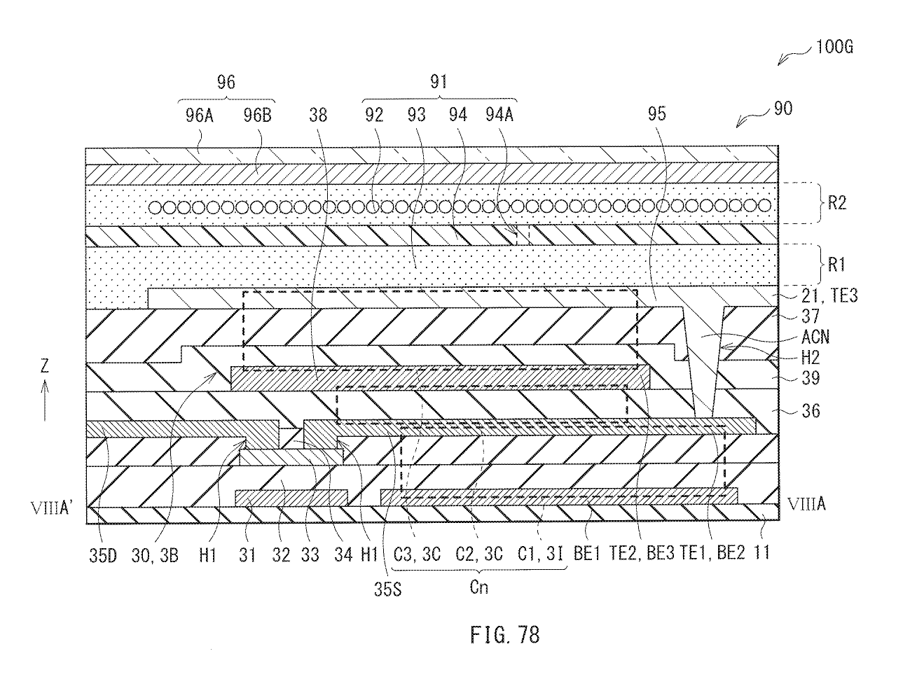

The electrophoretic element 91 may include, as described above, in the insulating liquid 92, the phoretic particle 93, the porous layer 94 including the plurality of pores 94A. The insulating liquid 92 may be filled in a space between the planarization layer 37 and the opposite substrate 96. The porous layer 94 may be supported by, for example, the spacer (not illustrated). The space where the insulating liquid 92 is filled may be divided into, for example, a retreat region R1 and a display region R2 with the porous layer 94 as a boundary. The retreat region R1 is on the side closer to the pixel electrode 95. The display region R2 is on the side closer to the opposite electrode 96B. Configurations of the insulating liquid 92, the phoretic particle 93, and the porous layer 94 may be same as described above. It is to be noted that, in FIG. 77 and FIG. 78, which is to be described later, part of the pores 94A are shown for simplicity of the figures.

The porous layer 94 may be adjacent to either one of the pixel electrode 95 and the opposite electrode 96B. The retreat region R1 and the display region R2 do not have to be divided clearly. The phoretic particle 93 is adapted to move toward the pixel electrode 95 or the opposite electrode 96B in response to an electric field.

A thickness of the spacer (not illustrated) may be, for example, 10 μm to 100 μm both inclusive. The thickness of the spacer (not illustrated) is preferably as thin as possible. Thus, it is possible to reduce power consumption. The spacer (not illustrated) may be configured of, for example, an insulating material such as a polymer material, or the like, and may be provided in a lattice shape between the planarization layer 37 and the opposite substrate 96. An arrangement and a shape of the spacer (not illustrated) are not limited in particular, but may be preferably provided so that the movement of the phoretic particle 93 is not hindered and the phoretic particles 93 are distributed uniformly.

In the display device 100C in an initial state, the phoretic particle 93 is disposed in the retreat region R1 (FIG. 77). In this case, the phoretic particle 93 is shielded by the porous layer 94 in all the pixels. Therefore, when viewed from the opposite substrate 96 side, the electrophoretic element 91 is in a no-contrast-generated (no-display) state.

On the other hand, when a pixel is selected by the thin film transistor 30 on the substrate 10, and an electric filed is applied between the pixel electrode 95 and the opposite electrode 96B, as illustrated in FIG. 78, the phoretic particle 93 moves, for each pixel, from the retreat region R1 to the display region R2 through the porous layer 94 (the pores 94A). In this case, there are a pixel where the phoretic particle 93 is shielded by the porous layer 94 and a pixel where the phoretic particle 93 is not shielded by the porous layer 94. Therefore, when viewed from the opposite substrate 96 side, the electrophoretic element 91 is in a contrast-generated state. Thus, an image is displayed.

### Application Examples

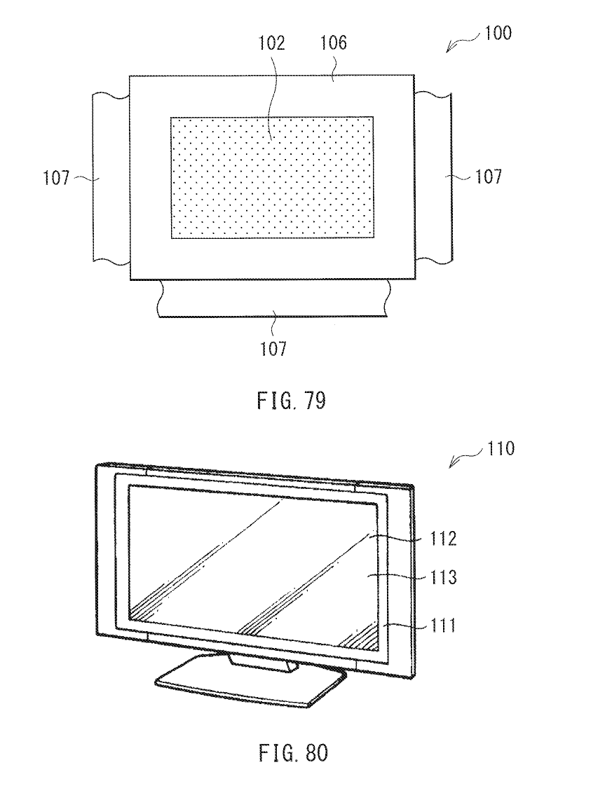

In the following, description will be given on application examples of the display device according to the above-described example embodiment with reference to FIGS. 79 to 82. The display device according to above-described example embodiment may be applied to an electronic apparatus in various fields, for example, as well as a television set, a personal computer of desktop, notebook, or tablet types, a monitor device of a game machine, a digital signage, a mobile terminal device such as a mobile phone, a smart phone, an electronic book reader, a portable music player.

### (Module)

The display device according to above-described example embodiment may be incorporated, in a form of a module as illustrated in FIG. 79, in an electronic apparatus such as application examples 1 to 3, which will be exemplified in the followings. The module may include, for example, a pixel array section 102 (refer to FIG. 1) in the center region and a peripheral region 106 outside the pixel array section 102. In the peripheral region 106, provided is a drive section (the signal selector 103, the main scanner 104, and the power scanner 105) as illustrated in FIG. 1. Also in the peripheral region 106, provided are external connection terminals (not illustrated) that are extended from wirings of the pixel array section 102. To the external connection terminals, a flexible printed circuit (FPC) 107 for signal input and output may be connected.

### Application Example 1

FIG. 80 illustrates an appearance of a television set 110 that is configured of the display device according to the above-described example embodiment. The television set 110 includes, for example, a picture display screen section 113 that includes a front panel 111 and a filter glass 112. The picture display screen section 113 is configured of the display device according to the above-described example embodiment.

### Application Example 2

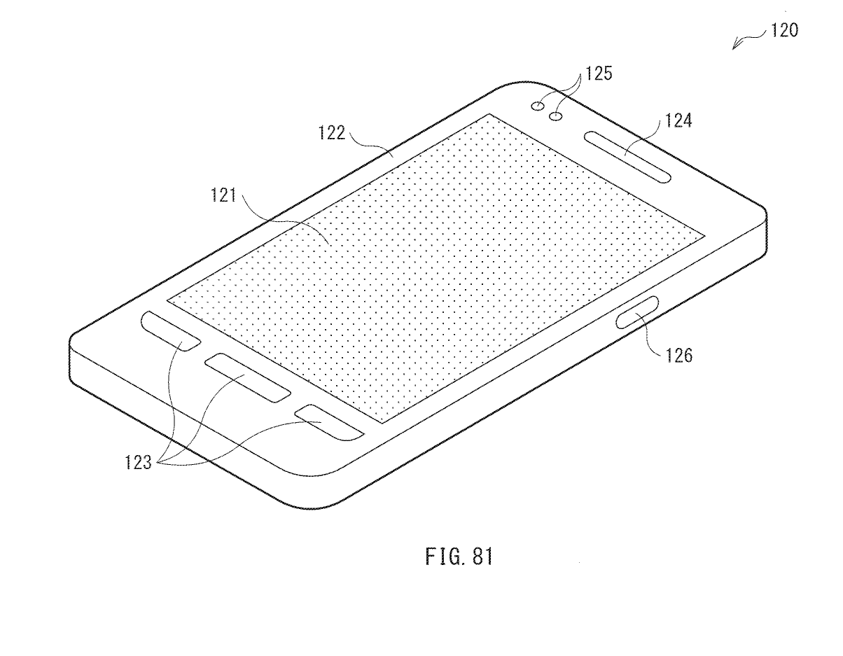

FIG. 81 illustrates an appearance of a smart phone 120 that is configured of the display device according to the above-described example embodiment. The smart phone 120 is configured of the display device according to the above-described example embodiment. The pixel array section 102 constitutes a touch panel section 121, and the peripheral region 106 constitutes a frame region 122. In the frame region 122, there are provided an operation button 123 in a lower region, an ear piece 124 and sensors 125 such as a proximity sensor, a luminance sensor in an upper region. On a side face, there is provided a power button 126. On a rear surface, there is provided a camera (not illustrated).

### Application Example 3

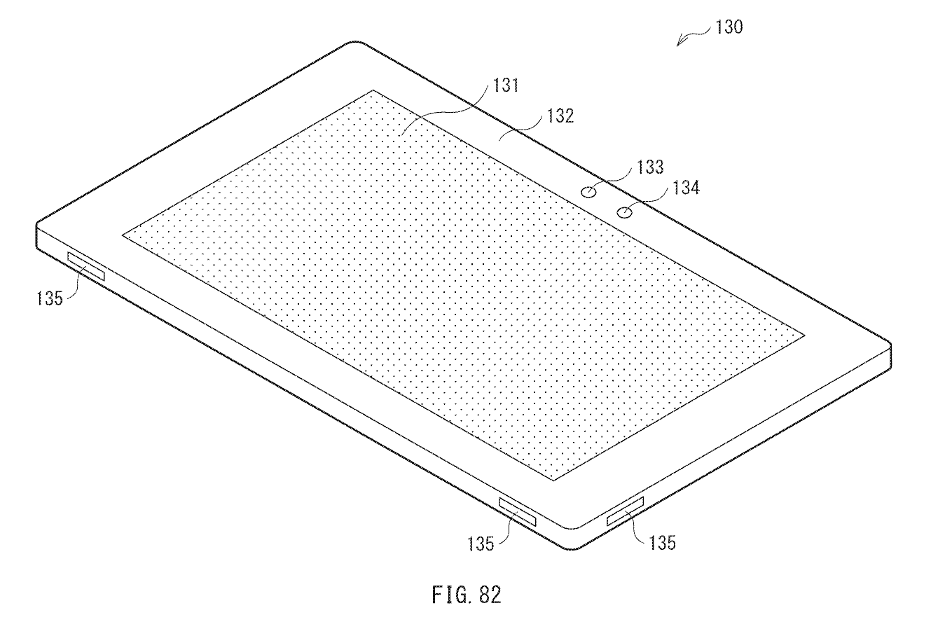

FIG. 82 illustrates an appearance of a tablet personal computer 130. The tablet personal computer 130 is configured of the display device according to the above-described example embodiment. The pixel array section 102 constitutes a touch panel section 131, and the peripheral region 106 constitutes a frame region 132. In the frame region 132, there are provided a luminance sensor 133 and a front camera 134. On a side face, there are arranged a speaker 135, a power key, mike, various operation buttons (neither illustrated). On a rear surface, there is provided a main camera (not illustrated).

Although description of the present technology has been made by giving the example embodiment as mentioned above, the contents of the present technology are not limited to the above-mentioned example embodiment and may be modified in a variety of ways.

For example, in the above-described example embodiment, description has been given on a case that the three capacitive elements C1 to C3 are stacked as the plurality of capacitive elements Cn. However, the number of the capacitive elements Cn stacked may be two, or may be four or more.

Moreover, for example, in the above-described example embodiment, description has been given on a case that two capacitive elements (the lower capacitive element C1 and the upper capacitive element C2) of the plurality of capacitive elements Cn are capable of maintaining different potentials from one another. However, the present disclosure is not limited thereto, but two or more of the plurality of capacitive elements Cn may be capable of maintaining different potentials from one another. For example, all of the plurality of capacitive elements Cn may be capable of maintaining different potentials from one another.

Further, for example, in the above-described example embodiment, description has been given on a case that the top electrode TE1 of the lower capacitive element C1 is provided on the same layer as the source electrode 35S, and is integral and continuous with the source electrode 35S. However, the top electrode TE1 of the lower capacitive element C1 may be provided on a different layer from the source electrode 35S, and may be connected to the source electrode 35S through a contact or the like. Alternatively, the top electrode TE1 of the lower capacitive element C1 may be provided on the same layer as the source electrode 35S, but may be provided as an uncontinuous layer with the source electrode 35S, and may be connected to the source electrode 35S through a contact or the like.

In addition, for example, in the above-described example embodiment, description has been given on a case that the top electrode TE1 of the lower capacitive element C1 and the bottom electrode BE2 of the upper capacitive element C2 are common. However, the top electrode TE1 of the lower capacitive element C1 and the bottom electrode BE2 of the upper capacitive element C2 may be provided as a separate layer and may be connected to each other through a contact or the like.

Furthermore, in addition, for example, in the above-described example embodiment, description has been given on specific configurations of the display devices 100, and 100A to 100G. However, the display devices 100, and 100A to 100G are not limited to display devices including all the components as illustrated. Moreover, some components may be substituted by other components.

Moreover, in the above-described example embodiment, description has been given on specific configurations and operations of the pixel circuit 101. However, configurations of the pixel circuit for active matrix driving are not limited to as exemplified in the above-described example embodiment. A capacitor or a transistor may be added as necessary, or the connection relation may be altered. In this case, according to changes or alterations of the pixel circuit, an additional drive circuit may be provided in addition to the above-mentioned drive section (the signal selector 103, the main scanner 104, and the power scanner 105). Moreover, it goes without saying that driving methods and operations of the pixel circuit are not limited to as exemplified above, but appropriate changes or alterations may be possible.

Furthermore, a material and a thickness, or a deposition method or a deposition condition of each layer as described in the above-mentioned example embodiment are not limitative, but other materials and other thicknesses, or other deposition methods or other deposition conditions may be adopted.

In addition, the organic layer 23 may be formed by other coating methods or printing methods, as well as a vacuum vapor method or a coating method such as an ejection coating method. Examples of other coating methods may include a dipping method, a doctor blade method, a spin coat method, a spray coat method. Examples of printing methods may include an inkjet method, an offset printing method, a letterpress printing method, an intaglio printing method, a screen printing method, a microgravure coat method. Depending on properties of layers of the organic layer 23 or other members, a dry process and a wet process may be used together.

Furthermore, in the above-described example embodiment, description has been given on a solid sealing structure in which the display element 20 is covered with the protective layer 25, the adhesive layer 26, and the sealing substrate 27, with no space left between the protective layer 25 and the sealing substrate 27. However, it is possible to adopt a hollow sealing structure in which the display element 20 is covered with the protective layer 25 and a lid member (not illustrated), with a space left between the protective layer 25 and the lid member. In this case, it is desirable that a getter agent (not illustrated) is disposed in the space between the protective layer 25 and the lid member, preventing moisture from intruding into the organic layer 23.

Furthermore, in addition, in the above-described example embodiment, description has been given on a case that the display element 20 includes the anode electrode 21, the organic layer 23, and the cathode electrode 24 in this order from the base 11 side. However, the anode electrode 21 and the cathode electrode 24 may be inverted, and the display element 20 may include the cathode electrode 24, the organic layer 23, and the anode electrode 21 from the base 11 side. Also in this case, it is possible to adopt both the upper surface emission in which light is extracted from the anode electrode 21 side and the lower surface emission in which light is extracted from the cathode electrode 24 (the substrate 10) side.

It is to be noted that effects described in the specification are merely exemplified and not limitative, and effects of the present disclosure may be other effects or may further include other effects.

It is possible to achieve at least the following configurations from the above-described example embodiments of the disclosure.

(1)

A display device provided with a substrate and a display element on the substrate, the substrate including:

a base; and

a plurality of capacitive elements that are stacked on the base and each include a bottom electrode and a top electrode,

wherein the plurality of capacitive elements include a lower capacitive element and an upper capacitive element that are different in position in a stacking direction, and

the bottom electrode of the lower capacitive element and the top electrode of the upper capacitive element are electrically independent from one another.

(2)

The display device according to (1),

wherein the bottom electrode of the lower capacitive element and the top electrode of the upper capacitive element are connected to different wirings from one another.

(3)

The display device according to (1) or (2),

wherein two or more capacitive elements of the plurality of capacitive elements are configured to be capable of maintaining different potentials from one another.

(4)

The display device according to any one of (1) to (3),

wherein two or more capacitive elements of the plurality of capacitive elements have different charge and discharge periods from one another.

(5)

The display device according to any one of (1) to (4),

wherein the substrate further includes a thin film transistor that includes a source electrode and a gate electrode,

the display element includes an anode electrode and a cathode electrode,

the source electrode of the thin film transistor is connected to the anode electrode of the display element,

the plurality of capacitive elements include a first capacitive element and a second capacitive element,

the first capacitive element is connected between the gate electrode and the source electrode of the thin film transistor, and

the second capacitive element is connected between the source electrode and the cathode electrode of the display element.

(6)

The display device according to (5),

wherein the first capacitive element is the upper capacitive element,

the second capacitive element is the lower capacitive element,

the bottom electrode of the lower capacitive element is connected to the cathode electrode of the display element, and

the top electrode of the upper capacitive element is connected to the gate electrode of the thin film transistor.

(7)

The display device according to (6),

wherein the plurality of capacitive elements further include an uppermost capacitive element,

the first capacitive element is the upper capacitive element and the uppermost capacitive element,

the bottom electrode of the uppermost capacitive element is the top electrode of the upper capacitive element, and

the top electrode of the uppermost capacitive element is the anode electrode of the display element.

(8)

The display device according to (5),

wherein the first capacitive element is the lower capacitive element,

the second capacitive element is the upper capacitive element,

the bottom electrode of the lower capacitive element is connected to the gate electrode of the thin film transistor, and

the top electrode of the upper capacitive element is connected to the cathode electrode of the display element.

(9)

The display device according to (8),

wherein the plurality of capacitive elements further include an uppermost capacitive element,

the second capacitive element is the upper capacitive element and the uppermost capacitive element,

the bottom electrode of the uppermost capacitive element is the top electrode of the upper capacitive element, and

the top electrode of the uppermost capacitive element is the anode electrode of the display element.

(10)

The display device according to any one of (5) to (9),

wherein the thin film transistor further includes a semiconductor layer that is configured of a first oxide semiconductor, and

the bottom electrode or the top electrode of one or more of the plurality of capacitive elements is configured of a second oxide semiconductor that has a lower resistance value than that of the first oxide semiconductor.

(11)

An electronic apparatus provided with a display device including a substrate and a display element on the substrate, the substrate including:

a base; and

a plurality of capacitive elements that are stacked on the base and each include a bottom electrode and a top electrode,

wherein the plurality of capacitive elements include a lower capacitive element and an upper capacitive element that are different in position in a stacking direction, and

the bottom electrode of the lower capacitive element and the top electrode of the upper capacitive element are electrically independent from one another.

(12)

A substrate including:

a base; and

a plurality of capacitive elements that are stacked on the base and each include a bottom electrode and a top electrode,

wherein the plurality of capacitive elements include a lower capacitive element and an upper capacitive element that are different in position in a stacking direction, and

the bottom electrode of the lower capacitive element and the top electrode of the upper capacitive element are electrically independent from one another.

It should be understood by those skilled in the art that various modifications, combinations, sub-combinations and alterations may occur depending on design requirements and other factors insofar as they are within the scope of the appended claims or the equivalents thereof.

What is claimed is:

1. A display device provided with a substrate and a display element on the substrate, the substrate comprising:
a base; and
a plurality of capacitive elements that are stacked on the base and each include a bottom electrode and a top electrode,
wherein the plurality of capacitive elements include a lower capacitive element and an upper capacitive element that are different in position in a stacking direction, and
the bottom electrode of the lower capacitive element and the top electrode of the upper capacitive element are electrically independent from one another.

2. The display device according to claim 1,
wherein the bottom electrode of the lower capacitive element and the top electrode of the upper capacitive element are connected to different wirings from one another.

3. The display device according to claim 1,
wherein two or more capacitive elements of the plurality of capacitive elements are configured to be capable of maintaining different potentials from one another.

4. The display device according to claim 1,
wherein two or more capacitive elements of the plurality of capacitive elements have different charge and discharge periods from one another.

5. The display device according to claim 1,
wherein the substrate further comprises a thin film transistor that includes a source electrode and a gate electrode,
the display element includes an anode electrode and a cathode electrode,
the source electrode of the thin film transistor is connected to the anode electrode of the display element,
the plurality of capacitive elements include a first capacitive element and a second capacitive element,
the first capacitive element is connected between the gate electrode and the source electrode of the thin film transistor, and
the second capacitive element is connected between the source electrode and the cathode electrode of the display element.

6. The display device according to claim 5,
wherein the first capacitive element is the upper capacitive element,
the second capacitive element is the lower capacitive element,
the bottom electrode of the lower capacitive element is connected to the cathode electrode of the display element, and
the top electrode of the upper capacitive element is connected to the gate electrode of the thin film transistor.

7. The display device according to claim 6,
wherein the plurality of capacitive elements further include an uppermost capacitive element,
the first capacitive element is the upper capacitive element and the uppermost capacitive element,
the bottom electrode of the uppermost capacitive element is the top electrode of the upper capacitive element, and
the top electrode of the uppermost capacitive element is the anode electrode of the display element.

8. The display device according to claim 5,
wherein the first capacitive element is the lower capacitive element,
the second capacitive element is the upper capacitive element,
the bottom electrode of the lower capacitive element is connected to the gate electrode of the thin film transistor, and
the top electrode of the upper capacitive element is connected to the cathode electrode of the display element.

9. The display device according to claim 8,
wherein the plurality of capacitive elements further include an uppermost capacitive element,
the second capacitive element is the upper capacitive element and the uppermost capacitive element,
the bottom electrode of the uppermost capacitive element is the top electrode of the upper capacitive element, and
the top electrode of the uppermost capacitive element is the anode electrode of the display element.

10. The display device according to claim 5,
wherein the thin film transistor further includes a semiconductor layer that is configured of a first oxide semiconductor, and
the bottom electrode or the top electrode of one or more of the plurality of capacitive elements is configured of a second oxide semiconductor that has a lower resistance value than that of the first oxide semiconductor.

11. An electronic apparatus provided with a display device including a substrate and a display element on the substrate, the substrate comprising:
a base; and
a plurality of capacitive elements that are stacked on the base and each include a bottom electrode and a top electrode,
wherein the plurality of capacitive elements include a lower capacitive element and an upper capacitive element that are different in position in a stacking direction, and
the bottom electrode of the lower capacitive element and the top electrode of the upper capacitive element are electrically independent from one another.

12. A substrate comprising:
a base; and
a plurality of capacitive elements that are stacked on the base and each include a bottom electrode and a top electrode,
wherein the plurality of capacitive elements include a lower capacitive element and an upper capacitive element that are different in position in a stacking direction, and
the bottom electrode of the lower capacitive element and the top electrode of the upper capacitive element are electrically independent from one another.
